(19) United States
(12) Patent Application Publication
(10) Pub. No.: US 2008/0299312 A1
(43) Pub. Date: Dec. 4, 2008

(54) Raw Material Solution for Metal Organic Chemical Vapor Deposition Method and Method for Manufacturing Composite Oxide Film Containing Hf-Si Using the Raw Material Solution

(76) Inventors: Atsushi Itsuki, Iwaki-shi (JP); Akio Yanagisawa, Kounosu-shi (JP); Nobuyuki Soyama, Sanda-shi (JP)

Correspondence Address: DARBY & DARBY P.C., P.O. BOX 770, Church Street Station, New York, NY, 10008-0770, US

(21) Appl. No.: 11/574,547

(22) PCT Filed: Sep. 2, 2005
(86) PCT No.: PCT/JP05/16082

§ 371 Date: Oct. 16, 2007

(30) Foreign Application Priority Data
Sep. 2, 2004 (JP) 2004-255097
Sep. 2, 2004 (JP) 2004-255098
Aug. 31, 2005 (JP) 2005-250917
Aug. 31, 2005 (JP) 2005-250945

(51) Int. Cl. C23C 16/06; C09D 5/00

(52) U.S. Cl. 427/255.31; 106/287.11

(57) ABSTRACT

There is provided a raw material solution for MOCVD method having a high film forming rate, and a method for manufacturing composite oxide film containing Hf-Si using the raw material solution. There is also provided a method for manufacturing composite oxide film containing Hf-Si by using the raw material solution for MOCVD method providing an excellent adhesivity with a substrate.

The raw material solution for MOCVD method of the invention includes an organic Si compound represented by the formula (R¹R²N)ₙSiH₍₄₋ₙ₎ which is mixed in a predetermined ratio. A mixing ratio of the organic Si compound and the organic Hf compound is within the range of 0.001 to 0.5 wt % in a weight ratio (organic Hf compound/organic Si compound). The raw material solution for MOCVD method of the invention is prepared by mixing the compounds in a ratio within the above-mentioned range, dissolving the organic Hf compound in the organic Si compound, and heating this solution at a temperature of 20 to 100 ° C.

### TECHNICAL FIELD

The present invention relates to a raw material solution for MOCVD method, which is a single solution of metal materials when forming a composite oxide film containing Hf-Si such as a HfSiO film or a HfSiON film using a Metal Organic Chemical Vapor Deposition method (hereinafter, referred to as MOCVD method), and to a method for manufacturing composite oxide film containing Hf-Si using the raw material solution.

### BACKGROUND ART

Silicon dioxide film is used as a high-k dielectric gate insulator, and thinning the silicon dioxide film is recently in progress to obtain a high density of LSI. However, since a tunnel current flows and an effect of insulation is decreased in a thin film having a thickness less than or equal to 100 nm, further thinning of the silicon oxide film is limited.

Therefore, a gate insulating film is considered in place of the silicon oxide film, and hafnium and silicon contained oxide films, specifically a composite oxide film containing Hf-Si such as a Hf-Si—O film or a Hf-Si—O—N film came to attention as a candidate. Examples of a method for producing a composite oxide film containing Hf-Si include a sputtering method, an ion plating method, a thermal decomposition, MOD (Metal Organic Deposition) such as a sol-gel process, and the like, and the most appropriate film production process is the MOCVD method considering its excellent composition control and step coverage in comparison with the above-mentioned production methods, and integrity with a semiconductor manufacturing process.

As a material for forming a composite oxide film containing Hf-Si, there are metal chloride or metal alkoxide, a DPM complex, and the like. As an organic Si compound, there are tetrakis(ethoxy)silane (hereinafter, referred to as Si(C₂H₅O)₄) and SiCl₆. As an organic Hf compound, there are tetrakis(tertiary-butoxy)hafnium (hereinafter, referred to as Hf(t-C₃H₇O)₄), tetrakis(dipivaloylmethanate)hafnium (hereinafter, referred to as Hf(DPM)₄), and the like.

However, there is a problem in the MOCVD method using a metalorganic compound that selection and composition of appropriate metalorganic compound raw materials are important, and there may always not be appropriate metalorganic compound raw materials for desired metal materials.

In order to solve such above-mentioned problem, there has been provided a method (e.g., see Patent Document 1) for forming a Hf-containing thin film according to the MOCVD method including a transport of at least one or plurality of metalorganic materials of M[N(C₂H₅)₂]₄ (M is a metal (Si containing) element) into a film forming chamber, a deposition of a metal (alloy containing) film or a metal compound film by a CVD method, and a thermal treatment followed by the deposition at a temperature higher than a volume temperature. According to the above-mentioned film forming method, although a film-forming surface of a semiconductor device or an electronic equipment is uneven, metal and a compound thereof can be deposited with excellent controllability and uniformity to manufacture a semiconductor device and an electronic equipment having an excellent performance.

[Patent Document 1] Japanese Unexamined Patent Application, First Publication No. 2002-167672 (claim 1, paragraph [0005])

### DISCLOSURE OF THE INVENTION

However, since the thermal treatment for improving a film quality is required after depositing a desired metal compound film according to the above-mentioned film forming method disclosed in the Patent Document 1, a process is complicated, and a substrate can be damaged as the thermal treatment is performed at a higher temperature than the temperature required for a film deposition.

The object of the invention is to provide a raw material solution having a high film forming rate for the MOCVD method, and a production method for forming the composite oxide film containing Hf-Si by using the raw material solution.

The other object of the invention is to provide a method for manufacturing the composite oxide film containing Hf-Si having a good adhesivity with a substrate, by using the raw material solution for MOCVD method.

The invention according to claim 1 is a raw material solution for MOCVD method including an organic Si compound represented by the following formula (1) and an organic Hf compound represented by the following formula (2), which are mixed in a predetermined ratio to dissolve the organic Hf compound in the organic Si compound.

(R¹R²N)ₙSiH₍₄₋ₙ₎ (1)

(wherein, R¹ and R² are straight or branched alkyl groups having 1 to 4 carbon atoms provided that R¹ and R² are same with each other, R¹ is an alkyl group having 1 or 2 carbon atoms and R² is a straight or branched alkyl group having 2 to 4 carbon atoms provided that R¹ and R² are different from each other, and n is an integer of 1 to 4).

Hf(OR³)₄ (2)

(wherein, R³ is a straight or branched alkyl group having 1 to 4 carbon atoms).

The invention according to claim 1 is a single solution of the metalorganic compound raw material for a film containing a plurality of metals such as the composite oxide film containing Hf-Si, and is obtained by mixing the organic Si compound represented by the above-mentioned formula (1) with the organic Hf compound represented by the above-mentioned formula (2) in a predetermined ratio and then dissolving the organic Hf compound in the organic Si compound. Since the single solution of the raw material solution for MOCVD method prepared in such manner is seemed to include an intermediate of Hf-Si mixed metal polynuclear molecule formed with the organic Hf compound and the organic Si compound, this intermediate nucleates the initial film-forming core on a surface of the substrate. Therefore, high film forming rate is obtained by using the raw material solution of the invention.

The invention according to claim 2 is the raw material solution for metal organic chemical vapor deposition method according to claim 1, in which a mixing ratio of the organic Si compound and the organic Hf compound is within a range of 0.001 to 0.5 wt % in a weight ratio (organic Hf compound/organic Si compound).

The invention according to claim 2 forms the composite oxide film containing Hf-Si of high quality by using the raw material solution mixed within the above-mentioned ratio.

The invention according to claim 3 is a method for manufacturing composite oxide film containing Hf-Si including preparing of the composite oxide film containing Hf-Si by using the raw material solution for metal organic chemical vapor deposition method according to claim 1 or 2.

The invention according to claim 3 can form a film at a higher film forming rate by using the above-mentioned single solution of raw material solution for MOCVD method, in comparison with a conventional case where two solutions of raw material solutions for MOCVD method are respectively supplied to prepare a film, and further obtains the composite oxide film containing Hf-Si having a high adhesivity with a substrate.

The invention according to claim 4 is the method for manufacturing composite oxide film containing Hf-Si which includes the steps of growing a Si film on a surface of a substrate by thermally decomposing an organic Si compound having a same or different composition from the organic Si compound used for the raw material solution for metal organic chemical vapor deposition method according to claim 1 or 2 together with a reducing gas; and forming a HfSiO film on a surface of the grown Si film by supplying the raw material solution for metal organic chemical vapor deposition method according to claim 1 or 2 together with an oxidizing agent and performing the thermal decomposition.

The invention according to claim 4 further improves adhesivity of HfSiO film with a substrate by preparing the HfSiO film on a surface of the Si film grown in advance on a surface of a substrate.

The invention according to claim 5 is the method for manufacturing composite oxide film containing Hf-Si which includes the steps of growing a Si film on a surface of a substrate by thermally decomposing an organic Si compound having a same or different composition from the organic Si compound used for the raw material solution for metal organic chemical vapor deposition method according to claim 1 or 2 together with a reducing gas; and forming a HfSiON film on a surface of the grown Si film by supplying the raw material solution for metal organic chemical vapor deposition method according to claim 1 or 2 together with an oxidizing agent and a nitrogen source and then performing the thermal decomposition.

The invention according to claim 5 further improves adhesivity of HfSiON film with a substrate by preparing the HfSiON film on a surface of the Si film grown in advance on a surface of the substrate.

The invention according to claim 6 is a raw material solution for metal organic chemical vapor deposition method, which is prepared by mixing an organic Si compound with an organic Hf compound such that the mixing ratio ranges from 0.001 to 0.5 wt % in a weight ratio (organic Hf compound/organic Si compound); dissolving the organic Hf compound in the organic Si compound; and heating the solution at a temperature of 20 to 100° C.

The invention according to claim 6 is a raw material solution which is a single solution of the metalorganic compound raw material for a film containing a plurality of metals such as the composite oxide film containing Hf-Si. This raw material solution is prepared as a single solution by mixing the organic Si compound with the organic Hf compound in a predetermined mixing ratio and then by dissolving the organic Hf compound in the organic Si compound, and the solution is obtained by heating in a predetermined temperature range to be prepared. Since the single solution of the raw material solution for MOCVD method prepared in such manner is thought to include an intermediate of Hf-Si mixed metal polynuclear molecule formed with the organic Hf compound and the organic Si compound, this intermediate nucleates the initial film-forming core on a surface of the substrate. Therefore, high film forming rate is obtained by using the raw material solution of the invention.

The invention according to claim 7 is the raw material solution for metal organic chemical vapor deposition method according to claim 6, in which the organic Si compound is represented by the following formula (1) or (3).

(R¹R²N)ₙSiH₍₄₋ₙ₎ (1)

(wherein, R¹ and R² are straight or branched alkyl groups having 1 to 4 carbon atoms provided that R¹ and R² are same with each other, R¹ is an alkyl group having 1 or 2 carbon atoms and R² is a straight or branched alkyl group having 2 to 4 carbon atoms provided that R¹ and R² are different from each other, and n is an integer of 1 to 4).

(R³O)ₘSiH₍₄₋ₘ₎ (3)

(wherein, R³ is a straight or branched alkyl group having 1 to 4 carbon atoms, and m is an integer of 1 to 4).

In the invention according to claim 7, the organic Si compounds represented by the above formula (1) or (3) are preferable as they exist in a liquid form at a room temperature, are capable of dissolving the organic Hf compounds, and have excellent volatilization stability, film forming rate, and step coverage.

The invention according to claim 8 is the raw material solution for metal organic chemical vapor deposition method according to claim 6, in which the organic Hf compound is represented by the following formula (4).

Hf(R⁴R⁵N)₄ (4)

(wherein, R⁴ and R⁵ are alkyl groups having 1 or 2 carbon atoms, and R⁴ and R⁵ may be same or different from each other).

The invention according to claim 9 is the raw material solution for metal organic chemical vapor deposition method according to claim 6, in which the organic Hf compound is represented by the following formula (5)

Hf(OR⁶)₄ (5)

(wherein, R⁶ is a straight or branched alkyl group having 1 to 4 carbon atoms).

The invention according to claim 8 or 9 is preferable as the organic Hf compound represented by the above-mentioned formula (4) or (5) easily dissolves in the organic Si compound, and has excellent volatilization stability, film forming rate, and step coverage.

The invention according to claim 10 is a method for manufacturing composite oxide film containing Hf-Si, which includes preparing the composite oxide film containing Hf-Si by using the raw material solution for metal organic chemical vapor deposition method according to any one of claims 6 to 9.

The invention according to claim 10 can form a film at a higher film forming rate by using the above-mentioned single solution of raw material solution for MOCVD method, in comparison with a conventional case where two solutions of raw material solutions for MOCVD method are respectively supplied to prepare a film, and further obtains the composite oxide film containing Hf-Si having a high adhesivity with the substrate.

The invention according to claim 11 is the method for manufacturing composite oxide film containing Hf-Si which includes the steps of growing a Si film on a surface of a substrate by thermally decomposing an organic Si compound having a same or different composition from the organic Si compound used for the raw material solution for metal organic chemical vapor deposition method according to any one of claims 6 to 9 together with a reducing gas; and forming a HfSiO film on a surface of the grown Si film by supplying the raw material solution for metal organic chemical vapor deposition method according to any one of claims 6 to 9 together with an oxidizing agent and performing the thermal decomposition.

The present invention according to claim 11 further improves adhesivity of HfSiO film with a substrate by forming the HfSiO film on a surface of the Si film grown in advance on a surface of the substrate.

The invention according to claim 12 is the method for manufacturing composite oxide film containing Hf-Si, which includes the steps of growing a Si film on a surface of a substrate by thermally decomposing the organic Si compound having a same or different composition from the organic Si compound used for the raw material solution for metal organic chemical vapor deposition method according to any one of claims 6 to 9 together with a reducing gas; and forming a HfSiON film on a surface of the grown Si film by supplying the raw material solution for metal organic chemical vapor deposition method according to any one of claims 6 to 9 together with an oxidizing agent and a nitrogen source and then performing the thermal decomposition.

The present invention according to claim 12 further improves adhesivity of HfSiON film with a substrate by forming the HfSiON film on a surface of the Si film grown in advance on a surface of the substrate.

### BRIEF DESCRIPTION OF THE DRAWINGS

FIG. 1 is a view schematically showing an MOCVD apparatus for manufacturing method of the invention.

FIG. 2 is a view schematically showing an MOCVD apparatus having a configuration capable of supplying nitrogen.

FIG. 3 is a view schematically showing an MOCVD apparatus for two raw material solutions according to comparative examples 1 and 2.

### BEST MODE FOR CARRYING OUT THE INVENTION

Hereinafter, the invention will be described in detail with reference to suitable forms of embodiment.

The raw material solution for the MOCVD method according to the invention is a single solution of the metalorganic compound raw material for a film containing a plurality of metals such as the composite oxide film containing Hf-Si, and is obtained by mixing the organic Si compound with the organic Hf compound in a predetermined ratio and then dissolving the organic Hf compound in the organic Si compound.

The organic Si compound used for the raw material solution for the MOCVD method of the invention is represented by the following formula (1).

(R¹R²N)ₐSiH₍₄₋ₙ₎ (1)

(wherein, R¹ and R² are straight or branched alkyl groups having 1 to 4 carbon atoms provided that R¹ and R² are same with each other, R¹ is an alkyl group having 1 or 2 carbon atoms and R² is a straight or branched alkyl group having 2 to 4 carbon atoms provided that R¹ and R² are different from each other, and n is an integer of 1 to 4).

Representative examples of the compound represented by the above formula (1) include Si[(CH₃)₂N]₄, Si[(C₂H₅)₂N]₄, Si[(C₃H₇)₂N]₄ Si[(C₄H₉)₂N]₄, Si[(CH₃)(C₂H₅)N]₄, Si[(CH₃)(C₃H₇)N]₄, Si[(CH₃)(C₄H₉)N]₄, Si[(C₂H₅)(C₃H₇)N]₄, Si[(C₂H₅)(C₄H₉)N]₄, SiH[(CH₃)₂N]₃, and the like. There is no doubt that other than these representative compounds, any other organic Si compound satisfying the above formula (1) can be used as the raw material solution of the invention. The organic Si compounds represented by the above formula (1) are preferable as they exist in a liquid form at a room temperature, capable of dissolving the organic Hf compounds represented by a formula (2) to be described later, and have excellent volatilization stability, film forming rate, and step coverage.

The organic Hf compound used for the MOCVD method of the invention is represented by the following formula (2).

Hf(OR³)₄ (2)

(wherein, R³ is a straight or branched alkyl group having 1 to 4 carbon atoms).

A representative example of the compound represented by the above formula (2) includes Hf(t-C₃H₇O)₄. There is no doubt that other than the representative compound, any other organic Hf compound satisfying the above formula (2) can be used as the raw material solution of the invention. The organic Hf compound represented by the above formula (2) is preferable as it easily dissolves in the above-mentioned organic Si compound represented by the formula (1), and has excellent volatilization stability, film forming rate, and step coverage.

By using the single solution of the raw material solution for the MOCVD method prepared in the above manner, high film forming rate is achieved, and also a fine composite oxide film containing Hf-Si having a high adhesivity is obtained. The reason is thought as follow. Since in the raw material solution of the invention, an intermediate of Hf-Si mixed metal polynuclear molecule formed with the organic Hf compound and the organic Si compound is thought to be included in the organic Si compound that holds most of the liquid mixture, this intermediate nucleates an initial film-forming core, and the composite oxide containing Hf-Si, which is formed by thermally decomposing vapor of the organic Si compound, organic Hf compound and the intermediates thereof and then reacting with an oxidizing agent, may start to deposit mainly from the initial film-forming core. In this way of depositing the composite oxide containing Hf-Si after nucleation of the initial film-forming core, high film forming rate is achieved. In addition, a fine film is formed as the film is formed mainly from the initial film-forming core. Furthermore, the composite oxide film containing Hf-Si having a high adhesivity is obtained as the initial film-forming core increases the adhesivity with the substrate.

A mixing ratio of the organic Si compound and the organic Hf compound is preferably within the range of 0.001 to 0.5 wt % in a weight ratio (organic Hf compound/organic Si compound). If it is less than a lower limit value, high quality of complex oxide membrane containing Hf-Si cannot be formed as a component ratio of the organic Hf compound is too small, and if it is more than an upper limit value, the intermediate of Hf-Si mixed metal polynuclear molecule hardly forms as the component ratio of the organic Hf compound is too large. The above-mentioned mixing ratio ranging from 0.001 to 0.5 wt % in a weight ratio (organic Hf compound/organic Si compound) is specifically preferable.

The raw material solution for the MOCVD method according to the invention is a single solution of the metalorganic compound raw material for a film containing a plurality of metals such as the composite oxide film containing Hf-Si. It is prepared as a single solution by mixing the organic Si compound with the organic Hf compound in the mixing ratio ranged from 0.001 to 0.5 wt % in a weight ratio (organic Hf compound/organic Si compound) and then by dissolving the organic Hf compound in the organic Si compound, and the solution is obtained by heating the mixed solution at 20 to 100° C. By using the single solution of the raw material solution for MOCVD method prepared in the above manner, high film forming rate is achieved, and also a fine composite oxide film containing Hf-Si having a high adhesivity is obtained. The reason is thought as follow. Since in the raw material solution of the invention, an intermediate of Hf-Si mixed metal polynuclear molecule, for example the intermediate represented by the following formula (6), formed with the organic Hf compound and the organic Si compound is thought to be included in the organic Si compound that holds most of the liquid mixture, this intermediate having a such structure nucleates the initial film-forming core, and the composite oxide containing Hf-Si, which is formed by thermally decomposing vapor of the organic Si compound, organic Hf compound and the intermediates thereof and then reacting with an oxidizing agent, may start to deposit mainly from the initial film-forming core. In this way of depositing the composite oxide containing Hf-Si after nucleation of the initial film-forming core, high film forming rate is achieved. In addition, a fine film is formed as the film is formed mainly from the initial film-forming core. Furthermore, the composite oxide film containing Hf-Si having a high adhesivity is obtained as the initial film-forming core increases the adhesivity with the substrate. Dotted lines shown in the formula (6) represent a weak bond.

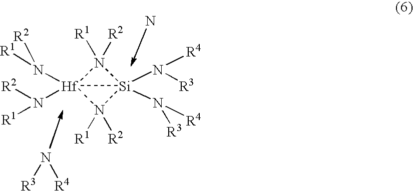

An intermediate when using a compound including the organic Si compound and the organic Hf compound together with nitrogen is represented in the formula (6), but in a case where a compound including oxygen is used as any one or both of the organic Si compound and the organic Hf compound, it can be thought that a form of Hf-Si mixed metal polynuclear molecule having a structure resembling the intermediate shown in the above formula (6) is taken.

The mixing ratio of the organic Hf compound and the organic Si compound is provided to be within the above-mentioned range, because if it is less than the lower limit value, high quality of composite oxide film containing Hf-Si cannot be formed as the component ratio of the organic Hf compound is too small, and if it is more than the upper limit value, the intermediate of Hf-Si mixed metal polynuclear molecule hardly forms as the component ratio of the organic Hf compound is too large. The mixing ratio is more preferably within the range of 0.01 to 0.1 wt % in a weight ratio (organic Hf compound/organic Si compound). In addition, the organic Hf compound and the organic Si compound are mixed in a predetermined ratio and dissolved to be heat treated at the above-mentioned temperature range, so as to form the intermediate of Hf-Si mixed metal polynuclear molecule by stably attacking the organic Si compound to the organic Hf compound. Specifically preferable heating temperature to be applied to the solution is within the range of 20 to 100° C. Also, a heat period is preferably from 30 minutes to 1 hour.

The organic Si compound used for the raw material solution for MOCVD method of the invention is represented by each of following formulae (1) and (3).

(R¹R²N)ₙSiH₍₄₋ₙ₎ (1)

(wherein, R¹ and R² are straight or branched alkyl groups having 1 to 4 carbon atoms provided that R¹ and R² are same with each other, R¹ is an alkyl group having 1 or 2 carbon atoms and R² is a straight or branched alkyl group having 2 to 4 carbon atoms provided that R¹ and R² are different from each other, and n is an integer of 1 to 4).

(R³O)ₘSiH₍₄₋ₘ₎ (3)

(wherein, R³ is a straight or branched alkyl group having 1 to 4 carbon atoms, and m is an integer of 1 to 4).

Representative examples of the compound represented by the above formula (1) include Si[(CH₃)₂N]₄, Si[(C₂H₅)₂N]₄, Si[(C₃H₇)₂N]₄, Si[(C₄H₉)₂N]₄, Si[(CH₃)(C₂H₅)N]₄, Si[(CH₃)(C₃H₇)N]₄, Si[(CH₃)(C₄H₉)N]₄, Si[(C₂H₅)(C₃H₇)N]₄, Si[(C₂H₅)(C₄H₉)N]₄, SiH[(CH₃)₂N]₃, and the like.

Representative examples of the compound represented by the above formula (3) include Si[(CH₃)O]₄, Si[(C₂H₅)O]₄, Si[(C₃H₇)O]₄, Si[(C₄H₉)O]₄, SiH[(CH₃)O]₃, and the like. There is no doubt that other than these representative compounds, any other organic Si compound satisfying the above formulae (1) or (3) can be used as the raw material solution of the invention.

The organic Si compounds represented by each of the above formulae (1) or (3) are preferable as they exist in a liquid form at a room temperature, can dissolve the organic Hf compounds, and have excellent volatilization stability, film forming rate, and step coverage.

The organic Hf compound used for the raw material solution for MOCVD method of the invention is represented by each of following formulae (4) or (5).

Hf(R⁴R⁵N)₄ (4)

(wherein, R⁴ and R⁵ are alkyl groups having 1 or 2 carbon atoms, and R⁴ and R⁵ may be same or different from each other).

Hf(OR⁶)₄ (5)

(wherein, R⁶ is a straight or branched alkyl group having 1 to 4 carbon atoms).

Representative examples of the compound represented by the above formula (4) include Hf[(CH₃)₂N]₄, Hf[(C₂H₅)₂N]₄, Hf[(CH₃)(C₂H₅)N]₄, and the like. A representative example of the compound represented by the above formula (5) includes Hf(t-C₄H₉O)₄. There is no doubt that other these representative compounds, any other organic Hf compound satisfying the above formulae (4) or (5) can be used as the raw material solution of the invention.

The organic Hf compounds represented by the above formulae (4) or (5) are preferable as they easily dissolve in the organic Si compound, and have excellent volatilization stability, film forming rate, and step coverage.

Ligands coordinated to each of the organic Hf compound and the organic Si compound used for the raw material solution for MOCVD method of the invention may be a combination of ligands of same structure, but by using a combination of ligands of different structure, for example, the organic Si compound SiH[(CH₃)₂N]₃ of which a dimethylamino group is coordinated to a Si atom and the organic Hf compound Hf[(C₂H₅)₂N]₄ of which a dimethylamino group is coordinated to a Hf atom, to prepare and use a single solution of raw material for MOCVD method, steric hindrance to the Hf-Si mixed metal polynuclear molecule formed as the intermediate is occurred. This occurrence of steric hindrance breaks symmetry of tetrahedral positions of the Hf element and Si element and thus it becomes easier to be dissolved. Therefore, nucleation of the initial film-forming core is promoted.

Next, the method for manufacturing composite oxide film containing Hf-Si of the invention will be described.

The method for manufacturing composite oxide film containing Hf-Si of the invention is characterized in that the composite oxide film containing Hf-Si is formed by using the raw material solution for MOCVD method of the invention described above. A film can be formed at a higher film forming rate by using the above-mentioned single solution of raw material solution for MOCVD method, in comparison with a case where each of two solutions of raw material solutions for MOCVD method are supplied to prepare a film. The reason for this is that the intermediate in the raw material solution supplied in the film forming chamber of an MOCVD apparatus is firstly thermally decomposed and nucleates the initial film-forming core which contributes in forming a film, and this initial film-forming core is modified on a surface of the substrate. Subsequently, vapor of the organic Si compound, the organic Hf compound, and the intermediates thereof thermally decompose and react with the oxidizing agent to produce HfSiO. When produced HfSiO gets closer to a heated substrate, HfSiO starts to deposit mainly from the initial film-forming core modified on a surface of the substrate, and thus it is considered that the film can be formed at a higher film forming rate in comparison with the conventional case where two solutions of raw material solution for MOCVD method are used. In addition, since the HfSiO deposits mainly from the initial film-forming core, obtained composite oxide film containing Hf-Si is compactly formed and thus has a high adhesitivity to the substrate.

The method for manufacturing composite oxide film containing Hf-Si of the invention will be described with reference to a method for forming a Hf-Si—O film.

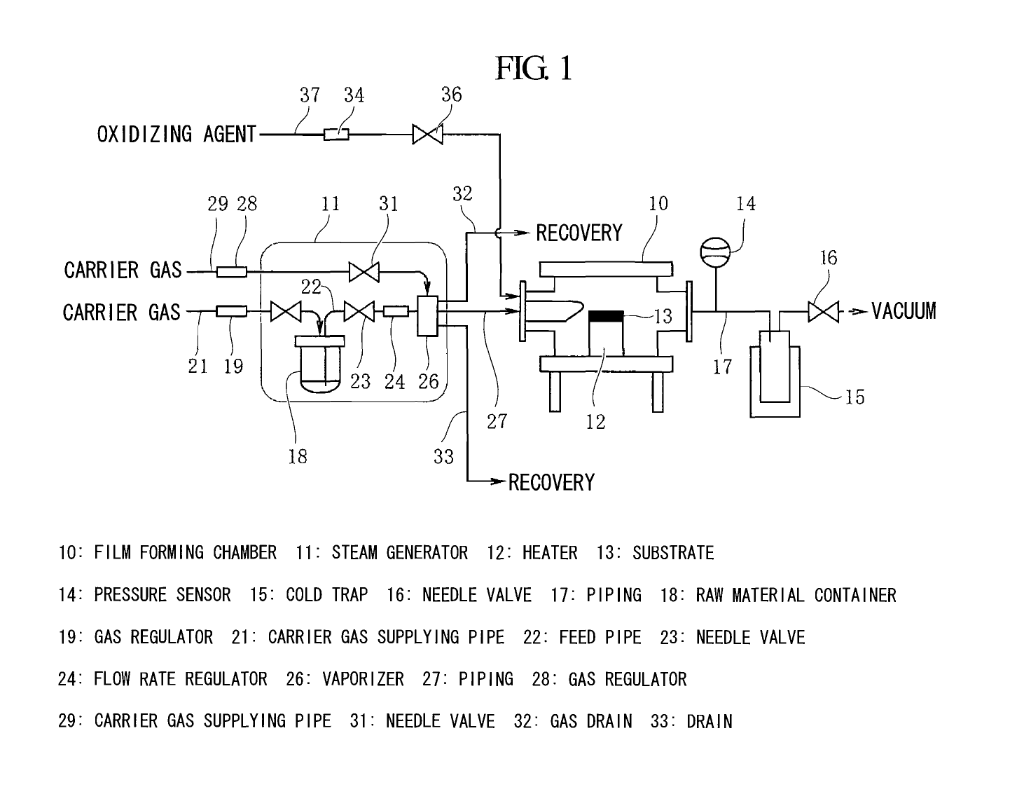

As shown in FIG. 1, the MOCVD apparatus is provided with a film forming chamber 10 and a steam generator 11. A heater 12 is arranged in the inside of the film forming chamber 10 and a substrate 13 is held on the heater 12. The inside of the film forming chamber 10 is evacuated by a piping 17 equipped with a pressure sensor 14, a cold trap 15 and a needle valve 16. An oxidizing agent supplying pipe 37 is connected via a needle valve 36 and a gas regulator 34 to the film forming chamber 10. The steam generator 11 is provided with a raw material container 18, and this raw material container 18 stores the raw material solution for MOCVD method of the invention and is sealed. A carrier gas supplying pipe 21 is connected via a gas regulator 19 to the raw material container 18. Further, a feed pipe 22 is connected to the raw material container 18. A needle valve 23 and a flow rate regulator 24 are arranged in the feed pipe 22 and the feed pipe 22 is connected to a vaporizer 26. A carrier gas supplying pipe 29 is connected via a needle valve 31 and a gas regulator 28 to the vaporizer 26. The vaporizer 26 is further connected via a pipe 27 to the film forming chamber 10. In addition, a gas drain 32 and a drain 33 are connected to the vaporizer 26, respectively.

In this apparatus, a carrier gas consisting of an inert gas, e.g., N₂, He, Ar, and the like is supplied from the carrier gas supplying pipe 21 into the raw material container 18 and the raw material solution for MOCVD method stored in the raw material container 18 is delivered via the feed pipe 22 to the vaporizer 26. The organic Si compound, organic Hf compound, and the intermediates thereof which have been vaporized by the vaporizer 26, is further fed via the piping 27 to the film forming chamber 10 by the carrier gas which is supplied from the carrier gas supplying pipe 28 into the vaporizer 26. The vapor of the organic Si compound, the organic Hf compound, and the intermediates thereof is thermally decomposed and reacted with the oxidizing agent supplied from the oxidizing agent supplying pipe 37 to form HfSiO, and the HfSiO formed is deposited on a surface of the substrate to form a Hf-Si—O film. Examples of the oxidizing agent include O₂, H₂O₂, N₂O, and the like.

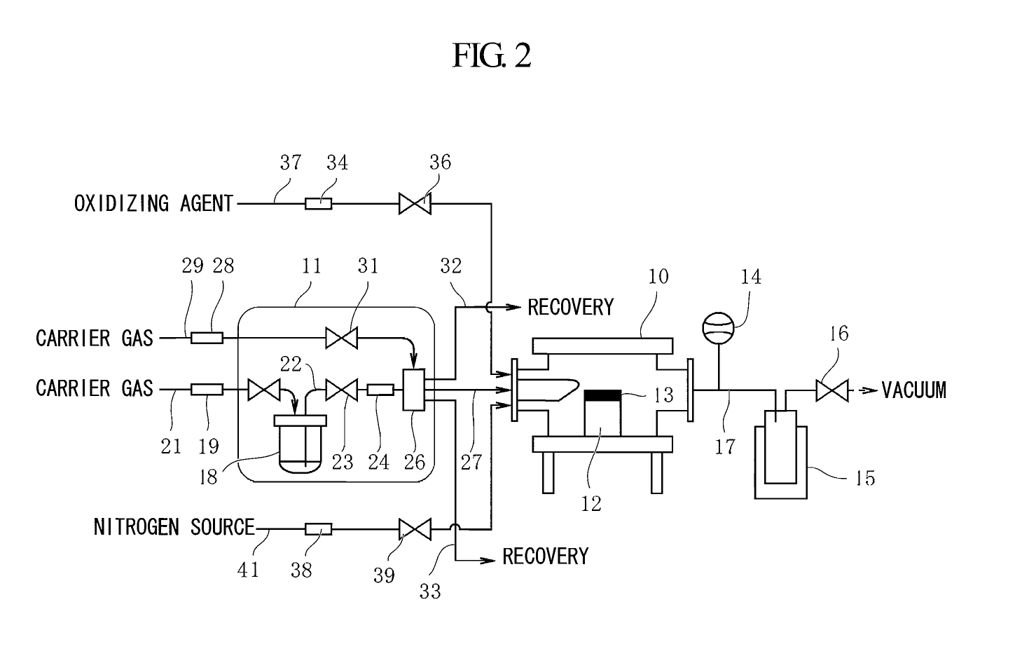

In addition, as shown in FIG. 2, a nitrogen source supplying pipe 41 is connected via a needle valve 39 and a gas regulator 38 to the film forming chamber 10. According to this configuration, a nitrogen source is directly supplied to the film forming chamber 10 to form a HfSiON thin film. Examples of the nitrogen source include N₂, NH₃, and the like.

Other method for manufacturing composite oxide film containing Hf-Si of the invention will be described.

When a state leaving a substrate, for example a silicon substrate, in the air is kept, oxygen in the air reacts with Si on the substrate surface to naturally form an oxide film (SiO₂) on a surface of the substrate. When the composite oxide film containing Hf-Si is formed on a surface having the naturally formed oxide film, a problem arises in that the inferior adhesivity of the composite oxide film containing Hf-Si occurs.

Therefore, in the other method for manufacturing composite oxide film containing Hf-Si of the invention, the organic Si compound is primarily thermally decomposed with a reducing gas to grow a Si film on a surface of the substrate. Specifically, the Si film is grown on a SiO₂ surface formed on the Si substrate surface. A surface layer of the Si film grown on a surface of the substrate is thought to be in a Si—H structure, and it is assumed that this Si—H structure contributes to an adhesion improvement when forming the Hf-Si film containing composite oxide film in the process that will be continued after. The specific reason is thought as that when the Si—H grown on the surface of the substrate reacts with the initial film-forming core formed by thermally decomposing the intermediate in the raw material solution to easily modify the initial film-forming core on the surface of the substrate, and subsequently the formed HfSiO gets closer to the heated substrate, HfSiO starts to deposit mainly from the Si—H modified on the surface of the substrate and the initial film-forming core, and thus the HfSiO film having a high adhesivity is obtained. The organic Si compound used for growing the Si film may have same or different composition from the organic Si compound used for the raw material solution for MOCVD of the invention. Also, the reducing gas is preferably an H₂ gas. A film thickness of the growing Si film is from about 0.1 to 10 nm, and preferably is 2 nm so as to observe its full effect.

Subsequently, the above-mentioned raw material solution for MOCVD method of the invention is supplied with the oxidizing agent and thermally decomposed to form the HfSiO film on a surface where the Si film is grown. As the oxidizing agent, O₂, H₂O₂, N₂O, and the like can be used. In this way of forming the HfSiO film on the surface of the Si film after growing the Si film on the surface of the substrate, interlayer of the Si substrate and the HfSiO film is stably formed.

Also, the above-mentioned raw material solution for MOCVD method of the invention is supplied together with the oxidizing agent and the nitrogen source and then thermally decomposed to form the HfSiON thin film. As the nitrogen source, N₂ and NH₃ are used.

### EXAMPLES

Hereinafter, Examples of the invention will be described in details with reference to Comparative Examples.

### Example 1

Hf(t-C₃H₇O)₄ and Si[(C₂H₅)₂N]₄ were prepared as the organic Hf compound and the organic Si compound, respectively. Next, the organic Hf compound and the organic Si compound were mixed at a room temperature in a ratio such that the weight ratio (organic Hf compound/organic Si compound) is 0.001 wt %, and the organic Hf compound was dissolved in the organic Si compound to prepare a single solution of the raw material solution for MOCVD method. Also, total of five raw material solutions for MOCVD method which differ in mixing ratio were prepared by respectively changing the mixing ratio of the organic Hf compound and the organic Si compound to 0.01 wt %, 0.1 wt %, 0.2 wt %, and 0.5 wt % in a weight ratio (organic Hf compound/organic Si compound).

Subsequently, Hf-Si—O thin films were formed respectively by using the prepared five raw material solutions for MOCVD method. In specific, at first, five silicon substrates having a SiO₂ film (thickness of 5000 Å) on each surface were respectively prepared as substrates, and the substrates were installed in the film forming chamber of the MOCVD apparatus shown in FIG. 1. Then, a substrate temperature, a vaporization temperature and a pressure were set to 600° C., 70° C., and about 266 Pa (2 torr), respectively. O₂ gas was used as a reactant gas and its partial pressure was set at 1000 ccm. Ar gas was used as a carrier gas, and the raw material solutions for MOCVD method were fed at a rate of 0.1 g/min, respectively. The substrates were taken out by one from the film forming chamber when the film formation time reached 1 minute, 2 minutes, 3 minutes, 4 minutes, and 5 minutes, respectively.

### Example 2

Five raw material solutions for MOCVD method which differ in mixing ratio were respectively prepared in the same manner as in Example 1 except that the organic Si compound was changed to SiH[(CH₃)₂N]₃, and the Hf-Si—O thin film was formed on a substrate in the same manner as in Example 1.

### Example 3

Five raw material solutions for MOCVD method which differ in mixing ratio were respectively prepared in the same manner as in Example 1 except that the organic Si compound was changed to Si[(CH₃)₂N]₄, and the Hf-Si—O thin film was formed on a substrate in the same manner as in Example 1.

### Comparative Example 1

Hf(t-C₃H₇O)₄ and Si[(C₂H₅)₂N]₄ were prepared as the organic Hf compound and the organic Si compound, respectively, and these organic Si compound and the organic Hf compound were respectively used as the raw material solutions for MOCVD method. That is, two solutions were used as the raw material solutions for MOCVD by individually preparing each solution of the organic Si compound and the organic Hf compound.

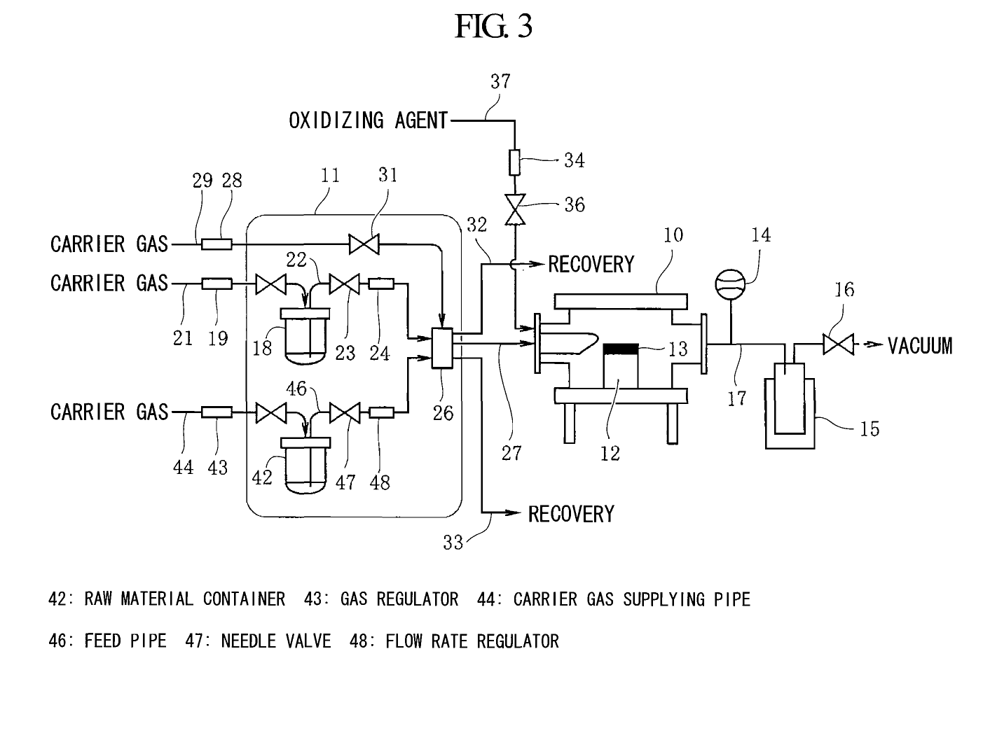

Subsequently, Hf-Si—O thin films were formed by using the prepared raw material solutions for MOCVD method. In specific, at first, five silicon substrates having a SiO₂ film (thickness of 5000 Å) formed on each surface were respectively prepared as substrates, and the substrates were installed in the film forming chamber of the MOCVD apparatus shown in FIG. 3. The organic Si compound raw material solution and the organic Hf compound raw material solution were stored and sealed in the raw material container 18 and the raw material container 42, respectively. A carrier gas supplying pipe 44 was connected via a gas regulator 43 to the raw material container 42 shown in the FIG. 3. A needle valve 47 and a flow rate regulator 48 were arranged in a feed pipe 46 and the feed pipe 46 was connected to a vaporizer 26. Then, a substrate temperature, a vaporization temperature and a pressure were set to 600° C., 70° C., and about 266 Pa (2 torr), respectively. O₂ gas was used as a reactant gas and its partial pressure was set at 1000 ccm. Ar gas was used as a carrier gas, and individual raw material solutions of the organic Si compound and the organic Hf compound were fed respectively. The substrates were taken out by one from the film forming chamber when the film formation time reached 1 minute, 2 minutes, 3 minutes, 4 minutes, and 5 minutes, respectively. Supplying ratio of the organic Si compound and the organic Hf compound raw material solutions during forming the film was changed to form a Hf-Si—O thin film having a same composition to the Hf-Si—O thin film formed by using the five raw material solutions for MOCVD method which differ in mixing ratio in Examples 1 to 3.

<Comparative Test 1>

For each obtained Hf-Si—O thin film according to Examples 1 to 3 and Comparative Example 1, a film thickness test, and a peel test to examine adhesivity, per film formation time of the obtained Hf-Si—O thin film were carried out.

(1) A Film Thickness Test

The film thickness of the Hf-Si—O thin film on the film-formed substrate was determined from a cross-sectional scanning electron microscope image.

(2) A Peel Test

Each thin film formed on a flat portion of the film-formed substrate was subjected to following peel test. At first each thin film formed on a substrate was cut by using a cutter in a predetermined size to prepare 100 cut grids. Then, adhesive cellophane tape was adhered on the thin-film prepared in girds. The tape was peeled off from the thin film, and respectively examined the number peeled off by the tape and the number remained on the substrate among the thin film cut in 100 girds.

<Evaluation>

Obtained results of the film thickness and the peel test per film formation time are respectively shown in tables 1 and 2. The peel test shows the number of remaining substrates per 100 pieces of cut grid.

TABLE 1

| | Organic Hf | | | | | | | | | | | |
|---|---|---|---|---|---|---|---|---|---|---|---|---|
| | compound | Mixing | Film thickness per film | | | | | Peel test | | | | |
| | & organic Si | ratio | formation time [nm] | | | | | [a piece/100 pieces] | | | | |
| | compound | [wt %] | 1 min. | 2 min. | 3 min. | 4 min. | 5 min. | 1 min. | 2 min. | 3 min. | 4 min. | 5 min. |
| Ex. 1 | Hf(t-C₃H₇O)₄ | 0.001 | 15 | 30 | 42 | 61 | 70 | 97 | 99 | 98 | 100 | 97 |
| | Si[(C₂H₅)₂N]₄ | 0.01 | 16 | 30 | 50 | 60 | 79 | 96 | 99 | 99 | 96 | 98 |
| | | 0.1 | 20 | 40 | 58 | 79 | 99 | 99 | 100 | 98 | 97 | 96 |
| | | 0.2 | 21 | 40 | 65 | 80 | 100 | 99 | 100 | 99 | 96 | 95 |
| | | 0.5 | 40 | 79 | 118 | 150 | 210 | 95 | 99 | 98 | 97 | 100 |
| Ex. 2 | Hf(t-C₃H₇O)₄ | 0.001 | 20 | 40 | 60 | 79 | 99 | 96 | 97 | 98 | 99 | 98 |
| | SiH[(CH₃)₂N]₃ | 0.01 | 15 | 30 | 42 | 60 | 75 | 95 | 94 | 93 | 92 | 95 |
| | | 0.1 | 30 | 60 | 90 | 118 | 153 | 93 | 94 | 99 | 100 | 98 |
| | | 0.2 | 40 | 75 | 112 | 151 | 198 | 98 | 100 | 98 | 97 | 99 |
| | | 0.5 | 60 | 120 | 170 | 241 | 300 | 99 | 98 | 100 | 96 | 97 |
| Ex. 3 | Hf(t-C₃H₇O)₄ | 0.001 | 10 | 21 | 30 | 41 | 53 | 97 | 96 | 99 | 100 | 96 |
| | Si[(CH₃)₂N]₄ | 0.01 | 18 | 40 | 51 | 70 | 89 | 93 | 92 | 95 | 98 | 99 |
| | | 0.1 | 25 | 50 | 72 | 100 | 125 | 100 | 99 | 100 | 96 | 96 |
| | | 0.2 | 32 | 64 | 90 | 121 | 161 | 97 | 99 | 100 | 97 | 96 |
| | | 0.5 | 50 | 101 | 151 | 203 | 248 | 99 | 100 | 97 | 96 | 99 |
| Comp. | Hf(t-C₃H₇O)₄ | 0.001 | 0.1 | 0.2 | 0.3 | 0.4 | 0.4 | 58 | 50 | 55 | 40 | 32 |
| Ex. 1 | Si[(C₂H₅)₂N]₄ | 0.01 | 0.15 | 0.3 | 0.4 | 0.5 | 0.5 | 50 | 51 | 56 | 38 | 32 |
| | | 0.1 | 0.2 | 0.4 | 0.5 | 0.6 | 0.7 | 60 | 53 | 57 | 35 | 30 |
| | | 0.2 | 0.5 | 1.0 | 1.2 | 1.6 | 1.8 | 52 | 58 | 58 | 32 | 33 |
| | | 0.5 | 0.9 | 1.8 | 1.5 | 1.6 | 1.6 | 55 | 55 | 60 | 33 | 32 |

As clearly shown in the table 1, the films formed by using two raw material solutions according to Comparative Example 1 did not increase much in film thickness as time increases, and it was clear that the film formation is unstable. Correspondingly, the films formed by using the single solution according to Examples 1 to 3 had a significantly high film forming rate in comparison with Comparative Example 1, and stable film formation was obtained. In addition, according to the peel test, almost half of the grids were peeled off in the film formed by using the two raw material solutions according to Comparative Example 1, while most of the grids were remained on the substrate in films formed by using the single raw material solution according to Examples 1 to 3 and thus high adhesivity results were obtained.

### Example 4

Five raw material solutions for MOCVD method which differ in mixing ratio used in Example 1 were prepared to form a Hf-Si—O thin film. In specific, first, five silicon substrates having a SiO₂ film (thickness of 5000 Å) on each surface were respectively prepared as substrates, and the substrates were installed in the film forming chamber of the MOCVD apparatus shown in FIG. 1. Then, the substrate temperature, the vaporization temperature and the pressure were set to 600° C., 70° C., and about 266 Pa (2 torr), respectively. H₂ gas was used as a reducing gas and its partial pressure was set at 1 ccm. Ar gas was used as a carrier gas. Si[(C₂H₅)₂N]₄ was respectively fed as the organic Si compound at a rate of 0.1 g/min, and Si[(C₂H₅)₂N]₄ was thermally decomposed to grow the Si film on a surface of the substrate. Supply of the organic Si compound and the reducing gas was stopped when the film formation time reached 2 minutes. Next, O₂ gas was used as a reactant gas and its partial pressure was set at 1000 ccm. Ar gas was used as a carrier gas, and the raw material solutions for MOCVD method were respectively fed at a rate of 0.1 g/min to form the Hf-Si—O film on a surface of the grown Si film. The substrates were taken out by one from the film forming chamber when the film formation time reached 1 minute, 2 minutes, 3 minutes, 4 minutes, and 5 minutes, respectively.

### Comparative Example 2

Two solutions used in Comparative Example 1 were prepared as the raw material solutions for MOCVD by individually preparing the organic Si compound and the organic Hf compound.

Subsequently, Hf-Si—O thin films were formed by using the prepared raw material solutions for MOCVD method. In specific, at first, five silicon substrates having a SiO₂ film (thickness of 5000 Å) formed on each surface were respectively prepared as substrates, and the substrates were installed in the film forming chamber of the MOCVD apparatus shown in FIG. 3. The organic Si compound raw material solution and the organic Hf compound raw material solution were stored and sealed in the raw material container 18 and the raw material container 42, respectively. Then, a substrate temperature, a vaporization temperature and a pressure were set to 600° C., 70° C., and about 266 Pa (2 torr), respectively. H₂ gas was used as a reducing gas and its partial pressure was set at 1 ccm. Ar gas was used as a carrier gas.

Si[(C₂H₅)₂N]₄ was respectively fed as the organic Si compound at a rate of 0.1 g/min, and Si[(C₂H₅)₂N]₄ was thermally decomposed to grow the Si film on a surface of the substrate. Supply of the organic Si compound and the reducing gas was stopped when the film formation time reached 2 minutes. Next, O₂ gas was used as a reactant gas and its partial pressure was set at 1000 ccm. Ar gas was used as a carrier gas, and individual raw material solutions of the organic Si compound and the organic Hf compound were respectively fed to form the Hf-Si—O thin film on a surface of the grown Si film. The substrates were taken out by one from the film forming chamber when the film formation time reached 1 minute, 2 minutes, 3 minutes, 4 minutes, and 5 minutes, respectively. Supplying ratio of the organic Si compound and the organic Hf compound raw material solutions during forming the film was changed to form a Hf-Si—O thin film having a same composition to the Hf-Si—O thin film formed by using the five raw material solutions for MOCVD method which differ in mixing ratio in Example 4.

<Comparative Test 2>

For each obtained Hf-Si—O thin film according to Example 4 and Comparative Example 2, a film thickness test, and a peel test to examine adhesivity, per film formation time of the obtained Hf-Si—O thin film were carried out in the same manner as in above-mentioned Comparative Test 1.

<Evaluation>

Obtained results of the film thickness and the peel test per film formation time are respectively shown in table 2. The peel test shows the number of remaining substrates per 100 pieces of cut grid.

TABLE 2

| | Organic Hf | | | | | | | | | | | |
|---|---|---|---|---|---|---|---|---|---|---|---|---|
| | compound | Mixing | Film thickness per film | | | | | Peel test | | | | |
| | & organic Si | ratio | formation time [nm] | | | | | [a piece/100 pieces] | | | | |
| | compound | [wt %] | 1 min. | 2 min. | 3 min. | 4 min. | 5 min. | 1 min. | 2 min. | 3 min. | 4 min. | 5 min. |
| Ex. 4 | Hf(t-C₃H₇O)₄ | 0.001 | 18 | 36 | 54 | 72 | 90 | 99 | 98 | 97 | 99 | 98 |
| | Si[(C₂H₅)₂N]₄ | 0.01 | 20 | 40 | 60 | 81 | 103 | 100 | 98 | 99 | 97 | 96 |
| | | 0.1 | 25 | 51 | 75 | 99 | 118 | 99 | 98 | 99 | 100 | 100 |
| | | 0.2 | 30 | 60 | 83 | 112 | 140 | 100 | 99 | 98 | 100 | 98 |
| | | 0.5 | 42 | 84 | 120 | 83 | 200 | 97 | 96 | 99 | 100 | 98 |
| Comp. | Hf(t-C₃H₇O)₄ | 0.001 | 0.1 | 0.2 | 0.3 | 0.3 | 0.4 | 58 | 56 | 61 | 40 | 40 |
| Ex. 2 | Si[(C₂H₅)₂N]₄ | 0.01 | 0.2 | 0.3 | 0.4 | 0.5 | 0.5 | 59 | 58 | 60 | 41 | 30 |
| | | 0.1 | 0.9 | 1.4 | 1.5 | 1.6 | 1.6 | 60 | 60 | 58 | 42 | 38 |
| | | 0.2 | 1.1 | 1.9 | 3.2 | 3.0 | 2.4 | 61 | 62 | 60 | 38 | 32 |
| | | 0.5 | 0.8 | 1.2 | 1.8 | 1.9 | 1.9 | 58 | 58 | 62 | 40 | 30 |

As clearly shown in the table 2, the films formed by using two raw material solutions according to Comparative Example 2 did not increase much in film thickness as time increases, and it was clear that the film formation is unstable. Also, only the low values in the peel test were obtained meaning a result of some decrease in adhesivity. Correspondingly, the films formed by using the single solution according to Examples 4 had a significantly high film forming rate in comparison with Comparative Example 2, and stable film formation was obtained. Furthermore, films having excellent adhesivity were obtained.

### Examples 5 to 8

Five raw material solutions for MOCVD method which differ in mixing ratio were respectively prepared in the same manner as in Example 1 to form Hf-Si—O thin films on substrates in the same manner as in Example 1, except that Si[(CH₃)₂N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 9 to 12

Five raw material solutions for MOCVD method which differ in mixing ratio were respectively prepared in the same manner as in Example 1 to form Hf-Si—O thin films on substrates in the same manner as in Example 1, except that Hf(CH₃O)₄, Hf(C₂H₅O)₄, Hf(n-C₃H₇O)₄ and Hf(n-C₄H₉O)₄ were used as the organic Hf compound.

### Examples 13 to 16

Five raw material solutions for MOCVD method which differ in mixing ratio were respectively prepared in the same manner as in Example 1 to form Hf-Si—O thin films on substrates in the same manner as in Example 1, except that Si[(n-C₃H₇)₂N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 17 to 20

Five raw material solutions for MOCVD method which differ in mixing ratio were respectively prepared in the same manner as in Example 1 to form Hf-Si—O thin films on substrates in the same manner as in Example 1, except that Si[(n-C₄H₉)₂N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 21 to 24

Five raw material solutions for MOCVD method which differ in mixing ratio were respectively prepared in the same manner as in Example 1 to form Hf-Si—O thin films on substrates in the same manner as in Example 1, except that Si[(CH₃)(C₂H₅)N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 25 to 28

Five raw material solutions for MOCVD method which differ in mixing ratio were respectively prepared in the same manner as in Example 1 to form Hf-Si—O thin films on substrates in the same manner as in Example 1, except that Si[(CH₃)(n-C₃H₇)N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 29 to 32

Five raw material solutions for MOCVD method which differ in mixing ratio were respectively prepared in the same manner as in Example 1 to form Hf-Si—O thin films on substrates in the same manner as in Example 1, except that Si[(CH₃)(n-C₄H₉)N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 33 to 36

Five raw material solutions for MOCVD method which differ in mixing ratio were respectively prepared in the same manner as in Example 1 to form Hf-Si—O thin films on substrates in the same manner as in Example 1, except that Si[(C₂H₅)(n-C₃H₇)N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 37 to 40

Five raw material solutions for MOCVD method which differ in mixing ratio were respectively prepared in the same manner as in Example 1 to form Hf-Si—O thin films on substrates in the same manner as in Example 1, except that Si[(C₂H₅)(n-C₄H₉)N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

<Comparative Test 3>

For each obtained Hf-Si—O thin film according to Examples 5 to 40, a film thickness test, and a peel test to examine adhesivity, per film formation time of the obtained Hf-Si—O thin film were carried out in the same manner as in the above-mentioned Comparative Test 1.

<Evaluation>

Obtained results of the film thickness and the peel test per film formation time are respectively shown in tables 3 to 11. The peel test shows the number of remaining substrates per 100 pieces of cut grid.

TABLE 3
Silicon substrate - HfSiO thin film

| | Organic Hf | | | | | | | | | | | |
|---|---|---|---|---|---|---|---|---|---|---|---|---|
| Raw | compound | Mixing | Film thickness per film | | | | | Peel test | | | | |
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 5 | Single | Hf(CH₃O)₄ | 0.001 | 13 | 30 | 40 | 60 | 72 | 90 to 92 |
| | solution | Si[(CH₃)₂N]₄ | 0.01 | 16 | 30 | 48 | 63 | 78 | |
| | | | 0.1 | 20 | 38 | 60 | 70 | 98 | |
| | | | 0.2 | 25 | 36 | 60 | 79 | 101 | |
| | | | 0.5 | 43 | 70 | 120 | 140 | 200 | |
| Ex. 6 | Single | Hf(C₂H₅O)₄ | 0.001 | 10 | 20 | 58 | 80 | 96 | 95 to 96 |
| | solution | Si[(CH₃)₂N]₄ | 0.01 | 20 | 39 | 40 | 60 | 70 | |
| | | | 0.1 | 28 | 48 | 88 | 117 | 140 | |
| | | | 0.2 | 30 | 60 | 110 | 149 | 150 | |
| | | | 0.5 | 33 | 100 | 130 | 150 | 200 | |
| Ex. 7 | Single | Hf(n-C₃H₇O)₄ | 0.001 | 20 | 32 | 36 | 48 | 56 | 94 to 95 |
| | solution | Si[(CH₃)₂N]₄ | 0.01 | 18 | 40 | 50 | 73 | 90 | |
| | | | 0.1 | 30 | 60 | 70 | 120 | 130 | |
| | | | 0.2 | 40 | 70 | 88 | 130 | 156 | |
| | | | 0.5 | 56 | 101 | 120 | 192 | 208 | |
| Ex. 8 | Single | Hf(n-C₄H₉O)₄ | 0.001 | 13 | 21 | 40 | 62 | 73 | 99 to 100 |
| | solution | Si[(CH₃)₂N]₄ | 0.01 | 21 | 38 | 48 | 60 | 79 | |
| | | | 0.1 | 28 | 48 | 60 | 70 | 89 | |
| | | | 0.2 | 32 | 60 | 68 | 81 | 100 | |
| | | | 0.5 | 41 | 110 | 120 | 130 | 200 | |

TABLE 4
Silicon substrate - HfSiO thin film

| | Organic Hf | | Film thickness per film | | | | | Peel test | | | | |
|---|---|---|---|---|---|---|---|---|---|---|---|---|
| Raw | compound | Mixing | formation time [nm] | | | | | [a piece/100 pieces] | | | | |
| material | & organic Si | ratio | 1 | | | | | | | | | 5 |
| solution | compound | [wt %] | min. | 2 min. | 3 min. | 4 min. | 5 min. | 1 min. | 2 min. | 3 min. | 4 min. | min. |

| | | | | | | | | | |
|---|---|---|---|---|---|---|---|---|---|
| Ex. 9 | Single | Hf(CH₃O)₄ | 0.001 | 14 | 32 | 43 | 68 | 74 | 90 to 92 |
| | solution | Si[(C₂H₅)₂N]₄ | 0.01 | 18 | 32 | 50 | 69 | 80 | |
| | | | 0.1 | 21 | 39 | 63 | 78 | 90 | |
| | | | 0.2 | 29 | 40 | 58 | 77 | 99 | |
| | | | 0.5 | 45 | 73 | 127 | 147 | 201 | |
| Ex. 10 | Single | Hf(C₂H₅O)₄ | 0.001 | 12 | 22 | 60 | 78 | 90 | 95 to 96 |
| | solution | Si[(C₂H₅)₂N]₄ | 0.01 | 23 | 44 | 49 | 61 | 73 | |
| | | | 0.1 | 29 | 50 | 90 | 116 | 138 | |
| | | | 0.2 | 31 | 63 | 112 | 138 | 160 | |
| | | | 0.5 | 32 | 98 | 131 | 149 | 201 | |
| Ex. 11 | Single | Hf(n-C₃H₇O)₄ | 0.001 | 23 | 35 | 38 | 48 | 59 | 96 to 98 |
| | solution | Si[(C₂H₅)₂N]₄ | 0.01 | 17 | 40 | 49 | 70 | 89 | |
| | | | 0.1 | 31 | 61 | 68 | 119 | 131 | |
| | | | 0.2 | 40 | 68 | 90 | 129 | 160 | |
| | | | 0.5 | 58 | 110 | 127 | 189 | 201 | |
| Ex. 12 | Single | Hf(n-C₄H₉O)₄ | 0.001 | 14 | 22 | 43 | 68 | 75 | 99 to 100 |
| | solution | Si[(C₂H₅)₂N]₄ | 0.01 | 23 | 40 | 45 | 61 | 80 | |
| | | | 0.1 | 28 | 47 | 61 | 72 | 90 | |
| | | | 0.2 | 32 | 56 | 67 | 81 | 98 | |
| | | | 0.5 | 43 | 110 | 128 | 140 | 210 | |

TABLE 5
Silicon substrate - HfSiO thin film

| | Organic Hf | | | | | | | | | | | |
|---|---|---|---|---|---|---|---|---|---|---|---|---|
| Raw | compound | Mixing | Film thickness per film | | | | | Peel test | | | | |
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 13 | Single solution | Hf(CH₃O)₄ | 0.001 | 15 | 31 | 41 | 61 | 72 | 90 to 92 |
| | | Si[(n-C₃H₇)₂N]₄ | 0.01 | 18 | 32 | 49 | 64 | 75 | |
| | | | 0.1 | 22 | 40 | 62 | 71 | 98 | |
| | | | 0.2 | 26 | 37 | 62 | 75 | 101 | |
| | | | 0.5 | 44 | 72 | 122 | 132 | 201 | |
| Ex. 14 | Single | Hf(C₂H₅O)₄ | 0.001 | 11 | 21 | 59 | 82 | 95 | 95 to 96 |
| | solution | Si[(n-C₃H₇)₂N]₄ | 0.01 | 25 | 40 | 42 | 63 | 72 | |
| | | | 0.1 | 30 | 49 | 89 | 110 | 142 | |
| | | | 0.2 | 31 | 61 | 111 | 140 | 150 | |
| | | | 0.5 | 37 | 102 | 132 | 152 | 201 | |
| Ex. 15 | Single | Hf(n-C₃H₇O)₄ | 0.001 | 21 | 33 | 37 | 49 | 57 | 96 to 98 |
| | solution | Si[(n-C₃H₇)₂N]₄ | 0.01 | 19 | 42 | 50 | 74 | 99 | |
| | | | 0.1 | 30 | 63 | 71 | 121 | 132 | |
| | | | 0.2 | 41 | 72 | 98 | 135 | 157 | |
| | | | 0.5 | 57 | 101 | 113 | 192 | 200 | |
| Ex. 16 | Single | Hf(n-C₄H₉O)₄ | 0.001 | 14 | 22 | 40 | 62 | 74 | 99 to 100 |
| | solution | Si[(n-C₃H₇)₂N]₄ | 0.01 | 22 | 38 | 45 | 60 | 79 | |
| | | | 0.1 | 29 | 50 | 62 | 73 | 88 | |
| | | | 0.2 | 33 | 61 | 65 | 80 | 100 | |
| | | | 0.5 | 42 | 112 | 119 | 131 | 201 | |

TABLE 6
Silicon substrate - HfSiO thin film

| | Organic Hf | | | | | | | | | | | |
|---|---|---|---|---|---|---|---|---|---|---|---|---|
| Raw | compound | Mixing | Film thickness per film | | | | | Peel test | | | | |
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 17 | Single solution | Hf(CH₃O)₄ | 0.001 | 14 | 30 | 40 | 60 | 70 | 90 to 92 |
| | | Si[(n-C₄H₉)₂N]₄ | 0.01 | 20 | 30 | 49 | 70 | 89 | |
| | | | 0.1 | 20 | 40 | 60 | 80 | 98 | |
| | | | 0.2 | 30 | 41 | 60 | 75 | 100 | |
| | | | 0.5 | 48 | 76 | 120 | 150 | 198 | |
| Ex. 18 | Single | Hf(C₂H₅O)₄ | 0.001 | 13 | 24 | 56 | 80 | 98 | 98 to 99 |
| | solution | Si[(n-C₄H₉)₂N]₄ | 0.01 | 20 | 40 | 50 | 58 | 68 | |
| | | | 0.1 | 30 | 45 | 89 | 120 | 141 | |
| | | | 0.2 | 34 | 60 | 110 | 140 | 158 | |
| | | | 0.5 | 30 | 100 | 121 | 151 | 200 | |
| Ex. 19 | Single | Hf(n-C₃H₇O)₄ | 0.001 | 20 | 40 | 51 | 62 | 88 | 98 to 99 |
| | solution | Si[(n-C₄H₉)₂N]₄ | 0.01 | 20 | 39 | 49 | 67 | 90 | |
| | | | 0.1 | 31 | 49 | 67 | 100 | 121 | |
| | | | 0.2 | 40 | 70 | 88 | 130 | 159 | |
| | | | 0.5 | 59 | 109 | 117 | 179 | 207 | |
| Ex. 20 | Single | Hf(n-C₄H₉O)₄ | 0.001 | 13 | 20 | 56 | 69 | 70 | 99 to 100 |
| | solution | Si[(n-C₄H₉)₂N]₄ | 0.01 | 23 | 38 | 47 | 68 | 90 | |
| | | | 0.1 | 29 | 50 | 60 | 68 | 91 | |
| | | | 0.2 | 31 | 60 | 67 | 79 | 100 | |
| | | | 0.5 | 40 | 99 | 117 | 127 | 156 | |

TABLE 7
Silicon substrate - HfSiO thin film

| | Organic Hf | | | | | | | | | | | |
|---|---|---|---|---|---|---|---|---|---|---|---|---|
| Raw | compound | | Film thickness per film | | | | | Peel test | | | | |
| material | & organic Si | Mixing | formation time [nm] | | | | | [a piece/100 pieces] | | | | |
| solution | compound | ratio [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 21 | Single | Hf(CH₃O)₄ | 0.001 | 15 | 33 | 43 | 69 | 73 | 90 to 92 |
| | solution | Si[(CH₃)(C₂H₅)N]₄ | 0.01 | 18 | 33 | 50 | 72 | 81 | |
| | | | 0.1 | 20 | 40 | 64 | 78 | 92 | |
| | | | 0.2 | 30 | 42 | 58 | 79 | 99 | |
| | | | 0.5 | 46 | 74 | 127 | 149 | 202 | |
| Ex. 22 | Single | Hf(C₂H₅O)₄ | 0.001 | 13 | 23 | 61 | 80 | 93 | 95 to 96 |
| | solution | Si[(CH₃)(C₂H₅)N]₄ | 0.01 | 24 | 45 | 50 | 62 | 74 | |
| | | | 0.1 | 30 | 55 | 92 | 112 | 140 | |
| | | | 0.2 | 30 | 62 | 113 | 142 | 162 | |
| | | | 0.5 | 30 | 99 | 132 | 150 | 202 | |
| Ex. 23 | Single | Hf(n-C₃H₇O)₄ | 0.001 | 20 | 36 | 39 | 50 | 60 | 95 to 96 |
| | solution | Si[(CH₃)(C₂H₅)N]₄ | 0.01 | 18 | 42 | 50 | 72 | 90 | |
| | | | 0.1 | 30 | 63 | 69 | 119 | 141 | |
| | | | 0.2 | 42 | 69 | 92 | 130 | 162 | |
| | | | 0.5 | 59 | 110 | 128 | 192 | 200 | |
| Ex. 24 | Single | Hf(n-C₄H₉O)₄ | 0.001 | 15 | 23 | 44 | 69 | 76 | 98 to 99 |
| | solution | Si[(CH₃)(C₂H₅)N]₄ | 0.01 | 24 | 38 | 45 | 63 | 81 | |
| | | | 0.1 | 29 | 45 | 63 | 73 | 92 | |
| | | | 0.2 | 33 | 57 | 69 | 82 | 99 | |
| | | | 0.5 | 44 | 112 | 128 | 141 | 203 | |

TABLE 8
Silicon substrate - HfSiO thin film

| Raw | | Mixing | Film thickness per film | | | | | Peel test | | | | |
|---|---|---|---|---|---|---|---|---|---|---|---|---|
| material | Organic Hf compound | ratio | formation time [nm] | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 25 | Single | Hf(CH₃O)₄ | 0.001 | 17 | 32 | 43 | 58 | 69 | 93 to 94 |
| | solution | Si[(CH₃)(n-C₃H₇)N]₄ | 0.01 | 20 | 30 | 50 | 68 | 90 | |
| | | | 0.1 | 27 | 40 | 57 | 79 | 97 | |
| | | | 0.2 | 30 | 40 | 59 | 70 | 90 | |
| | | | 0.5 | 45 | 78 | 117 | 146 | 201 | |
| Ex. 26 | Single | Hf(C₂H₅O)₄ | 0.001 | 14 | 20 | 57 | 69 | 95 | 95 to 96 |
| | solution | Si[(CH₃)(n-C₃H₇)N]₄ | 0.01 | 20 | 43 | 56 | 59 | 67 | |
| | | | 0.1 | 30 | 40 | 79 | 101 | 127 | |
| | | | 0.2 | 29 | 45 | 79 | 110 | 122 | |
| | | | 0.5 | 40 | 68 | 90 | 120 | 140 | |
| Ex. 27 | Single | Hf(n-C₃H₇O)₄ | 0.001 | 20 | 42 | 50 | 60 | 90 | 95 to 96 |
| | solution | Si[(CH₃)(n-C₃H₇)N]₄ | 0.01 | 14 | 31 | 43 | 58 | 69 | |
| | | | 0.1 | 30 | 42 | 56 | 62 | 69 | |
| | | | 0.2 | 37 | 63 | 80 | 93 | 120 | |
| | | | 0.5 | 60 | 110 | 120 | 180 | 193 | |
| Ex. 28 | Single | Hf(n-C₄H₉O)₄ | 0.001 | 18 | 40 | 49 | 60 | 90 | 95 to 96 |
| | solution | Si[(CH₃)(n-C₃H₇)N]₄ | 0.01 | 20 | 42 | 50 | 60 | 88 | |
| | | | 0.1 | 29 | 50 | 62 | 92 | 101 | |
| | | | 0.2 | 30 | 48 | 62 | 92 | 120 | |
| | | | 0.5 | 38 | 90 | 110 | 120 | 149 | |

TABLE 9
Silicon substrate - HfSiO thin film

| Raw | | Mixing | Film thickness per film | | | | | Peel test [a piece/100 | | | | |
|---|---|---|---|---|---|---|---|---|---|---|---|---|
| material | Organic Hf compound | ratio | formation time [nm] | | | | | pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 29 | Single | Hf(CH₃O)₄ | 0.001 | 15 | 31 | 42 | 62 | 72 | 92 to 94 |
| | solution | Si[(CH₃)(n-C₄H₉)N]₄ | 0.01 | 22 | 32 | 50 | 70 | 90 | |
| | | | 0.1 | 23 | 41 | 62 | 81 | 98 | |
| | | | 0.2 | 31 | 42 | 62 | 76 | 110 | |
| | | | 0.5 | 50 | 77 | 130 | 151 | 192 | |
| Ex. 30 | Single | Hf(C₂H₅O)₄ | 0.001 | 14 | 25 | 57 | 82 | 99 | 90 to 92 |
| | solution | Si[(CH₃)(n-C₄H₉)N]₄ | 0.01 | 22 | 41 | 57 | 59 | 69 | |
| | | | 0.1 | 31 | 46 | 90 | 120 | 151 | |
| | | | 0.2 | 35 | 61 | 120 | 141 | 159 | |
| | | | 0.5 | 31 | 102 | 122 | 151 | 201 | |
| Ex. 31 | Single | Hf(n-C₃H₇O)₄ | 0.001 | 21 | 42 | 52 | 62 | 89 | 92 to 94 |
| | solution | Si[(CH₃)(n-C₄H₉)N]₄ | 0.01 | 23 | 40 | 50 | 67 | 91 | |
| | | | 0.1 | 32 | 50 | 67 | 110 | 122 | |
| | | | 0.2 | 42 | 72 | 90 | 132 | 159 | |
| | | | 0.5 | 60 | 110 | 120 | 180 | 207 | |
| Ex. 32 | Single | Hf(n-C₄H₉O)₄ | 0.001 | 14 | 21 | 56 | 70 | 72 | 95 to 96 |
| | solution | Si[(CH₃)(n-C₄H₉)N]₄ | 0.01 | 22 | 40 | 47 | 70 | 92 | |
| | | | 0.1 | 29 | 51 | 62 | 92 | 93 | |
| | | | 0.2 | 32 | 62 | 66 | 80 | 101 | |
| | | | 0.5 | 42 | 98 | 110 | 127 | 160 | |

TABLE 10
Silicon substrate - HfSiO thin film

| Raw | | Mixing | Film thickness per film | | | | | Peel test | | | | |
|---|---|---|---|---|---|---|---|---|---|---|---|---|
| material | Organic Hf compound | ratio | formation time [nm] | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 33 | Single | Hf(CH₃O)₄ | 0.001 | 17 | 29 | 43 | 60 | 70 | 95 to 96 |
| | solution | Si[(C₂H₅)(n-C₃H₇)N]₄ | 0.01 | 21 | 38 | 48 | 70 | 88 | |
| | | | 0.1 | 30 | 43 | 61 | 81 | 100 | |
| | | | 0.2 | 31 | 39 | 60 | 70 | 90 | |
| | | | 0.5 | 43 | 80 | 119 | 138 | 200 | |
| Ex. 34 | Single | Hf(C₂H₅O)₄ | 0.001 | 14 | 18 | 60 | 70 | 89 | 96 to 97 |
| | solution | Si[(C₂H₅)(n-C₃H₇)N]₄ | 0.01 | 20 | 40 | 55 | 60 | 69 | |
| | | | 0.1 | 30 | 42 | 80 | 98 | 130 | |
| | | | 0.2 | 30 | 44 | 88 | 120 | 132 | |
| | | | 0.5 | 39 | 65 | 88 | 110 | 132 | |
| Ex. 35 | Single | Hf(n-C₃H₇O)₄ | 0.001 | 23 | 40 | 51 | 61 | 88 | 92 to 94 |
| | solution | Si[(C₂H₅)(n-C₃H₇)N]₄ | 0.01 | 14 | 29 | 40 | 56 | 69 | |
| | | | 0.1 | 31 | 43 | 60 | 69 | 82 | |
| | | | 0.2 | 36 | 63 | 81 | 95 | 118 | |
| | | | 0.5 | 66 | 121 | 132 | 189 | 201 | |
| Ex. 36 | Single | Hf(n-C₄H₉O)₄ | 0.001 | 20 | 41 | 53 | 58 | 70 | 92 to 94 |
| | solution | Si[(C₂H₅)(n-C₃H₇)N]₄ | 0.01 | 20 | 40 | 49 | 56 | 90 | |
| | | | 0.1 | 30 | 49 | 63 | 91 | 100 | |
| | | | 0.2 | 32 | 56 | 60 | 90 | 112 | |
| | | | 0.5 | 37 | 89 | 100 | 118 | 139 | |

TABLE 11
Silicon substrate - HfSiO thin film

| Raw | | Mixing | Film thickness per film | | | | | Peel test | | | | |
|---|---|---|---|---|---|---|---|---|---|---|---|---|
| material | Organic Hf compound | ratio | formation time [nm] | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 37 | Single | Hf(CH₃O)₄ | 0.001 | 18 | 32 | 43 | 62 | 73 | 94 to 100 |
| | solution | Si[(C₂H₅)(n-C₄H₉)N]₄ | 0.01 | 23 | 33 | 52 | 72 | 92 | |
| | | | 0.1 | 24 | 42 | 63 | 81 | 99 | |
| | | | 0.2 | 32 | 43 | 64 | 76 | 110 | |
| | | | 0.5 | 51 | 78 | 130 | 155 | 190 | |
| Ex. 38 | Single | Hf(C₂H₅O)₄ | 0.001 | 15 | 26 | 57 | 98 | 95 | 99 to 100 |
| | solution | Si[(C₂H₅)(n-C₄H₉)N]₄ | 0.01 | 23 | 42 | 57 | 63 | 65 | |
| | | | 0.1 | 32 | 47 | 93 | 121 | 142 | |
| | | | 0.2 | 36 | 62 | 120 | 145 | 150 | |
| | | | 0.5 | 33 | 102 | 124 | 152 | 200 | |
| Ex. 39 | Single | Hf(n-C₃H₇O)₄ | 0.001 | 22 | 43 | 53 | 62 | 85 | 98 to 99 |
| | solution | Si[(C₂H₅)(n-C₄H₉)N]₄ | 0.01 | 24 | 42 | 52 | 68 | 90 | |
| | | | 0.1 | 33 | 51 | 67 | 112 | 119 | |
| | | | 0.2 | 43 | 73 | 90 | 136 | 159 | |
| | | | 0.5 | 62 | 113 | 121 | 182 | 200 | |
| Ex. 40 | Single | Hf(n-C₄H₉O)₄ | 0.001 | 15 | 23 | 57 | 72 | 65 | 95 to 96 |
| | solution | Si[(C₂H₅)(n-C₄H₉)N]₄ | 0.01 | 25 | 42 | 47 | 75 | 93 | |
| | | | 0.1 | 30 | 53 | 63 | 66 | 95 | |
| | | | 0.2 | 33 | 63 | 66 | 80 | 100 | |
| | | | 0.5 | 43 | 99 | 110 | 121 | 154 | |

As clearly shown in the tables 3 to 11, the films formed by using the single raw material solution according to Examples 5 to 40 had a significantly high film forming rate in comparison with Comparative Example 1, and stable film formation was obtained. Also, in the peel test, most of grids were remained on substrates in films formed by using the raw material solution according to Examples 5 to 40 and thus high adhesivity results were obtained.

### Examples 41 to 44

Five raw material solutions for MOCVD method which differ in mixing ratio were respectively prepared in the same manner as in Example 1 so as to grow Si films on substrates and form Hf-Si—O thin films on surfaces of those Si films in the same manner as in Example 4, except that Si[(CH₃)₂N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 45 to 48

Five raw material solutions for MOCVD method which differ in mixing ratio were respectively prepared in the same manner as in Example 1 so as to grow Si films on substrates and form Hf-Si—O thin films on surfaces of those Si films in the same manner as in Example 4, except that Hf(CH₃O)₄, Hf(C₂H₅O)₄, Hf(n-C₃H₇O)₄ and Hf(n-C₄H₉O)₄ were used as the organic Hf compound.

### Examples 49 to 52

Five raw material solutions for MOCVD method which differ in mixing ratio were respectively prepared in the same manner as in Example 1 so as to grow Si films on substrates and form Hf-Si—O thin films on surfaces of those Si films in the same manner as in Example 4, except that Si[(n-C₃H₇)₂N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 53 to 56

Five raw material solutions for MOCVD method which differ in mixing ratio were respectively prepared in the same manner as in Example 1 so as to grow Si films on substrates and form Hf-Si—O thin films on surfaces of those Si films in the same manner as in Example 4, except that Si[(n-C₄H₉)₂N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 57 to 60

Five raw material solutions for MOCVD method which differ in mixing ratio were respectively prepared in the same manner as in Example 1 so as to grow Si films on substrates and form Hf-Si—O thin films on surfaces of those Si films in the same manner as in Example 4, except that Si[(CH₃)(C₂H₅)N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 61 to 64

Five raw material solutions for MOCVD method which differ in mixing ratio were respectively prepared in the same manner as in Example 1 so as to grow Si films on substrates and form Hf-Si—O thin films on surfaces of those Si films in the same manner as in Example 4, except that Si[(CH₃)(n-C₃H₇)N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 65 to 68

Five raw material solutions for MOCVD method which differ in mixing ratio were respectively prepared in the same manner as in Example 1 so as to grow Si films on substrates and form Hf-Si—O thin films on surfaces of those Si films in the same manner as in Example 4, except that Si[(CH₃)(n-C₄H₉)N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 69 to 72

Five raw material solutions for MOCVD method which differ in mixing ratio were respectively prepared in the same manner as in Example 1 so as to grow Si films on substrates and form Hf-Si—O thin films on surfaces of those Si films in the same manner as in Example 4, except that Si[(C₂H₅)(n-C₃H₇)N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 73 to 76

Five raw material solutions for MOCVD method which differ in mixing ratio were respectively prepared in the same manner as in Example 1 so as to grow Si films on substrates and form Hf-Si—O thin films on surfaces of those Si films in the same manner as in Example 4, except that Si[(C₂H₅)(n-C₄H₉)N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

<Comparative Test 4>

For each obtained Hf-Si—O thin film according to Examples 41 to 76, a film thickness test, and a peel test to examine adhesivity, per film formation time of the obtained Hf-Si—O thin film were carried out in the same manner as in the above-mentioned Comparative Test 1.

<Evaluation>

Obtained results of the film thickness and the peel test per film formation time are respectively shown in tables 12 to 20. The peel test shows the number of remaining substrates per 100 pieces of cut grid.

TABLE 12
Silicon substrate-si film-HfSiO thin film

| | Organic Hf | | Film thickness per film | | | | | Peel test | | | | |
|---|---|---|---|---|---|---|---|---|---|---|---|---|
| Raw | compound & | Mixing | formation time [nm] | | | | | [a piece/100 pieces] | | | | |
| material | organic Si | ratio | 1 | | | | | | | | | 5 |
| solution | compound | [wt %] | min. | 2 min. | 3 min. | 4 min. | 5 min. | 1 min. | 2 min. | 3 min. | 4 min. | min. |

| | | | | | | | | | |
|---|---|---|---|---|---|---|---|---|---|
| Ex. 41 | Single | Hf(CH₃O)₄ | 0.001 | 20 | 30 | 40 | 59 | 69 | 99 to 100 |
| | solution | Si[(CH₃)₂N]₄ | 0.01 | 23 | 39 | 47 | 69 | 90 | |
| | | | 0.1 | 30 | 40 | 61 | 82 | 98 | |
| | | | 0.2 | 31 | 39 | 57 | 68 | 88 | |
| | | | 0.5 | 40 | 73 | 120 | 140 | 190 | |
| Ex. 42 | Single | Hf(C₂H₅O)₄ | 0.001 | 15 | 23 | 62 | 68 | 90 | 99 to 100 |
| | solution | Si[(CH₃)₂N]₄ | 0.01 | 21 | 43 | 56 | 64 | 73 | |
| | | | 0.1 | 29 | 40 | 76 | 100 | 125 | |
| | | | 0.2 | 30 | 40 | 79 | 100 | 122 | |
| | | | 0.5 | 38 | 59 | 90 | 101 | 121 | |
| Ex. 43 | Single | Hf(n-C₃H₇O)₄ | 0.001 | 24 | 38 | 50 | 62 | 90 | 99 to 100 |
| | solution | Si[(CH₃)₂N]₄ | 0.01 | 16 | 30 | 39 | 61 | 73 | |
| | | | 0.1 | 30 | 40 | 56 | 70 | 80 | |
| | | | 0.2 | 35 | 61 | 75 | 90 | 110 | |
| | | | 0.5 | 60 | 120 | 127 | 170 | 200 | |
| Ex. 44 | Single | Hf(n-C₄H₉O)₄ | 0.001 | 20 | 43 | 50 | 60 | 72 | 98 to 99 |
| | solution | Si[(CH₃)₂N]₄ | 0.01 | 23 | 38 | 42 | 58 | 89 | |
| | | | 0.1 | 30 | 45 | 60 | 88 | 93 | |
| | | | 0.2 | 31 | 49 | 62 | 88 | 100 | |
| | | | 0.5 | 36 | 70 | 92 | 100 | 120 | |

TABLE 13
Silicon substrate-Si film-HfSiO thin film

| | Organic Hf | | Film thickness per film | | | | | | | | | |
|---|---|---|---|---|---|---|---|---|---|---|---|---|
| Raw | compound & | Mixing | formation time [nm] | | | | | Peel test [a piece/100 | | | | |
| material | organic Si | ratio | 1 | | | | 5 | pieces] | | | | |
| solution | compound | [wt %] | min. | 2 min. | 3 min. | 4 min. | min. | 1 min. | 2 min. | 3 min. | 4 min. | 5 min. |

| | | | | | | | | | |
|---|---|---|---|---|---|---|---|---|---|
| Ex. 45 | Single | Hf(CH₃O)₄ | 0.001 | 22 | 29 | 41 | 62 | 70 | 97 to 99 |
| | solution | Si[(C₂H₅)₂N]₄ | 0.01 | 23 | 39 | 49 | 72 | 89 | |
| | | | 0.1 | 31 | 42 | 62 | 81 | 99 | |
| | | | 0.2 | 32 | 38 | 62 | 72 | 93 | |
| | | | 0.5 | 45 | 70 | 110 | 134 | 190 | |
| Ex. 46 | Single | Hf(C₂H₅O)₄ | 0.001 | 16 | 22 | 61 | 69 | 99 | 97 to 99 |
| | solution | Si[(C₂H₅)₂N]₄ | 0.01 | 22 | 43 | 62 | 61 | 70 | |
| | | | 0.1 | 29 | 49 | 81 | 93 | 123 | |
| | | | 0.2 | 30 | 45 | 88 | 99 | 110 | |
| | | | 0.5 | 35 | 59 | 89 | 100 | 112 | |
| Ex. 47 | Single | Hf(n-C₃H₇O)₄ | 0.001 | 21 | 36 | 56 | 60 | 88 | 89 to 100 |
| | solution | Si[(C₂H₅)₂N]₄ | 0.01 | 17 | 29 | 39 | 67 | 65 | |
| | | | 0.1 | 30 | 44 | 56 | 69 | 80 | |
| | | | 0.2 | 32 | 65 | 72 | 80 | 110 | |
| | | | 0.5 | 57 | 112 | 132 | 162 | 205 | |
| Ex. 48 | Single | Hf(n-C₄H₉O)₄ | 0.001 | 21 | 41 | 57 | 69 | 69 | 99 to 100 |
| | solution | Si[(C₂H₅)₂N]₄ | 0.01 | 21 | 41 | 44 | 60 | 88 | |
| | | | 0.1 | 42 | 44 | 63 | 89 | 87 | |
| | | | 0.2 | 37 | 51 | 69 | 92 | 92 | |
| | | | 0.5 | 40 | 69 | 94 | 99 | 100 | |

TABLE 14
Silicon substrate-Si film-HfSiO thin film

| | Organic Hf | | Film thickness per film | | | | | | | | | |
|---|---|---|---|---|---|---|---|---|---|---|---|---|
| Raw | compound & | Mixing | formation time [nm] | | | | | Peel test [a piece/100 | | | | |
| material | organic Si | ratio | 1 | | | | 5 | pieces] | | | | |
| solution | compound | [wt %] | min. | 2 min. | 3 min. | 4 min. | min. | 1 min. | 2 min. | 3 min. | 4 min. | 5 min. |

| | | | | | | | | | |
|---|---|---|---|---|---|---|---|---|---|
| Ex. 49 | Single | Hf(CH₃O)₄ | 0.001 | 18 | 27 | 40 | 60 | 70 | 90 to 92 |
| | solution | Si[(n-C₃H₇)₂N]₄ | 0.01 | 20 | 38 | 47 | 70 | 88 | |
| | | | 0.1 | 29 | 40 | 60 | 80 | 97 | |
| | | | 0.2 | 30 | 38 | 60 | 70 | 90 | |
| | | | 0.5 | 40 | 70 | 110 | 132 | 192 | |
| Ex. 50 | Single | Hf(C₂H₅O)₄ | 0.001 | 15 | 21 | 60 | 68 | 98 | 92 to 94 |
| | solution | Si[(n-C₃H₇)₂N]₄ | 0.01 | 20 | 40 | 62 | 60 | 70 | |
| | | | 0.1 | 28 | 49 | 80 | 92 | 130 | |
| | | | 0.2 | 31 | 43 | 82 | 98 | 120 | |
| | | | 0.5 | 37 | 58 | 88 | 101 | 121 | |
| Ex. 51 | Single | Hf(n-C₃H₇O)₄ | 0.001 | 20 | 37 | 57 | 62 | 90 | 94 to 95 |
| | solution | Si[(n-C₃H₇)₂N]₄ | 0.01 | 16 | 29 | 38 | 67 | 70 | |
| | | | 0.1 | 29 | 43 | 60 | 67 | 82 | |
| | | | 0.2 | 30 | 61 | 72 | 82 | 110 | |
| | | | 0.5 | 56 | 110 | 130 | 162 | 201 | |
| Ex. 52 | Single | Hf(n-C₄H₉O)₄ | 0.001 | 20 | 40 | 57 | 63 | 70 | 95 to 96 |
| | solution | Si[(n-C₃H₇)₂N]₄ | 0.01 | 20 | 40 | 43 | 60 | 90 | |
| | | | 0.1 | 40 | 43 | 62 | 90 | 90 | |
| | | | 0.2 | 36 | 50 | 68 | 90 | 101 | |
| | | | 0.5 | 37 | 68 | 93 | 98 | 110 | |

TABLE 15
Silicon substrate-Si film-HfSiO thin film

| | Organic Hf | | Film thickness per film | | | | | | | | | |
|---|---|---|---|---|---|---|---|---|---|---|---|---|
| Raw | compound & | Mixing | formation time [nm] | | | | | Peel test | | | | |
| material | organic Si | ratio | 1 | 2 | 3 | 4 | 5 | [a piece/100 pieces] | | | | |
| solution | compound | [wt %] | min. | min. | min. | min. | min. | 1 min. | 2 min. | 3 min. | 4 min. | 5 min. |

| | | | | | | | | | |
|---|---|---|---|---|---|---|---|---|---|
| Ex. 53 | Single | Hf(CH₃O)₄ | 0.001 | 23 | 30 | 40 | 63 | 71 | 97 to 99 |
| | solution | Si[(n-C₄H₉)₂N]₄ | 0.01 | 24 | 40 | 50 | 73 | 90 | |
| | | | 0.1 | 32 | 42 | 60 | 88 | 100 | |
| | | | 0.2 | 33 | 38 | 63 | 76 | 94 | |
| | | | 0.5 | 46 | 76 | 112 | 132 | 192 | |
| Ex. 54 | Single | Hf(C₂H₅O)₄ | 0.001 | 18 | 23 | 65 | 70 | 99 | 99 to 100 |
| | solution | Si[(n-C₄H₉)₂N]₄ | 0.01 | 23 | 44 | 63 | 62 | 72 | |
| | | | 0.1 | 30 | 45 | 81 | 94 | 122 | |
| | | | 0.2 | 32 | 45 | 89 | 100 | 111 | |
| | | | 0.5 | 36 | 66 | 89 | 110 | 113 | |
| Ex. 55 | Single | Hf(n-C₃H₇O)₄ | 0.001 | 22 | 35 | 60 | 62 | 89 | 98 to 99 |
| | solution | Si[(n-C₄H₉)₂N]₄ | 0.01 | 19 | 30 | 40 | 67 | 65 | |
| | | | 0.1 | 31 | 44 | 60 | 70 | 81 | |
| | | | 0.2 | 33 | 60 | 72 | 81 | 111 | |
| | | | 0.5 | 56 | 110 | 130 | 163 | 206 | |
| Ex. 56 | Single | Hf(n-C₄H₉O)₄ | 0.001 | 22 | 42 | 60 | 70 | 70 | 90 |
| | solution | Si[(n-C₄H₉)₂N]₄ | 0.01 | 23 | 40 | 45 | 61 | 90 | |
| | | | 0.1 | 43 | 43 | 65 | 90 | 89 | |
| | | | 0.2 | 38 | 53 | 70 | 93 | 93 | |
| | | | 0.5 | 42 | 70 | 95 | 99 | 101 | |

TABLE 16
Silicon substrate-Si film-HfSiO thin film

| | Organic Hf | | Film thickness per film | | | | | | | | | |
|---|---|---|---|---|---|---|---|---|---|---|---|---|
| Raw | compound & | Mixing | formation time [nm] | | | | | Peel test | | | | |
| material | organic Si | ratio | 1 | 2 | 3 | 4 | 5 | [a piece/100 pieces] | | | | |
| solution | compound | [wt %] | min. | min. | min. | min. | min. | 1 min. | 2 min. | 3 min. | 4 min. | 5 min. |

| | | | | | | | | | |
|---|---|---|---|---|---|---|---|---|---|
| Ex. 57 | Single | Hf(CH₃O)₄ | 0.001 | 20 | 30 | 40 | 60 | 72 | 99 to 100 |
| | solution | Si[(CH₃)(C₂H₅)N]₄ | 0.01 | 22 | 37 | 46 | 72 | 82 | |
| | | | 0.1 | 30 | 41 | 56 | 78 | 96 | |
| | | | 0.2 | 29 | 40 | 57 | 70 | 90 | |
| | | | 0.5 | 38 | 67 | 110 | 122 | 180 | |
| Ex. 58 | Single | Hf(C₂H₅O)₄ | 0.001 | 16 | 20 | 62 | 69 | 97 | 99 to 100 |
| | solution | Si[(CH₃)(C₂H₅)N]₄ | 0.01 | 22 | 37 | 60 | 62 | 67 | |
| | | | 0.1 | 30 | 48 | 79 | 90 | 129 | |
| | | | 0.2 | 32 | 40 | 80 | 92 | 110 | |
| | | | 0.5 | 40 | 56 | 86 | 98 | 120 | |
| Ex. 59 | Single | Hf(n-C₃H₇O)₄ | 0.001 | 24 | 36 | 56 | 60 | 92 | 96 to 98 |
| | solution | Si[(CH₃)(C₂H₅)N]₄ | 0.01 | 18 | 30 | 40 | 67 | 67 | |
| | | | 0.1 | 30 | 40 | 57 | 60 | 80 | |
| | | | 0.2 | 37 | 61 | 70 | 80 | 110 | |
| | | | 0.5 | 60 | 109 | 120 | 160 | 200 | |
| Ex. 60 | Single | Hf(n-C₄H₉O)₄ | 0.001 | 22 | 38 | 57 | 60 | 68 | 97 to 99 |
| | solution | Si[(CH₃)(C₂H₅)N]₄ | 0.01 | 21 | 37 | 42 | 59 | 92 | |
| | | | 0.1 | 38 | 40 | 60 | 88 | 88 | |
| | | | 0.2 | 32 | 48 | 67 | 88 | 92 | |
| | | | 0.5 | 36 | 70 | 90 | 90 | 98 | |

TABLE 17
Silicon substrate-Si film-HfSiO thin film

| | Organic Hf | | | | | | | | | | | |
|---|---|---|---|---|---|---|---|---|---|---|---|---|
| Raw | compound & | Mixing | Film thickness per film | | | | | Peel test | | | | |
| material | organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 61 | Single | Hf(CH₃O)₄ | 0.001 | 19 | 28 | 42 | 62 | 72 | 99 to 100 |
| | solution | Si[(CH₃)(n-C₃H₇)N]₄ | 0.01 | 22 | 38 | 49 | 72 | 89 | |
| | | | 0.1 | 30 | 41 | 62 | 82 | 97 | |
| | | | 0.2 | 31 | 39 | 62 | 72 | 92 | |
| | | | 0.5 | 40 | 72 | 112 | 141 | 193 | |
| Ex. 62 | Single | Hf(C₂H₅O)₄ | 0.001 | 16 | 22 | 62 | 70 | 98 | 99 to 100 |
| | solution | Si[(CH₃)(n-C₃H₇)N]₄ | 0.01 | 22 | 41 | 63 | 62 | 70 | |
| | | | 0.1 | 29 | 50 | 87 | 93 | 130 | |
| | | | 0.2 | 30 | 44 | 83 | 99 | 121 | |
| | | | 0.5 | 38 | 59 | 88 | 102 | 121 | |
| Ex. 63 | Single | Hf(n-C₃H₇O)₄ | 0.001 | 21 | 38 | 57 | 63 | 92 | 97 to 98 |
| | solution | Si[(CH₃)(n-C₃H₇)N]₄ | 0.01 | 17 | 30 | 40 | 67 | 71 | |
| | | | 0.1 | 30 | 44 | 62 | 68 | 82 | |
| | | | 0.2 | 30 | 62 | 72 | 83 | 110 | |
| | | | 0.5 | 57 | 109 | 131 | 163 | 200 | |
| Ex. 64 | Single | Hf(n-C₄H₉O)₄ | 0.001 | 22 | 41 | 57 | 64 | 72 | 96 to 98 |
| | solution | Si[(CH₃)(n-C₃H₇)N]₄ | 0.01 | 22 | 42 | 44 | 62 | 92 | |
| | | | 0.1 | 42 | 44 | 62 | 92 | 92 | |
| | | | 0.2 | 31 | 51 | 69 | 92 | 101 | |
| | | | 0.5 | 37 | 69 | 94 | 99 | 101 | |

TABLE 18
Silicon substrate-Si film-HfSiO thin film

| | Organic Hf | | | | | | | | | | | |
|---|---|---|---|---|---|---|---|---|---|---|---|---|
| Raw | compound & | Mixing | Film thickness per film | | | | | Peel test | | | | |
| material | organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 65 | Single | Hf(CH₃O)₄ | 0.001 | 20 | 31 | 35 | 60 | 70 | 99 to 100 |
| | solution | Si[(CH₃)(n-C₄H₉)N]₄ | 0.01 | 21 | 37 | 48 | 70 | 80 | |
| | | | 0.1 | 33 | 40 | 50 | 70 | 90 | |
| | | | 0.2 | 32 | 40 | 60 | 72 | 92 | |
| | | | 0.5 | 40 | 65 | 109 | 110 | 190 | |
| Ex. 66 | Single | Hf(C₂H₅O)₄ | 0.001 | 18 | 20 | 60 | 60 | 90 | 99 to 100 |
| | solution | Si[(CH₃)(n-C₄H₉)N]₄ | 0.01 | 20 | 36 | 68 | 56 | 65 | |
| | | | 0.1 | 41 | 40 | 80 | 86 | 120 | |
| | | | 0.2 | 30 | 40 | 70 | 90 | 109 | |
| | | | 0.5 | 33 | 49 | 81 | 90 | 109 | |
| Ex. 67 | Single | Hf(n-C₃H₇O)₄ | 0.001 | 25 | 37 | 50 | 56 | 90 | 99 to 100 |
| | solution | Si[(CH₃)(n-C₄H₉)N]₄ | 0.01 | 20 | 41 | 35 | 60 | 65 | |
| | | | 0.1 | 25 | 35 | 50 | 67 | 81 | |
| | | | 0.2 | 40 | 60 | 70 | 80 | 109 | |
| | | | 0.5 | 53 | 80 | 120 | 180 | 190 | |
| Ex. 68 | Single | Hf(n-C₄H₉O)₄ | 0.001 | 21 | 40 | 57 | 60 | 62 | 98 to 99 |
| | solution | Si[(CH₃)(n-C₄H₉)N]₄ | 0.01 | 22 | 30 | 40 | 59 | 92 | |
| | | | 0.1 | 40 | 35 | 58 | 80 | 88 | |
| | | | 0.2 | 30 | 50 | 60 | 87 | 90 | |
| | | | 0.5 | 40 | 65 | 89 | 90 | 98 | |

TABLE 19
Silicon substrate-Si film-HfSiO thin film

| | Organic Hf | | Film thickness | | | | | | | | | |
|---|---|---|---|---|---|---|---|---|---|---|---|---|
| Raw | compound & | Mixing | per film formation time | | | | | Peel test | | | | |
| material | organic Si | ratio | [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 69 | Single | Hf(CH₃O)₄ | 0.001 | 18 | 29 | 43 | 60 | 70 | 95 to 96 |
| | solution | Si[(C₂H₅)(n-C₃H₇)N]₄ | 0.01 | 22 | 39 | 50 | 70 | 90 | |
| | | | 0.1 | 31 | 42 | 63 | 80 | 96 | |
| | | | 0.2 | 32 | 40 | 63 | 70 | 93 | |
| | | | 0.5 | 41 | 72 | 112 | 140 | 194 | |
| Ex. 70 | Single | Hf(C₂H₅O)₄ | 0.001 | 17 | 23 | 60 | 72 | 99 | 96 to 97 |
| | solution | Si[(C₂H₅)(n-C₃H₇)N]₄ | 0.01 | 23 | 42 | 62 | 63 | 72 | |
| | | | 0.1 | 30 | 51 | 80 | 94 | 132 | |
| | | | 0.2 | 31 | 45 | 82 | 99 | 122 | |
| | | | 0.5 | 39 | 60 | 90 | 110 | 125 | |
| Ex. 71 | Single | Hf(n-C₃H₇O)₄ | 0.001 | 22 | 39 | 60 | 64 | 90 | 92 to 94 |
| | solution | Si[(C₂H₅)(n-C₃H₇)N]₄ | 0.01 | 18 | 31 | 42 | 68 | 83 | |
| | | | 0.1 | 31 | 45 | 60 | 68 | 83 | |
| | | | 0.2 | 31 | 63 | 70 | 82 | 115 | |
| | | | 0.5 | 57 | 110 | 130 | 162 | 201 | |
| Ex. 72 | Single | Hf(n-C₄H₉O)₄ | 0.001 | 23 | 42 | 55 | 65 | 75 | 92 to 94 |
| | solution | Si[(C₂H₅)(n-C₃H₇)N]₄ | 0.01 | 22 | 40 | 43 | 63 | 95 | |
| | | | 0.1 | 43 | 45 | 60 | 92 | 95 | |
| | | | 0.2 | 32 | 52 | 70 | 92 | 100 | |
| | | | 0.5 | 38 | 70 | 90 | 100 | 102 | |

TABLE 20
Silicon substrate-Si film-HfSiO thin film

| | Organic Hf | | | | | | | | | | | |
|---|---|---|---|---|---|---|---|---|---|---|---|---|
| Raw | compound & | Mixing | Film thickness per film | | | | | Peel test | | | | |
| material | organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 73 | Single | Hf(CH₃O)₄ | 0.001 | 19 | 30 | 32 | 62 | 65 | 90 to 92 |
| | solution | Si[(C₂H₅)(n-C₄H₉)N]₄ | 0.01 | 20 | 37 | 45 | 70 | 70 | |
| | | | 0.1 | 30 | 40 | 52 | 62 | 80 | |
| | | | 0.2 | 32 | 40 | 62 | 70 | 92 | |
| | | | 0.5 | 38 | 63 | 92 | 98 | 190 | |
| Ex. 74 | Single | Hf(C₂H₅O)₄ | 0.001 | 20 | 20 | 62 | 72 | 90 | 92 to 94 |
| | solution | Si[(C₂H₅)(n-C₄H₉)N]₄ | 0.01 | 18 | 36 | 68 | 60 | 82 | |
| | | | 0.1 | 41 | 46 | 72 | 86 | 109 | |
| | | | 0.2 | 32 | 42 | 72 | 93 | 120 | |
| | | | 0.5 | 33 | 48 | 82 | 98 | 131 | |
| Ex. 75 | Single | Hf(n-C₃H₇O)₄ | 0.001 | 25 | 35 | 50 | 62 | 90 | 94 to 96 |
| | solution | Si[(C₂H₅)(n-C₄H₉)N]₄ | 0.01 | 21 | 41 | 43 | 62 | 85 | |
| | | | 0.1 | 25 | 38 | 52 | 70 | 81 | |
| | | | 0.2 | 40 | 57 | 70 | 82 | 110 | |
| | | | 0.5 | 53 | 79 | 112 | 190 | 198 | |
| Ex. 76 | Single | Hf(n-C₄H₉O)₄ | 0.001 | 20 | 42 | 57 | 60 | 70 | 96 to 98 |
| | solution | Si[(C₂H₅)(n-C₄H₉)N]₄ | 0.01 | 22 | 30 | 43 | 60 | 90 | |
| | | | 0.1 | 35 | 38 | 60 | 82 | 90 | |
| | | | 0.2 | 35 | 49 | 62 | 87 | 98 | |
| | | | 0.5 | 40 | 60 | 90 | 92 | 97 | |

As clearly shown in the tables 12 to 20, the HfSiO films formed by using the single raw material solution according to Examples 41 to 76 had a significantly high film forming rate in comparison with Comparative Example 2, and stable film formation was obtained. Also, in the peel test, most of grids were remained on substrates in HfSiO films formed by using the raw material solution according to Examples 41 to 76 and thus high adhesivity results were obtained.

### Example 77

Five raw material solutions for MOCVD method which differ in mixing ratio were respectively prepared in the same manner as in Example 1 so as to form Hf-Si—O—N thin films, except that Si[(CH₃)₂N]₄ was used as the organic Si compound, and Hf(CH₃O)₄ was used as the organic Hf compound. In specific, first, five silicon substrates having a SiO₂ film (thickness of 5000 Å) on each surface were respectively prepared as substrates, and the substrates were installed in the film forming chamber of the MOCVD apparatus shown in FIG. 1. Then, the substrate temperature, the vaporization temperature and the pressure were set to 600° C., 70° C., and about 266 Pa (2 torr), respectively. H₂ gas was used as a reducing gas and its partial pressure was set at 1 ccm. Ar gas was used as a carrier gas. Si[(C₂H₅)₂N]₄ was respectively fed as the organic Si compound at a rate of 0.1 g/min, and Si[(C₂H₅)₂N]₄ was thermally decomposed to grow the Si film on a surface of the substrate. Supply of the organic Si compound and the reducing gas was stopped when the film formation time reached 2 minutes. Next, O₂ gas and N₂ were used as reactant gases and their partial pressures were each set at 1000 ccm. Ar gas was used as a carrier gas, and the raw material solutions for MOCVD method were respectively fed at a rate of 0.1 g/min to form the Hf-Si—O—N film on a surface of the grown Si film. The substrates were taken out by one from the film forming chamber when the film formation time reached 1 minute, 2 minutes, 3 minutes, 4 minutes, and 5 minutes, respectively.

### Examples 78 to 80

Five raw material solutions for MOCVD method which differ in mixing ratio were respectively prepared in the same manner as in Example 77 so as to grow Si films on substrates and form Hf-Si—O—N thin films on surfaces of those Si films in the same manner as in Example 77, except that Hf(C₂H₅O)₄, Hf(n-C₃H₇O)₄ and Hf(n-C₄H₉O)₄ were used as the organic Hf compound.

### Examples 81 to 84

Five raw material solutions for MOCVD method which differ in mixing ratio were respectively prepared in the same manner as in Example 77 so as to grow Si films on substrates and form Hf-Si—O—N thin films on surfaces of those Si films in the same manner as in Example 77, except that Si[(C₂H₅)₂N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 85 to 88

Five raw material solutions for MOCVD method which differ in mixing ratio were respectively prepared in the same manner as in Example 77 so as to grow Si films on substrates and form Hf-Si—O—N thin films on surfaces of those Si films in the same manner as in Example 77, except that Si[(n-C₃H₇)₂N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 89 to 92

Five raw material solutions for MOCVD method which differ in mixing ratio were respectively prepared in the same manner as in Example 77 so as to grow Si films on substrates and form Hf-Si—O—N thin films on surfaces of those Si films in the same manner as in Example 77, except that Si[(n-C₄H₉)₂N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 93 to 96

Five raw material solutions for MOCVD method which differ in mixing ratio were respectively prepared in the same manner as in Example 77 so as to grow Si films on substrates and form Hf-Si—O—N thin films on surfaces of those Si films in the same manner as in Example 77, except that Si[(CH₃)(C₂H₅)N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 97 to 100

Five raw material solutions for MOCVD method which differ in mixing ratio were respectively prepared in the same manner as in Example 77 so as to grow Si films on substrates and form Hf-Si—O—N thin films on surfaces of those Si films in the same manner as in Example 77, except that Si[(CH₃)(n-C₃H₇)N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 101 to 104

Five raw material solutions for MOCVD method which differ in mixing ratio were respectively prepared in the same manner as in Example 77 so as to grow Si films on substrates and form Hf-Si—O—N thin films on surfaces of those Si films in the same manner as in Example 77, except that Si[(CH₃)(n-C₄H₉)N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 105 to 108

Five raw material solutions for MOCVD method which differ in mixing ratio were respectively prepared in the same manner as in Example 77 so as to grow Si films on substrates and form Hf-Si—O—N thin films on surfaces of those Si films in the same manner as in Example 77, except that Si[(C₂H₅)(n-C₃H₇)N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples 109 to 112

Five raw material solutions for MOCVD method which differ in mixing ratio were respectively prepared in the same manner as in Example 77 so as to grow Si films on substrates and form Hf-Si—O—N thin films on surfaces of those Si films in the same manner as in Example 77, except that Si[(C₂H₅)(n-C₄H₉)N]₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

<Comparative Test 5>

For each obtained Hf-Si—O—N thin film according to Examples 77 to 112, a film thickness test, and a peel test to examine adhesivity, per film formation time of the obtained Hf-Si—O—N thin film were carried out in the same manner as in the above-mentioned Comparative Test 1.

<Evaluation>

Obtained results of the film thickness and the peel test per film formation time are respectively shown in tables 21 to 29. The peel test shows the number of remaining substrates per 100 pieces of cut grid.

TABLE 21
Silicon substrate-Si film-HfSiON thin film

| | Organic Hf | | Film thickness per film | | | | | | | | | |
|---|---|---|---|---|---|---|---|---|---|---|---|---|
| Raw | compound | Mixing | formation time [nm] | | | | | Peel test | | | | |
| material | & organic Si | ratio | 1 | | | | 5 | [a piece/100 pieces] | | | | |
| solution | compound | [wt %] | min. | 2 min. | 3 min. | 4 min. | min. | 1 min. | 2 min. | 3 min. | 4 min. | 5 min. |

| | | | | | | | | | |
|---|---|---|---|---|---|---|---|---|---|
| Ex. 77 | Single | Hf(CH₃O)₄ | 0.001 | 20 | 31 | 35 | 62 | 70 | 99 to 100 |
| | solution | Si[(CH₃)₂N]₄ | 0.01 | 22 | 39 | 49 | 70 | 80 | |
| | | | 0.1 | 35 | 43 | 53 | 70 | 92 | |
| | | | 0.2 | 33 | 42 | 62 | 72 | 99 | |
| | | | 0.5 | 38 | 85 | 93 | 110 | 180 | |
| Ex. 78 | Single | Hf(C₂H₅O)₄ | 0.001 | 20 | 40 | 68 | 60 | 90 | 99 to 100 |
| | solution | Si[(CH₃)₂N]₄ | 0.01 | 21 | 35 | 68 | 70 | 85 | |
| | | | 0.1 | 38 | 42 | 79 | 88 | 121 | |
| | | | 0.2 | 35 | 41 | 79 | 100 | 110 | |
| | | | 0.5 | 32 | 45 | 80 | 109 | 119 | |
| Ex. 79 | Single | Hf(n-C₃H₇O)₄ | 0.001 | 28 | 38 | 52 | 92 | 95 | 98 to 99 |
| | solution | Si[(CH₃)₂N]₄ | 0.01 | 21 | 43 | 40 | 65 | 70 | |
| | | | 0.1 | 23 | 38 | 44 | 80 | 88 | |
| | | | 0.2 | 38 | 65 | 65 | 90 | 190 | |
| | | | 0.5 | 50 | 79 | 119 | 182 | 195 | |
| Ex. 80 | Single | Hf(n-C₄H₉O)₄ | 0.001 | 22 | 35 | 60 | 65 | 72 | 99 to 100 |
| | solution | Si[(CH₃)₂N]₄ | 0.01 | 25 | 38 | 48 | 92 | 110 | |
| | | | 0.1 | 38 | 49 | 60 | 90 | 110 | |
| | | | 0.2 | 40 | 53 | 62 | 99 | 120 | |
| | | | 0.5 | 43 | 68 | 90 | 99 | 120 | |

TABLE 22
Silicon substrate-Si film-HfSiON thin film

| | Organic Hf | | Film thickness per film | | | | | | | | | |
|---|---|---|---|---|---|---|---|---|---|---|---|---|
| Raw | compound | Mixing | formation time [nm] | | | | | Peel test | | | | |
| material | & organic Si | ratio | 1 | | | | 5 | [a piece/100 pieces] | | | | |
| solution | compound | [wt %] | min. | 2 min. | 3 min. | 4 min. | min. | 1 min. | 2 min. | 3 min. | 4 min. | 5 min. |

| | | | | | | | | | |
|---|---|---|---|---|---|---|---|---|---|
| Ex. 81 | Single | Hf(CH₃O)₄ | 0.001 | 20 | 31 | 33 | 62 | 63 | 96 to 97 |
| | solution | Si[(C₂H₅)₂N]₄ | 0.01 | 21 | 38 | 44 | 72 | 72 | |
| | | | 0.1 | 32 | 41 | 53 | 63 | 81 | |
| | | | 0.2 | 35 | 41 | 63 | 72 | 83 | |
| | | | 0.5 | 39 | 64 | 93 | 99 | 192 | |
| Ex. 82 | Single | Hf(C₂H₅O)₄ | 0.001 | 21 | 21 | 63 | 73 | 90 | 97 to 99 |
| | solution | Si[(C₂H₅)₂N]₄ | 0.01 | 19 | 37 | 69 | 62 | 85 | |
| | | | 0.1 | 45 | 46 | 73 | 88 | 100 | |
| | | | 0.2 | 33 | 43 | 74 | 93 | 113 | |
| | | | 0.5 | 34 | 49 | 88 | 99 | 132 | |
| Ex. 83 | Single | Hf(n-C₃H₇O)₄ | 0.001 | 26 | 37 | 53 | 63 | 93 | 99 to 100 |
| | solution | Si[(C₂H₅)₂N]₄ | 0.01 | 22 | 42 | 42 | 63 | 84 | |
| | | | 0.1 | 27 | 39 | 52 | 73 | 80 | |
| | | | 0.2 | 41 | 57 | 70 | 88 | 100 | |
| | | | 0.5 | 55 | 79 | 112 | 190 | 199 | |
| Ex. 84 | Single | Hf(n-C₄H₉O)₄ | 0.001 | 21 | 42 | 56 | 60 | 69 | 99 to 100 |
| | solution | Si[(C₂H₅)₂N]₄ | 0.01 | 23 | 31 | 43 | 60 | 93 | |
| | | | 0.1 | 36 | 39 | 62 | 80 | 100 | |
| | | | 0.2 | 36 | 50 | 61 | 84 | 100 | |
| | | | 0.5 | 41 | 62 | 93 | 95 | 100 | |

TABLE 23
Silicon substrate-Si film-HfSiON thin film

| | Organic Hf | | Film thickness per film | | | | | | | | | |
|---|---|---|---|---|---|---|---|---|---|---|---|---|
| Raw | compound | Mixing | formation time [nm] | | | | | Peel test [a piece/100 | | | | |
| material | & organic Si | ratio | 1 | | | | 5 | pieces] | | | | |
| solution | compound | [wt %] | min. | 2 min. | 3 min. | 4 min. | min. | 1 min. | 2 min. | 3 min. | 4 min. | 5 min. |

| | | | | | | | | | |
|---|---|---|---|---|---|---|---|---|---|
| Ex. 85 | Single | Hf(CH₃O)₄ | 0.001 | 21 | 30 | 36 | 62 | 71 | 90 to 92 |
| | solution | Si[(n-C₃H₇)₂N]₄ | 0.01 | 23 | 38 | 50 | 71 | 81 | |
| | | | 0.1 | 36 | 42 | 54 | 71 | 92 | |
| | | | 0.2 | 34 | 43 | 63 | 73 | 99 | |
| | | | 0.5 | 39 | 86 | 93 | 111 | 181 | |
| Ex. 86 | Single | Hf(C₂H₅O)₄ | 0.001 | 21 | 41 | 69 | 61 | 91 | 92 to 94 |
| | solution | Si[(n-C₃H₇)₂N]₄ | 0.01 | 22 | 36 | 69 | 71 | 85 | |
| | | | 0.1 | 39 | 41 | 80 | 89 | 121 | |
| | | | 0.2 | 36 | 42 | 80 | 110 | 110 | |
| | | | 0.5 | 33 | 46 | 80 | 119 | 119 | |
| Ex. 87 | Single | Hf(n-C₃H₇O)₄ | 0.001 | 29 | 39 | 53 | 93 | 95 | 94 to 96 |
| | solution | Si[(n-C₃H₇)₂N]₄ | 0.01 | 22 | 44 | 41 | 65 | 71 | |
| | | | 0.1 | 23 | 39 | 45 | 82 | 88 | |
| | | | 0.2 | 39 | 66 | 68 | 91 | 101 | |
| | | | 0.5 | 51 | 80 | 119 | 183 | 194 | |
| Ex. 88 | Single | Hf(n-C₄H₉O)₄ | 0.001 | 23 | 36 | 62 | 64 | 72 | 90 to 92 |
| | solution | Si[(n-C₃H₇)₂N]₄ | 0.01 | 26 | 39 | 49 | 92 | 110 | |
| | | | 0.1 | 39 | 48 | 61 | 92 | 111 | |
| | | | 0.2 | 41 | 54 | 63 | 99 | 120 | |
| | | | 0.5 | 44 | 69 | 91 | 99 | 121 | |

TABLE 24
Silicon substrate-Si film-HfSiON thin film

| | Organic Hf | | Film thickness per film | | | | | | | | | |
|---|---|---|---|---|---|---|---|---|---|---|---|---|
| Raw | compound | Mixing | formation time [nm] | | | | | Peel test [a piece/100 | | | | |
| material | & organic Si | ratio | 1 | 2 | 3 | 4 | 5 | pieces] | | | | |
| solution | compound | [wt %] | min. | min. | min. | min. | min. | 1 min. | 2 min. | 3 min. | 4 min. | 5 min. |

| | | | | | | | | | |
|---|---|---|---|---|---|---|---|---|---|
| Ex. 89 | Single | Hf(CH₃O)₄ | 0.001 | 23 | 32 | 34 | 63 | 82 | 96 to 97 |
| | solution | Si[(n-C₄H₉)₂N]₄ | 0.01 | 22 | 39 | 45 | 74 | 85 | |
| | | | 0.1 | 33 | 42 | 55 | 64 | 81 | |
| | | | 0.2 | 36 | 42 | 64 | 78 | 93 | |
| | | | 0.5 | 40 | 64 | 94 | 100 | 190 | |
| Ex. 90 | Single | Hf(C₂H₅O)₄ | 0.001 | 22 | 21 | 64 | 74 | 93 | 97 to 98 |
| | solution | Si[(n-C₄H₉)₂N]₄ | 0.01 | 20 | 38 | 68 | 89 | 97 | |
| | | | 0.1 | 46 | 85 | 74 | 90 | 100 | |
| | | | 0.2 | 34 | 45 | 75 | 95 | 113 | |
| | | | 0.5 | 35 | 50 | 90 | 100 | 135 | |
| Ex. 91 | Single | Hf(n-C₃H₇O)₄ | 0.001 | 27 | 37 | 55 | 63 | 90 | 99 to 100 |
| | solution | Si[(n-C₄H₉)₂N]₄ | 0.01 | 23 | 45 | 84 | 99 | 105 | |
| | | | 0.1 | 27 | 40 | 59 | 73 | 85 | |
| | | | 0.2 | 41 | 60 | 72 | 90 | 95 | |
| | | | 0.5 | 56 | 80 | 110 | 190 | 195 | |
| Ex. 92 | Single | Hf(n-C₄H₉O)₄ | 0.001 | 22 | 43 | 60 | 65 | 69 | 99 to 100 |
| | solution | Si[(n-C₄H₉)₂N]₄ | 0.01 | 24 | 33 | 49 | 62 | 92 | |
| | | | 0.1 | 37 | 40 | 63 | 80 | 100 | |
| | | | 0.2 | 37 | 51 | 62 | 85 | 95 | |
| | | | 0.5 | 42 | 65 | 100 | 110 | 120 | |

TABLE 25
Silicon substrate-Si film-HfSiON thin film

| | Organic Hf | | Film thicknessper film | | | | | | | | | |
|---|---|---|---|---|---|---|---|---|---|---|---|---|
| Raw | compound | Mixing | formation time [nm] | | | | | Peel test | | | | |
| material | & organic Si | ratio | 1 | 2 | 3 | 4 | 5 | [a piece/100 pieces] | | | | |
| solution | compound | [wt %] | min. | min. | min. | min. | min. | 1 min. | 2 min. | 3 min. | 4 min. | 5 min. |

| | | | | | | | | | |
|---|---|---|---|---|---|---|---|---|---|
| Ex. 93 | Single | Hf(CH₃O)₄ | 0.001 | 21 | 31 | 37 | 63 | 73 | 90 to 92 |
| | solution | Si[(CH₃)(C₂H₅)N]₄ | 0.01 | 23 | 39 | 51 | 72 | 82 | |
| | | | 0.1 | 36 | 43 | 54 | 72 | 93 | |
| | | | 0.2 | 35 | 44 | 63 | 73 | 99 | |
| | | | 0.5 | 40 | 87 | 94 | 112 | 182 | |
| Ex. 94 | Single | Hf(C₂H₅O)₄ | 0.001 | 22 | 42 | 70 | 82 | 93 | 92 to 95 |
| | solution | Si[(CH₃)(C₂H₅)N]₄ | 0.01 | 22 | 36 | 70 | 72 | 86 | |
| | | | 0.1 | 39 | 42 | 81 | 90 | 122 | |
| | | | 0.2 | 37 | 43 | 80 | 111 | 111 | |
| | | | 0.5 | 34 | 47 | 81 | 119 | 119 | |
| Ex. 95 | Single | Hf(n-C₃H₇O)₄ | 0.001 | 30 | 40 | 54 | 94 | 96 | 99 to 100 |
| | solution | Si[(CH₃)(C₂H₅)N]₄ | 0.01 | 23 | 45 | 52 | 66 | 72 | |
| | | | 0.1 | 24 | 40 | 47 | 83 | 88 | |
| | | | 0.2 | 40 | 67 | 69 | 92 | 192 | |
| | | | 0.5 | 52 | 81 | 120 | 182 | 193 | |
| Ex. 96 | Single | Hf(n-C₄H₉O)₄ | 0.001 | 24 | 36 | 61 | 63 | 74 | 96 to 97 |
| | solution | Si[(CH₃)(C₂H₅)N]₄ | 0.01 | 27 | 39 | 49 | 92 | 111 | |
| | | | 0.1 | 40 | 49 | 62 | 93 | 111 | |
| | | | 0.2 | 42 | 55 | 64 | 99 | 121 | |
| | | | 0.5 | 45 | 70 | 92 | 99 | 120 | |

TABLE 26
Silicon substrate-Si film-HfSiON thin film

| Raw | Organic Hf | Mixing | Film thickness per film | | | | | Peel test | | | | |
|---|---|---|---|---|---|---|---|---|---|---|---|---|
| material | compound & organic | ratio | formation time [nm] | | | | | [a piece/100 pieces] | | | | |
| solution | Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 97 | Single | Hf(CH₃O)₄ | 0.001 | 22 | 31 | 37 | 63 | 75 | 98 to 99 |
| | solution | Si[(CH₃)(n-C₃H₇)N]₄ | 0.01 | 24 | 39 | 51 | 72 | 82 | |
| | | | 0.1 | 40 | 44 | 55 | 73 | 92 | |
| | | | 0.2 | 35 | 45 | 63 | 75 | 99 | |
| | | | 0.5 | 40 | 85 | 93 | 110 | 182 | |
| Ex. 98 | Single | Hf(C₂H₅O)₄ | 0.001 | 22 | 43 | 69 | 62 | 90 | 97 to 99 |
| | solution | Si[(CH₃)(n-C₃H₇)N]₄ | 0.01 | 26 | 37 | 69 | 75 | 82 | |
| | | | 0.1 | 40 | 41 | 82 | 90 | 120 | |
| | | | 0.2 | 37 | 43 | 82 | 110 | 110 | |
| | | | 0.5 | 35 | 49 | 80 | 117 | 118 | |
| Ex. 99 | Single | Hf(n-C₃H₇O)₄ | 0.001 | 30 | 42 | 54 | 94 | 99 | 96 to 98 |
| | solution | Si[(CH₃)(n-C₃H₇)N]₄ | 0.01 | 23 | 45 | 42 | 65 | 75 | |
| | | | 0.1 | 24 | 40 | 47 | 84 | 89 | |
| | | | 0.2 | 40 | 62 | 69 | 92 | 110 | |
| | | | 0.5 | 53 | 80 | 110 | 180 | 190 | |
| Ex. 100 | Single | Hf(n-C₄H₉O)₄ | 0.001 | 24 | 37 | 62 | 65 | 72 | 99 to 100 |
| | solution | Si[(CH₃)(n-C₃H₇)N]₄ | 0.01 | 27 | 40 | 50 | 95 | 118 | |
| | | | 0.1 | 40 | 48 | 62 | 92 | 118 | |
| | | | 0.2 | 42 | 55 | 64 | 98 | 120 | |
| | | | 0.5 | 45 | 70 | 95 | 99 | 125 | |

TABLE 27
Silicon substrate-Si film-HfSiON thin film

| Raw | Organic Hf compound | Mixing | Film thickness per film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 101 | Single | Hf(CH₃O)₄ | 0.001 | 22 | 32 | 37 | 63 | 74 | 99 to 100 |
| | solution | Si[(CH₃)(n-C₄H₉)N]₄ | 0.01 | 24 | 40 | 52 | 73 | 83 | |
| | | | 0.1 | 36 | 44 | 55 | 73 | 93 | |
| | | | 0.2 | 35 | 45 | 64 | 74 | 99 | |
| | | | 0.5 | 41 | 88 | 94 | 113 | 181 | |
| Ex. 102 | Single | Hf(C₂H₅O)₄ | 0.001 | 23 | 42 | 71 | 63 | 94 | 99 to 100 |
| | solution | Si[(CH₃)(n-C₄H₉)N]₄ | 0.01 | 23 | 36 | 71 | 73 | 87 | |
| | | | 0.1 | 40 | 44 | 81 | 91 | 123 | |
| | | | 0.2 | 37 | 44 | 81 | 112 | 112 | |
| | | | 0.5 | 34 | 48 | 80 | 120 | 118 | |
| Ex. 103 | Single | Hf(n-C₃H₇O)₄ | 0.001 | 31 | 41 | 55 | 95 | 97 | 99 to 100 |
| | solution | Si[(CH₃)(n-C₄H₉)N]₄ | 0.01 | 24 | 46 | 43 | 66 | 73 | |
| | | | 0.1 | 24 | 41 | 47 | 84 | 89 | |
| | | | 0.2 | 41 | 68 | 69 | 93 | 192 | |
| | | | 0.5 | 53 | 82 | 122 | 183 | 190 | |
| Ex. 104 | Single | Hf(n-C₄H₉O)₄ | 0.001 | 25 | 36 | 62 | 64 | 75 | 96 to 97 |
| | solution | Si[(CH₃)(n-C₄H₉)N]₄ | 0.01 | 28 | 39 | 50 | 93 | 112 | |
| | | | 0.1 | 41 | 50 | 63 | 93 | 113 | |
| | | | 0.2 | 43 | 54 | 64 | 99 | 120 | |
| | | | 0.5 | 46 | 71 | 93 | 98 | 121 | |

TABLE 28
Silicon substrate-Si film-HfSiON thin film

| | | | | | | | | Peel test [a piece/100 | | | | |
|---|---|---|---|---|---|---|---|---|---|---|---|---|
| Raw | Organic Hf compound | Mixing | Film thickness per film | | | | | pieces] | | | | |
| material | & organic Si | ratio | formation time [nm] | | | | | | 2 | 3 | 4 | 5 |
| solution | compound | [wt %] | 1 min. | 2 min. | 3 min. | 4 min. | 5 min. | 1 min. | min. | min. | min. | min. |

| | | | | | | | | | |
|---|---|---|---|---|---|---|---|---|---|
| Ex. 105 | Single | Hf(CH₃O)₄ | 0.001 | 22 | 31 | 36 | 64 | 75 | 93 to 100 |
| | solution | Si[(C₂H₅)(n-C₃H₇)N]₄ | 0.01 | 28 | 38 | 51 | 78 | 85 | |
| | | | 0.1 | 30 | 40 | 55 | 76 | 99 | |
| | | | 0.2 | 35 | 42 | 62 | 75 | 100 | |
| | | | 0.5 | 44 | 80 | 93 | 110 | 190 | |
| Ex. 106 | Single | Hf(C₂H₅O)₄ | 0.001 | 23 | 42 | 72 | 80 | 95 | 92 to 94 |
| | solution | Si[(C₂H₅)(n-C₃H₇)N]₄ | 0.01 | 24 | 37 | 72 | 85 | 95 | |
| | | | 0.1 | 40 | 46 | 85 | 93 | 99 | |
| | | | 0.2 | 39 | 45 | 80 | 100 | 110 | |
| | | | 0.5 | 39 | 50 | 79 | 120 | 129 | |
| Ex. 107 | Single | Hf(n-C₃H₇O)₄ | 0.001 | 38 | 42 | 55 | 93 | 99 | 94 to 98 |
| | solution | Si[(C₂H₅)(n-C₃H₇)N]₄ | 0.01 | 24 | 48 | 54 | 69 | 78 | |
| | | | 0.1 | 25 | 40 | 49 | 80 | 90 | |
| | | | 0.2 | 42 | 65 | 69 | 90 | 180 | |
| | | | 0.5 | 53 | 80 | 120 | 180 | 190 | |
| Ex. 108 | Single | Hf(n-C₄H₉O)₄ | 0.001 | 24 | 36 | 60 | 61 | 70 | 98 to 100 |
| | solution | Si[(C₂H₅)(n-C₃H₇)N]₄ | 0.01 | 29 | 40 | 50 | 90 | 110 | |
| | | | 0.1 | 40 | 50 | 68 | 93 | 112 | |
| | | | 0.2 | 43 | 53 | 69 | 97 | 130 | |
| | | | 0.5 | 45 | 68 | 90 | 100 | 119 | |

TABLE 29
Silicon substrate-Si film-HfSiON thin film

| | | | | | | | | Peel test [a piece/100 | | | | |
|---|---|---|---|---|---|---|---|---|---|---|---|---|
| Raw | Organic Hf | Mixing | Film thickness per film | | | | | pieces] | | | | |
| material | compound & organic | ratio | formation time [nm] | | | | | | 2 | 3 | 4 | 5 |
| solution | Si compound | [wt %] | 1 min. | 2 min. | 3 min. | 4 min. | 5 min. | 1 min. | min. | min. | min. | min. |

| | | | | | | | | | |
|---|---|---|---|---|---|---|---|---|---|
| Ex. 109 | Single | Hf(CH₃O)₄ | 0.001 | 23 | 33 | 37 | 64 | 76 | 90 to 95 |
| | solution | Si[(C₂H₅)(n-C₄H₉)N]₄ | 0.01 | 25 | 41 | 53 | 74 | 84 | |
| | | | 0.1 | 37 | 45 | 55 | 74 | 94 | |
| | | | 0.2 | 34 | 46 | 65 | 75 | 95 | |
| | | | 0.5 | 40 | 89 | 96 | 115 | 180 | |
| Ex. 110 | Single | Hf(C₂H₅O)₄ | 0.001 | 22 | 43 | 70 | 84 | 93 | 92 to 100 |
| | solution | Si[(C₂H₅)(n-C₄H₉)N]₄ | 0.01 | 24 | 40 | 71 | 74 | 87 | |
| | | | 0.1 | 41 | 45 | 73 | 93 | 130 | |
| | | | 0.2 | 38 | 47 | 82 | 113 | 112 | |
| | | | 0.5 | 35 | 49 | 80 | 121 | 116 | |
| Ex. 111 | Single | Hf(n-C₃H₇O)₄ | 0.001 | 32 | 40 | 57 | 98 | 98 | 95 to 98 |
| | solution | Si[(C₂H₅)(n-C₄H₉)N]₄ | 0.01 | 25 | 47 | 44 | 67 | 74 | |
| | | | 0.1 | 25 | 40 | 46 | 84 | 89 | |
| | | | 0.2 | 43 | 69 | 65 | 95 | 190 | |
| | | | 0.5 | 53 | 80 | 120 | 180 | 188 | |
| Ex. 112 | Single | Hf(n-C₄H₉O)₄ | 0.001 | 26 | 37 | 63 | 65 | 70 | 99 to 100 |
| | solution | Si[(C₂H₅)(n-C₄H₉)N]₄ | 0.01 | 28 | 40 | 51 | 94 | 115 | |
| | | | 0.1 | 42 | 51 | 62 | 94 | 115 | |
| | | | 0.2 | 43 | 53 | 65 | 99 | 123 | |
| | | | 0.5 | 47 | 70 | 93 | 96 | 120 | |

As clearly shown in the tables 21 to 29, the HfSiON films formed by using the single raw material solution according to Examples 77 to 112 had a significantly high film forming rate and high film formation stability was obtained. Also, in the peel test, most of grids were remained on substrates in HfSiON films formed by using the raw material solution according to Examples 77 to 112 and thus high adhesivity results were obtained.

### Example A1

Hf[(C₂H₅)₂N]₄ and Si[(C₂H₅)₂N]₄ were prepared as the organic Hf compound and the organic Si compound, respectively. Next, the organic Hf compound and the organic Si compound were mixed at a room temperature in a ratio such that the weight ratio (organic Hf compound/organic Si compound) is 0.001 wt %, and the organic Hf compound was dissolved in the organic Si compound. This solution was then heated at a temperature of 60° C. for 2 hours to prepare a single solution of the raw material solution for MOCVD method. Also, total of five raw material solutions for MOCVD method which differ in mixing ratio were prepared by respectively changing the mixing ratio of the organic Hf compound and the organic Si compound to 0.01 wt %, 0.1 wt %, 0.2 wt %, and 0.5 wt % in a weight ratio (organic Hf compound/organic Si compound).

Subsequently, Hf-Si—O thin films were formed respectively by using the prepared five raw material solutions for MOCVD method. In specific, at first, five silicon substrates having a SiO₂ film (thickness of 5000 Å) on each surface were respectively prepared as substrates, and the substrates were installed in the film forming chamber of the MOCVD apparatus shown in FIG. 1. Then, a substrate temperature, a vaporization temperature and a pressure were set to 600° C., 70° C., and about 266 Pa (2 torr), respectively. O₂ gas was used as a reactant gas and its partial pressure was set at 1000 ccm. Ar gas was used as a carrier gas, and the raw material solutions for MOCVD method were fed at a rate of 0.1 g/min, respectively. The substrates were taken out by one from the film forming chamber when the film formation time reached 1 minute, 2 minutes, 3 minutes, 4 minutes, and 5 minutes, respectively.

### Example A2

Five raw material solutions for MOCVD method which differ in mixing ratio were respectively prepared in the same manner as in Example A1 except that the organic Si compound was changed to SiH[(CH₃)₂N]₃, and the Hf-Si—O thin film was formed on a substrate in the same manner as in Example A1.

### Example A3

Five raw material solutions for MOCVD method which differ in mixing ratio were respectively prepared in the same manner as in Example A1 except that the organic Si compound was changed to Si[(CH₃)₂N]₄, and the Hf-Si—O thin film was formed on a substrate in the same manner as in Example A1.

### Example A4

Five raw material solutions for MOCVD method which differ in mixing ratio were respectively prepared in the same manner as in Example A1 except that the organic Hf compound and the organic Si compound were changed to Hf[(CH₃)₂N]₄ and Si[(CH₃)₂N]₄, respectively, and the Hf-Si—O thin film was formed on a substrate in the same manner as in Example A1.

### Example A5

Five raw material solutions for MOCVD method which differ in mixing ratio were respectively prepared in the same manner as in Example A1 except that the organic Hf compound and the organic Si compound were changed to Hf[(CH₃)₂N]₄ and SiH[(CH₃)₂N]₄, respectively, and the Hf-Si—O thin film was formed on a substrate in the same manner as in Example A1.

### Example A6

Five raw material solutions for MOCVD method which differ in mixing ratio were respectively prepared in the same manner as in Example A1 except that the organic Hf compound and the organic Si compound were changed to Hf(t-C₃H₇O)₄ and SiH[(CH₃)₂N]₃, respectively, and the Hf-Si—O thin film was formed on a substrate in the same manner as in Example A1.

### Example A7

Five raw material solutions for MOCVD method which differ in mixing ratio were respectively prepared in the same manner as in Example A1 except that the organic Hf compound was changed to Hf[(CH₃)₂N]₄, and the Hf-Si—O thin film was formed on a substrate in the same manner as in Example A1.

### Example A8

Five raw material solutions for MOCVD method which differ in mixing ratio were respectively prepared in the same manner as in Example A1 except that the organic Hf compound and the organic Si compound were changed to Hf(t-C₃H₇O)₄ and Si[(CH₃)₂N]₄, respectively, and the Hf-Si—O thin film was formed on a substrate in the same manner as in Example A1.

### Comparative Example A1

Two raw material solutions for MOCVD method which differ in mixing ratio were respectively prepared in the same manner as in Example A1 except that the mixing ratios of the organic Hf compound and the organic Si compound were changed to 0.0005 wt % and 0.6 wt % in a weight ratio (organic Hf compound/organic Si compound), and the Hf-Si—O thin film was formed on a substrate in the same manner as in Example A1.

### Comparative Example A2

Hf[(C₂H₅)₂N]₄ and Si[(C₂H₅)₂N]₄ were prepared as the organic Hf compound and the organic Si compound, respectively, and these organic Si compound and the organic Hf compound were respectively used as the raw material solutions for MOCVD method. That is, two solutions were used as the raw material solutions for MOCVD by individually preparing each solution of the organic Si compound and the organic Hf compound.

Subsequently, Hf-Si—O thin films were formed by using the prepared raw material solutions for MOCVD method. In specific, at first, five silicon substrates having a SiO₂ film (thickness of 5000 Å) formed on each surface were respectively prepared as substrates, and the substrates were installed in the film forming chamber of the MOCVD apparatus shown in FIG. 3. The organic Si compound raw material solution and the organic Hf compound raw material solution were stored and sealed in the raw material container 18 and the raw material container 42, respectively. A carrier gas supplying pipe 44 was connected via a gas regulator 43 to the raw material container 42 shown in the FIG. 3. A needle valve 47 and a flow rate regulator 48 were arranged in a feed pipe 46 and the feed pipe 46 was connected to a vaporizer 26. Then, a substrate temperature, a vaporization temperature and a pressure were set to 600° C., 70° C., and about 266 Pa (2 torr), respectively. O₂ gas was used as a reactant gas and its partial pressure was set at 1000 ccm. Ar gas was used as a carrier gas, and individual raw material solutions of the organic Si compound and the organic Hf compound were fed respectively. The substrates were taken out by one from the film forming chamber when the film formation time reached 1 minute, 2 minutes, 3 minutes, 4 minutes, and 5 minutes, respectively. Supplying ratio of the organic Si compound and the organic Hf compound raw material solutions during forming the film was changed to form a Hf-Si—O thin film having a same composition to the Hf-Si—O thin film formed by using the five raw material solutions for MOCVD method which differ in mixing ratio in Examples A1 to A8.

<Comparative Test A1>

For each obtained Hf-Si—O thin film according to Examples A1 to A8 and Comparative Examples A1 and A2, a film thickness test, and a peel test to examine adhesivity, per film formation time of the obtained Hf-Si—O thin film were carried out.

(1) A Film Thickness Test

The film thickness of the Hf-Si—O thin film on the film-formed substrate was determined from a cross-sectional scanning electron microscope image.

(2) A Peel Test

Each thin film formed on a flat portion of the film-formed substrate was subjected to following peel test. At first each thin film formed on a substrate was cut by using a cutter in a predetermined size to prepare 100 cut grids. Then, adhesive cellophane tape was adhered on the thin-film prepared in girds. The tape was peeled off from the thin film, and respectively examined the number peeled off by the tape and the number remained on the substrate among the thin film cut in 100 girds.

<Evaluation>

Obtained results of the film thickness and the peel test per film formation time are respectively shown in tables 30 and 31. The peel test shows the number of remaining substrates per 100 pieces of cut grid. In the tables 30 and 31, letter ‘A’s numbering Examples and Comparative Examples are omitted.

TABLE 30
Silicon substrate - HfSiO thin film

| | | Organic Hf | | | | | | | | | | | |
|---|---|---|---|---|---|---|---|---|---|---|---|---|---|
| | Raw | compound | Mixing | Film thickness per film | | | | | Peel test | | | | |
| | material | & organic Si | ratio | formation time [nm] | | | | | [a piece/100 pieces] | | | | |
| | solution | compound | [wt %] | 1 min. | 2 min. | 3 min. | 4 min. | 5 min. | 1 min. | 2 min. | 3 min. | 4 min. | 5 min. |
| Ex. 1 | single | Hf[(C₂H₅)₂N]₄ | 0.001 | 5 | 10 | 18 | 21 | 25 | 98 | 99 | 97 | 96 | 98 |
| | solution | Si[(C₂H₅)₂N]₄ | 0.01 | 20 | 55 | 62 | 80 | 100 | 99 | 99 | 98 | 99 | 97 |
| | | | 0.1 | 25 | 50 | 76 | 100 | 130 | 99 | 98 | 97 | 98 | 99 |
| | | | 0.2 | 30 | 60 | 90 | 123 | 152 | 97 | 96 | 98 | 99 | 99 |
| | | | 0.5 | 40 | 80 | 118 | 158 | 192 | 99 | 98 | 97 | 96 | 98 |
| Ex. 2 | single | Hf[(C₂H₅)₂N]₄ | 0.001 | 10 | 20 | 30 | 38 | 48 | 98 | 97 | 98 | 96 | 96 |
| | solution | SiH[(CH₃)₂N]₃ | 0.01 | 15 | 30 | 44 | 58 | 80 | 99 | 98 | 99 | 99 | 99 |
| | | | 0.1 | 28 | 52 | 82 | 110 | 138 | 97 | 95 | 99 | 98 | 96 |
| | | | 0.2 | 30 | 60 | 89 | 119 | 145 | 96 | 96 | 96 | 96 | 98 |
| | | | 0.5 | 45 | 90 | 140 | 180 | 225 | 98 | 99 | 96 | 98 | 98 |
| Ex. 3 | single | Hf[(C₂H₅)₂N]₄ | 0.001 | 10 | 20 | 31 | 43 | 52 | 99 | 98 | 97 | 96 | 98 |
| | solution | Si[(CH₃)₂N]₄ | 0.01 | 15 | 30 | 43 | 58 | 78 | 99 | 96 | 97 | 98 | 97 |
| | | | 0.1 | 25 | 52 | 80 | 100 | 120 | 99 | 96 | 99 | 99 | 95 |
| | | | 0.2 | 40 | 80 | 110 | 154 | 200 | 99 | 98 | 99 | 99 | 99 |
| | | | 0.5 | 70 | 140 | 212 | 280 | 346 | 98 | 96 | 99 | 98 | 96 |
| Ex. 4 | single | Hf[(CH₃)₂N]₄ | 0.001 | 20 | 38 | 60 | 82 | 102 | 99 | 97 | 98 | 96 | 97 |
| | solution | Si[(CH₃)₂N]₄ | 0.01 | 26 | 50 | 72 | 100 | 126 | 99 | 97 | 97 | 99 | 98 |
| | | | 0.1 | 30 | 60 | 88 | 119 | 145 | 95 | 98 | 99 | 99 | 99 |
| | | | 0.2 | 35 | 70 | 110 | 130 | 169 | 97 | 99 | 96 | 98 | 96 |
| | | | 0.5 | 52 | 110 | 156 | 208 | 261 | 96 | 98 | 98 | 99 | 98 |
| Ex. 5 | single | Hf[(CH₃)₂N]₄ | 0.001 | 20 | 40 | 60 | 81 | 99 | 99 | 96 | 97 | 99 | 98 |
| | solution | SiH[(CH₃)₂N]₃ | 0.01 | 27 | 50 | 80 | 102 | 130 | 98 | 98 | 98 | 99 | 99 |
| | | | 0.1 | 30 | 56 | 90 | 110 | 148 | 98 | 98 | 99 | 97 | 98 |
| | | | 0.2 | 33 | 66 | 101 | 130 | 160 | 98 | 98 | 98 | 98 | 97 |
| | | | 0.5 | 50 | 100 | 151 | 198 | 248 | 98 | 96 | 97 | 99 | 99 |

TABLE 31
Silicon substrate - HfSiO thin film

| | | Organic Hf | | | | | | | Peel test | | | | |
|---|---|---|---|---|---|---|---|---|---|---|---|---|---|
| | Raw | compound | Mixing | Film thickness per film | | | | | [a piece/100 pieces] | | | | |
| | material | & organic Si | ratio | formation time [nm] | | | | | | | | 4 | 5 |
| | solution | compound | [wt %] | 1 min. | 2 min. | 3 min. | 4 min. | 5 min. | 1 min. | 2 min. | 3 min. | min. | min. |
| Ex. 6 | single | Hf(t-C₄H₉O)₄ | 0.001 | 10 | 20 | 29 | 38 | 48 | 97 | 97 | 99 | 97 | 99 |
| | solution | SiH[(CH₃)₂N]₃ | 0.01 | 18 | 40 | 54 | 70 | 89 | 98 | 98 | 97 | 97 | 99 |
| | | | 0.1 | 20 | 40 | 56 | 78 | 114 | 99 | 99 | 98 | 98 | 99 |
| | | | 0.2 | 29 | 60 | 89 | 118 | 145 | 96 | 96 | 98 | 99 | 99 |
| | | | 0.5 | 60 | 120 | 178 | 230 | 300 | 99 | 96 | 98 | 99 | 97 |
| Ex. 7 | single | Hf[(CH₃)₂N]₄ | 0.001 | 23 | 50 | 72 | 90 | 110 | 98 | 96 | 99 | 99 | 97 |
| | solution | Si[(C₂H₅)₂N]₄ | 0.01 | 19 | 40 | 60 | 80 | 100 | 98 | 99 | 99 | 98 | 99 |
| | | | 0.1 | 30 | 60 | 90 | 110 | 145 | 99 | 98 | 97 | 96 | 97 |
| | | | 0.2 | 40 | 80 | 110 | 154 | 189 | 96 | 98 | 96 | 98 | 99 |
| | | | 0.5 | 75 | 151 | 225 | 290 | 375 | 97 | 99 | 98 | 96 | 98 |
| Ex. 8 | single | Hf(t-C₄H₉O)₄ | 0.001 | 5 | 11 | 18 | 20 | 27 | 98 | 98 | 99 | 97 | 99 |
| | solution | Si[(CH₃)₂N]₄ | 0.01 | 12 | 25 | 37 | 45 | 55 | 97 | 99 | 98 | 97 | 96 |
| | | | 0.1 | 18 | 36 | 50 | 70 | 88 | 98 | 99 | 99 | 98 | 98 |
| | | | 0.2 | 30 | 60 | 90 | 115 | 148 | 98 | 97 | 97 | 97 | 99 |
| | | | 0.5 | 70 | 140 | 200 | 280 | 348 | 99 | 96 | 98 | 96 | 99 |
| Comp. | single | Hf[(C₂H₅)₂N]₄ | 0.0005 | 0.1 | 0.1 | 0.2 | 0.3 | 0.4 | 58 | 60 | 61 | 58 | 32 |
| Ex. 1 | solution | Si[(C₂H₅)₂N]₄ | 0.6 | 0.8 | 1.5 | 2 | 2.1 | 2.5 | 60 | 50 | 53 | 40 | 30 |
| Comp. | two | Hf[(CH₃)₂N]₄ | 0.001 | 0.5 | 1 | 1.7 | 2 | 2.2 | 50 | 39 | 48 | 30 | 30 |
| Ex. 2 | solutions | Si[(CH₃)₂N]₄ | 0.01 | 0.2 | 0.4 | 0.5 | 0.7 | 0.7 | 58 | 60 | 39 | 30 | 32 |
| | | | 0.1 | 0.9 | 1.6 | 2.2 | 2.8 | 3.1 | 60 | 65 | 58 | 50 | 40 |
| | | | 0.2 | 1.1 | 2 | 3 | 3.8 | 4 | 62 | 58 | 60 | 38 | 30 |
| | | | 0.5 | 0.9 | 1 | 1.3 | 1.9 | 2.5 | 65 | 50 | 60 | 40 | 28 |

As clearly shown in the tables 30 and 31, the films formed by using the raw material solution mixed in a ratio outside the range of the invention according to Comparative Example A1 were low in adhesivity and film forming rate. In addition, the films formed by using two raw material solutions according to Comparative Example A2 did not increase much in film thickness as time increases, and it was clear that the film formation is unstable.

Correspondingly, the films formed by using the single solution according to Examples A1 to A8 had a significantly high film forming rate in comparison with Comparative Examples A1 and A2, and highly stable film formation was obtained. Furthermore, according to the peel test, almost half of the grids were peeled off in the films formed by using the raw material solution mixed in a ratio outside the range of the invention according to Comparative Example 1 and the films formed by using the two raw material solutions according to Comparative Example 2, while most of the grids were remained on the substrate in films formed by using the single raw material solution according to Examples 1 to 8 and thus high adhesivity results were obtained.

### Example A9

Five raw material solutions for MOCVD method which differ in mixing ratio used in Example A1 were prepared to form a Hf-Si—O thin film. In specific, first, five silicon substrates having a SiO₂ film (thickness of 5000 Å) on each surface were respectively prepared as substrates, and the substrates were installed in the film forming chamber of the MOCVD apparatus shown in FIG. 1. Then, the substrate temperature, the vaporization temperature and the pressure were set to 600° C., 70° C., and about 266 Pa (2 torr), respectively. H₂ gas was used as a reducing gas and its partial pressure was set at 1 ccm. Ar gas was used as a carrier gas. Si[(C₂H₅)₂N]₄ was respectively fed as the organic Si compound at a rate of 0.1 g/min, and Si[(C₂H₅)₂N]₄ was thermally decomposed to grow the Si film on a surface of the substrate. Supply of the organic Si compound and the reducing gas was stopped when the film formation time reached 2 minutes. Next, O₂ gas was used as a reactant gas and its partial pressure was set at 1000 ccm. Ar gas was used as a carrier gas, and the raw material solutions for MOCVD method were respectively fed at a rate of 0.1 g/min to form the Hf-Si—O thin film on a surface of the grown Si film. The substrates were taken out by one from the film forming chamber when the film formation time reached 1 minute, 2 minutes, 3 minutes, 4 minutes, and 5 minutes, respectively.

### Comparative Example A3

Two raw material solutions for MOCVD method which differ in mixing ratio were respectively prepared in the same manner as in Example A9 except that the mixing ratios of the organic Hf compound and the organic Si compound were changed to 0.0005 wt % and 0.6 wt % in a weight ratio (organic Hf compound/organic Si compound), and the Hf-Si—O thin film was formed on a substrate in the same manner as in Example 13.

### Comparative Example A4

Two solutions used in Comparative Example A2 were prepared as the raw material solutions for MOCVD by individually preparing the organic Si compound and the organic Hf compound.

Subsequently, Hf-Si—O thin films were formed by using the prepared raw material solutions for MOCVD method. In specific, at first, five silicon substrates having a SiO₂ film (thickness of 5000 Å) formed on each surface were respectively prepared as substrates, and the substrates were installed in the film forming chamber of the MOCVD apparatus shown in FIG. 3. The organic Si compound raw material solution and the organic Hf compound raw material solution were stored and sealed in the raw material container 18 and the raw material container 42, respectively. Then, a substrate temperature, a vaporization temperature and a pressure were set to 600° C., 70° C., and about 266 Pa (2 torr), respectively. H₂ gas was used as a reducing gas and its partial pressure was set at 1 ccm. Ar gas was used as a carrier gas. Si[(C₂H₅)₂N]₄ was respectively fed as the organic Si compound at a rate of 0.1 g/min, and Si[(C₂H₅)₂N]₄ was thermally decomposed to grow the Si film on a surface of the substrate. Supply of the organic Si compound and the reducing gas was stopped when the film formation time reached 2 minutes. Next, O₂ gas was used as a reactant gas and its partial pressure was set at 1000 ccm. Ar gas was used as a carrier gas, and individual raw material solutions of the organic Si compound and the organic Hf compound were respectively fed to form the Hf-Si—O thin film on a surface of the grown Si film. The substrates were taken out by one from the film forming chamber when the film formation time reached 1 minute, 2 minutes, 3 minutes, 4 minutes, and 5 minutes, respectively. Supplying ratio of the organic Si compound and the organic Hf compound raw material solutions during forming the film was changed to form a Hf-Si—O thin film having a same composition to the Hf-Si—O thin film formed by using the five raw material solutions for MOCVD method which differ in mixing ratio in Example 13.

<Comparative Test A2>

For each obtained Hf-Si—O thin film according to Example A9 and Comparative Example A3 and A4, a film thickness test, and a peel test to examine adhesivity, per film formation time of the obtained Hf-Si—O thin film were carried out in the same manner as in above-mentioned Comparative Test A1.

<Evaluation>

Obtained results of the film thickness and the peel test per film formation time are respectively shown in table 32. The peel test shows the number of remaining substrates per 100 pieces of cut grid. In the table 32, letter ‘A’s numbering Examples and Comparative Examples are omitted.

TABLE 32
Silicon substrate-Si film-HfSiO thin film

| | | Organic Hf | | | | | | | Peel test | | | | |
|---|---|---|---|---|---|---|---|---|---|---|---|---|---|
| | Raw | compound | Mixing | Film thickness per film | | | | | [a piece/100 pieces] | | | | |
| | material | & organic Si | ratio | formation time [nm] | | | | | | | | 4 | 5 |
| | solution | compound | [wt %] | 1 min. | 2 min. | 3 min. | 4 min. | 5 min. | 1 min. | 2 min. | 3 min. | min. | min. |
| Ex. 9 | single | Hf[(C₂H₅)₂N]₄ | 0.001 | 10 | 20 | 28 | 42 | 51 | 100 | 97 | 92 | 95 | 96 |
| | solution | Si[(C₂H₅)₂N]₄ | 0.01 | 25 | 50 | 72 | 98 | 118 | 98 | 98 | 100 | 100 | 98 |
| | | | 0.1 | 30 | 61 | 88 | 118 | 148 | 100 | 99 | 99 | 98 | 99 |
| | | | 0.2 | 26 | 56 | 76 | 100 | 128 | 100 | 100 | 98 | 98 | 99 |
| | | | 0.5 | 70 | 140 | 210 | 278 | 345 | 99 | 100 | 98 | 99 | 100 |
| Comp. | single | Hf[(C₂H₅)₂N]₄ | 0.0005 | 0.1 | 0.1 | 0.2 | 0.25 | 0.31 | 65 | 60 | 50 | 20 | 25 |
| Ex. 3 | solution | Si[(C₂H₅)₂N]₄ | 0.6 | 1.1 | 1.8 | 1.9 | 2.1 | 2.7 | 60 | 65 | 70 | 72 | 78 |
| Comp. | two | Hf[(C₂H₅)₂N]₄ | 0.001 | 1 | 2 | 3 | 3.5 | 5 | 58 | 50 | 60 | 28 | 28 |
| Ex. 4 | solutions | Si[(C₂H₅)₂N]₄ | 0.01 | 0.5 | 1.2 | 1.5 | 2 | 2.2 | 60 | 53 | 58 | 40 | 30 |
| | | | 0.1 | 1 | 2.1 | 3.1 | 3.8 | 4.8 | 50 | 58 | 48 | 30 | 30 |
| | | | 0.2 | 0.8 | 1.5 | 2.2 | 3 | 3.8 | 58 | 60 | 39 | 40 | 32 |
| | | | 0.5 | 0.9 | 1.1 | 1.5 | 1.8 | 2.5 | 62 | 60 | 38 | 30 | 32 |

As clearly shown in the table 32, the films formed by using the raw material solution mixed in a ratio outside the range of the invention according to Comparative Example A3 were low in adhesivity and film forming rate. In addition, the films formed by using two raw material solutions according to Comparative Example A4 did not increase much in film thickness as time increases, and it was clear that the film formation is unstable. Also, only the low values in the peel test were obtained meaning a result of some decrease in adhesivity. Correspondingly, the films formed by using the single solution according to Example 13 had a significantly high film forming rate in comparison with Comparative Examples A3 and A4, and stable film formation was obtained. Furthermore, films having excellent adhesivity were obtained.

### Example A10

Hf[(C₂H₅)₂N]₄ and Si[(C₂H₅)O]₄ were prepared as the organic Hf compound and the organic Si compound, respectively. Next, the organic Hf compound and the organic Si compound were mixed at a room temperature in a ratio such that the weight ratio (organic Hf compound/organic Si compound) is 0.001 wt %, and the organic Hf compound was dissolved in the organic Si compound. This solution was then heated at a temperature of 60° C. for 1 hour to prepare a single solution of the raw material solution for MOCVD method. Also, total of five raw material solutions for MOCVD method which differ in mixing ratio were prepared by respectively changing the mixing ratio of the organic Hf compound and the organic Si compound to 0.01 wt %, 0.1 wt %, 0.2 wt %, and 0.5 wt % in a weight ratio (organic Hf compound/organic Si compound).

Subsequently, Hf-Si—O thin films were respectively formed on substrates by using the prepared five raw material solutions for MOCVD method in the same manner as in Example A1.

### Example A11

Five raw material solutions for MOCVD method which differ in mixing ratio were respectively prepared in the same manner as in Example A10 to form Hf-Si—O thin films on substrates in the same manner as in Example A1, except that Hf[(CH₃)₂N]₄ was used as the organic Hf compound.

### Example A12

Five raw material solutions for MOCVD method which differ in mixing ratio were respectively prepared in the same manner as in Example A10 to form Hf-Si—O thin films on substrates in the same manner as in Example A1, except that Hf[(CH₃)(C₂H₅)N]₄ was used as the organic Hf compound.

### Example A13

Five raw material solutions for MOCVD method which differ in mixing ratio were respectively prepared in the same manner as in Example A10 to form Hf-Si—O thin films on substrates in the same manner as in Example A1, except that Hf(t-C₃H₇O)₄ was used as the organic Hf compound.

<Comparative Test A3>

For each obtained Hf-Si—O thin film according to Examples A10 to A13, a film thickness test, and a peel test to examine adhesivity, per film formation time of the obtained Hf-Si—O thin film were carried out in the same manner as in the above-mentioned Comparative Test A1.

<Evaluation>

Obtained results of the film thickness and the peel test per film formation time are respectively shown in table 33. The peel test shows the number of remaining substrates per 100 pieces of cut grid. In the table 33, letter ‘A’s numbering Examples are omitted.

TABLE 33
Silicon substrate - HfSiO thin film

| | | | | | | | | | Peel test | | | | |
|---|---|---|---|---|---|---|---|---|---|---|---|---|---|
| | Raw | Organic Hf | Mixing | Film thickness per film | | | | | [a piece/100 pieces] | | | | |
| | material | compound & organic | ratio | formation time [nm] | | | | | 1 | 2 | 3 | 4 | 5 |
| | solution | Si compound | [wt %] | 1 min. | 2 min. | 3 min. | 4 min. | 5 min. | min. | min. | min. | min. | min. |
| Ex. 10 | single | Hf[(C₂H₅)₂N]₄ | 0.001 | 10 | 20 | 30 | 42 | 52 | 100 | 97 | 91 | 96 | 95 |
| | solution | Si[(C₂H₅)O]₄ | 0.01 | 20 | 40 | 60 | 78 | 98 | 95 | 100 | 98 | 97 | 99 |
| | | | 0.1 | 30 | 51 | 89 | 108 | 142 | 95 | 98 | 96 | 93 | 99 |
| | | | 0.2 | 20 | 40 | 101 | 81 | 98 | 100 | 99 | 98 | 99 | 98 |
| | | | 0.5 | 60 | 118 | 170 | 230 | 301 | 99 | 100 | 99 | 100 | 99 |
| Ex. 11 | single | Hf[(CH₃)₂N]₄ | 0.001 | 15 | 30 | 45 | 60 | 75 | 100 | 92 | 98 | 96 | 99 |
| | solution | (C₂H₅)O]₄ | 0.01 | 10 | 21 | 28 | 38 | 48 | 98 | 99 | 96 | 91 | 95 |
| | | | 0.1 | 25 | 51 | 70 | 98 | 120 | 99 | 100 | 99 | 98 | 96 |
| | | | 0.2 | 30 | 60 | 81 | 112 | 140 | 99 | 98 | 95 | 91 | 92 |
| | | | 0.5 | 20 | 40 | 60 | 81 | 91 | 100 | 99 | 95 | 93 | 92 |
| Ex. 12 | single | Hf[(CH₃)(C₂H₅)N]₄ | 0.001 | 18 | 38 | 53 | 70 | 88 | 91 | 93 | 94 | 95 | 93 |
| | solution | Si[(C₂H₅)O]₄ | 0.01 | 23 | 45 | 65 | 90 | 115 | 100 | 99 | 98 | 99 | 95 |
| | | | 0.1 | 40 | 80 | 112 | 156 | 196 | 96 | 95 | 93 | 92 | 98 |
| | | | 0.2 | 52 | 100 | 150 | 200 | 246 | 98 | 99 | 95 | 93 | 92 |
| | | | 0.5 | 60 | 118 | 181 | 241 | 300 | 95 | 99 | 98 | 99 | 100 |
| Ex. 13 | single | Hf(t-C₃H₇O)₄ | 0.001 | 10 | 20 | 30 | 40 | 50 | 98 | 99 | 99 | 100 | 99 |
| | solution | Si[(C₂H₅)O]₄ | 0.01 | 15 | 30 | 42 | 60 | 70 | 100 | 97 | 96 | 93 | 91 |
| | | | 0.1 | 30 | 58 | 83 | 118 | 118 | 99 | 98 | 99 | 97 | 96 |
| | | | 0.2 | 45 | 90 | 121 | 170 | 220 | 100 | 100 | 99 | 98 | 98 |
| | | | 0.5 | 60 | 118 | 179 | 230 | 310 | 97 | 96 | 95 | 98 | 97 |

As clearly shown in the table 33, the films formed by using the single raw material solution according to Examples A10 to 13 had a significantly high film forming rate and stable film formation was obtained. Furthermore, films having excellent adhesivity were obtained.

### Examples A14 to A18

Five raw material solutions for MOCVD method which differ in mixing ratio were respectively prepared in the same manner as in Example A1 to form Hf-Si—O thin films on substrates in the same manner as in Example A1, except that Si[(CH₃)₂N]₄ was used as the organic Si compound, and Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A19 to A23

Five raw material solutions for MOCVD method which differ in mixing ratio were respectively prepared in the same manner as in Example A1 to form Hf-Si—O thin films on substrates in the same manner as in Example A1, except that Si[(C₂H₅)₂N]₄ was used as the organic Si compound, and Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A24 to A30

Five raw material solutions for MOCVD method which differ in mixing ratio were respectively prepared in the same manner as in Example A1 to form Hf-Si—O thin films on substrates in the same manner as in Example A1, except that Si[(n-C₃H₇)₂N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A31 to A37

Five raw material solutions for MOCVD method which differ in mixing ratio were respectively prepared in the same manner as in Example A1 to form Hf-Si—O thin films on substrates in the same manner as in Example A1, except that Si[(n-C₄H₉)₂N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A38 to A44

Five raw material solutions for MOCVD method which differ in mixing ratio were respectively prepared in the same manner as in Example A1 to form Hf-Si—O thin films on substrates in the same manner as in Example A1, except that Si[(CH₃)(C₂H₅)N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A45 to A51

Five raw material solutions for MOCVD method which differ in mixing ratio were respectively prepared in the same manner as in Example A1 to form Hf-Si—O thin films on substrates in the same manner as in Example A1, except that Si[(CH₃)(n-C₃H₇)N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A52 to A58

Five raw material solutions for MOCVD method which differ in mixing ratio were respectively prepared in the same manner as in Example A1 to form Hf-Si—O thin films on substrates in the same manner as in Example A1, except that Si[(CH₃)(n-C₄H₉)N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A59 to A65

Five raw material solutions for MOCVD method which differ in mixing ratio were respectively prepared in the same manner as in Example A1 to form Hf-Si—O thin films on substrates in the same manner as in Example A1, except that Si[(C₂H₅)(n-C₃H₇)N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A66 to A72

Five raw material solutions for MOCVD method which differ in mixing ratio were respectively prepared in the same manner as in Example A1 to form Hf-Si—O thin films on substrates in the same manner as in Example A1, except that Si[(C₂H₅)(n-C₄H₉)N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A73 to A79

Five raw material solutions for MOCVD method which differ in mixing ratio were respectively prepared in the same manner as in Example A1 to form Hf-Si—O thin films on substrates in the same manner as in Example A1, except that Si(CH₃O)₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A80 to A83

Five raw material solutions for MOCVD method which differ in mixing ratio were respectively prepared in the same manner as in Example A1 to form Hf-Si—O thin films on substrates in the same manner as in Example A1, except that Si(C₂H₅O)₄ was used as the organic Si compound, and Hf(CH₃O)₄, Hf(C₂H₅O)₄, Hf(n-C₃H₇O)₄ and Hf(n-C₄H₉O)₄ were used as the organic Hf compound.

### Examples A84 to A90

Five raw material solutions for MOCVD method which differ in mixing ratio were respectively prepared in the same manner as in Example A1 to form Hf-Si—O thin films on substrates in the same manner as in Example A1, except that Si(n-C₃H₇O)₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A91 to A97

Five raw material solutions for MOCVD method which differ in mixing ratio were respectively prepared in the same manner as in Example A1 to form Hf-Si—O thin films on substrates in the same manner as in Example A1, except that Si(n-C₄H₉O)₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

<Comparative Test A4>

For each obtained Hf-Si—O thin film according to Examples A14 to A97, a film thickness test, and a peel test to examine adhesivity, per film formation time of the obtained Hf-Si—O thin film were carried out in the same manner as in the above-mentioned Comparative Test A1.

<Evaluation>

Obtained results of the film thickness and the peel test per film formation time are respectively shown in tables 34 to 50. The peel test shows the number of remaining substrates per 100 pieces of cut grid. In the tables 34 to 50, letter ‘A’s numbering Examples are omitted.

TABLE 34
Silicon substrate - HfSiO thin film

| | Organic Hf | | | | | | | Peel test | | | | |
|---|---|---|---|---|---|---|---|---|---|---|---|---|
| Raw | compound | Mixing | Film thickness per film | | | | | [a piece/100 pieces] | | | | |
| material | & organic Si | ratio | formation time [nm] | | | | | | | 3 | 4 | 5 |
| solution | compound | [wt %] | 1 min. | 2 min. | 3 min. | 4 min. | 5 min. | 1 min. | 2 min. | min. | min. | min. |

| | | | | | | | | | |
|---|---|---|---|---|---|---|---|---|---|
| Ex. 14 | Single | Hf[(CH₃)(C₂H₅)N]₄ | 0.001 | 18 | 35 | 44 | 72 | 74 | 90 to 92 |
| | solution | Si[(CH₃)₂N]₄ | 0.01 | 20 | 34 | 51 | 74 | 80 | |
| | | | 0.1 | 23 | 42 | 63 | 79 | 92 | |
| | | | 0.2 | 31 | 45 | 59 | 79 | 92 | |
| | | | 0.5 | 47 | 78 | 120 | 150 | 200 | |
| Ex. 15 | Single | Hf(CH₃O)₄ | 0.001 | 13 | 30 | 40 | 60 | 72 | 90 to 92 |
| | solution | Si[(CH₃)₂N]₄ | 0.01 | 16 | 30 | 48 | 63 | 78 | |
| | | | 0.1 | 20 | 38 | 60 | 70 | 98 | |
| | | | 0.2 | 25 | 36 | 60 | 79 | 101 | |
| | | | 0.5 | 43 | 70 | 120 | 140 | 200 | |
| Ex. 16 | Single | Hf(C₂H₅O)₄ | 0.001 | 10 | 20 | 58 | 80 | 96 | 95 to 96 |
| | solution | Si[(CH₃)₂N]₄ | 0.01 | 20 | 39 | 40 | 60 | 70 | |
| | | | 0.1 | 28 | 48 | 88 | 117 | 140 | |
| | | | 0.2 | 30 | 60 | 110 | 149 | 150 | |
| | | | 0.5 | 33 | 100 | 130 | 150 | 200 | |
| Ex. 17 | Single | Hf(n-C₃H₉O)₄ | 0.001 | 20 | 32 | 36 | 48 | 56 | 94 to 95 |
| | solution | Si[(CH₃)₂N]₄ | 0.01 | 18 | 40 | 50 | 73 | 90 | |
| | | | 0.1 | 30 | 60 | 70 | 120 | 130 | |
| | | | 0.2 | 40 | 70 | 88 | 130 | 156 | |
| | | | 0.5 | 56 | 101 | 120 | 192 | 208 | |
| Ex. 18 | Single | Hf(n-C₄H₉O)₄ | 0.001 | 13 | 21 | 40 | 62 | 73 | 99 to 100 |
| | solution | Si[(CH₃)₂N]₄ | 0.01 | 21 | 38 | 48 | 60 | 79 | |
| | | | 0.1 | 28 | 48 | 60 | 70 | 89 | |
| | | | 0.2 | 32 | 60 | 68 | 81 | 100 | |
| | | | 0.5 | 41 | 110 | 120 | 130 | 200 | |

TABLE 35
Silicon substrate - HfSiO thin film

| | Organic Hf | | | | | | | Peel test | | | | |
|---|---|---|---|---|---|---|---|---|---|---|---|---|
| Raw | compound | Mixing | Film thickness per film | | | | | [a piece/100 pieces] | | | | |
| material | & organic Si | ratio | formation time [nm] | | | | | 1 | 2 | 3 | 4 | 5 |
| solution | compound | [wt %] | 1 min. | 2 min. | 3 min. | 4 min. | 5 min. | min. | min. | min. | min. | min. |

| | | | | | | | | | |
|---|---|---|---|---|---|---|---|---|---|
| Ex. 19 | Single | Hf[(CH₃)(C₂H₅)N]₄ | 0.001 | 19 | 38 | 48 | 51 | 63 | 95 to 98 |
| | solution | Si[(C₂H₅)₂N]₄ | 0.01 | 20 | 44 | 52 | 73 | 92 | |
| | | | 0.1 | 31 | 60 | 68 | 118 | 140 | |
| | | | 0.2 | 43 | 70 | 91 | 130 | 160 | |
| | | | 0.5 | 56 | 100 | 120 | 190 | 199 | |
| Ex. 20 | Single | Hf(CH₃O)₄ | 0.001 | 14 | 32 | 43 | 68 | 74 | 90 to 92 |
| | solution | Si[(C₂H₅)₂N]₄ | 0.01 | 18 | 32 | 50 | 69 | 80 | |
| | | | 0.1 | 21 | 39 | 63 | 78 | 90 | |
| | | | 0.2 | 29 | 40 | 58 | 77 | 99 | |
| | | | 0.5 | 45 | 73 | 127 | 147 | 201 | |
| Ex. 21 | Single | Hf(C₂H₅O)₄ | 0.001 | 12 | 22 | 60 | 78 | 90 | 95 to 96 |
| | solution | Si[(C₂H₅)₂N]₄ | 0.01 | 23 | 44 | 49 | 61 | 73 | |
| | | | 0.1 | 29 | 50 | 90 | 116 | 138 | |
| | | | 0.2 | 31 | 63 | 112 | 138 | 160 | |
| | | | 0.5 | 32 | 98 | 131 | 149 | 201 | |
| Ex. 22 | Single | Hf(n-C₃H₉O)₄ | 0.001 | 23 | 35 | 38 | 48 | 59 | 96 to 98 |
| | solution | Si[(C₂H₅)₂N]₄ | 0.01 | 17 | 40 | 49 | 70 | 89 | |
| | | | 0.1 | 31 | 61 | 68 | 119 | 131 | |
| | | | 0.2 | 40 | 68 | 90 | 129 | 160 | |
| | | | 0.5 | 58 | 110 | 127 | 189 | 201 | |
| Ex. 23 | Single | Hf(n-C₄H₉O)₄ | 0.001 | 14 | 22 | 43 | 68 | 75 | 99 to 100 |
| | solution | Si[(C₂H₅)₂N]₄ | 0.01 | 23 | 40 | 45 | 61 | 80 | |
| | | | 0.1 | 28 | 47 | 61 | 72 | 90 | |
| | | | 0.2 | 32 | 56 | 67 | 81 | 98 | |
| | | | 0.5 | 43 | 110 | 128 | 140 | 210 | |

TABLE 36
Silicon substrate - HfSiO thin film

| | Organic Hf | | | | | | | Peel test | | | | |
|---|---|---|---|---|---|---|---|---|---|---|---|---|
| Raw | compound & | Mixing | Film thickness per film | | | | | [a piece/100 pieces] | | | | |
| material | organic | ratio | formation time [nm] | | | | | | | 3 | 4 | 5 |
| solution | Si compound | [wt %] | 1 min. | 2 min. | 3 min. | 4 min. | 5 min. | 1 min. | 2 min. | min. | min. | min. |

| | | | | | | | | | |
|---|---|---|---|---|---|---|---|---|---|
| Ex. 24 | Single | Hf[(CH₃)₂N]₄ | 0.001 | 15 | 24 | 45 | 70 | 78 | 98 to 99 |
| | solution | Si[(n-C₃H₇)₂N]₄ | 0.01 | 23 | 39 | 46 | 64 | 80 | |
| | | | 0.1 | 30 | 46 | 62 | 74 | 90 | |
| | | | 0.2 | 34 | 58 | 69 | 80 | 98 | |
| | | | 0.5 | 45 | 110 | 130 | 140 | 200 | |
| Ex. 25 | Single | Hf[(C₂H₅)₂N]₄ | 0.001 | 21 | 37 | 40 | 51 | 63 | 99 to 100 |
| | solution | Si[(n-C₃H₇)₂N]₄ | 0.01 | 19 | 44 | 51 | 73 | 92 | |
| | | | 0.1 | 31 | 62 | 69 | 118 | 142 | |
| | | | 0.2 | 42 | 69 | 90 | 130 | 160 | |
| | | | 0.5 | 58 | 109 | 120 | 182 | 198 | |
| Ex. 26 | Single | Hf[(CH₃)(C₂H₅)N]₄ | 0.001 | 13 | 24 | 62 | 82 | 90 | 99 to 100 |
| | solution | Si[(n-C₃H₇)₂N]₄ | 0.01 | 24 | 44 | 51 | 63 | 78 | |
| | | | 0.1 | 31 | 54 | 90 | 110 | 130 | |
| | | | 0.2 | 30 | 63 | 100 | 113 | 160 | |
| | | | 0.5 | 32 | 90 | 124 | 148 | 182 | |
| Ex. 27 | Single | Hf(CH₃O)₄ | 0.001 | 15 | 31 | 41 | 61 | 72 | 90 to 92 |
| | solution | Si[(n-C₃H₇)₂N]₄ | 0.01 | 18 | 32 | 49 | 64 | 75 | |
| | | | 0.1 | 22 | 40 | 62 | 71 | 98 | |
| | | | 0.2 | 26 | 37 | 62 | 75 | 101 | |
| | | | 0.5 | 44 | 72 | 122 | 132 | 201 | |
| Ex. 28 | Single | Hf(C₂H₅O)₄ | 0.001 | 11 | 21 | 59 | 82 | 95 | 95 to 96 |
| | solution | Si[(n-C₃H₇)₂N]₄ | 0.01 | 25 | 40 | 42 | 63 | 72 | |
| | | | 0.1 | 30 | 49 | 89 | 110 | 142 | |
| | | | 0.2 | 31 | 61 | 111 | 140 | 150 | |
| | | | 0.5 | 37 | 102 | 132 | 152 | 201 | |

TABLE 37
Silicon substrate - HfSiO thin film

| | Organic Hf | | | | | | | Peel test | | | | |
|---|---|---|---|---|---|---|---|---|---|---|---|---|
| Raw | compound | Mixing | Film thickness per film | | | | | [a piece/100 pieces] | | | | |
| material | & organic Si | ratio | formation time [nm] | | | | | | | 3 | 4 | 5 |
| solution | compound | [wt %] | 1 min. | 2 min. | 3 min. | 4 min. | 5 min. | 1 min. | 2 min. | min. | min. | min. |

| | | | | | | | | | |
|---|---|---|---|---|---|---|---|---|---|
| Ex. 29 | Single | Hf(n-C₃H₇O)₄ | 0.001 | 21 | 33 | 37 | 49 | 57 | 96 to 98 |
| | solution | Si[(n-C₃H₇)₂N]₄ | 0.01 | 19 | 42 | 50 | 74 | 99 | |
| | | | 0.1 | 30 | 63 | 71 | 121 | 132 | |
| | | | 0.2 | 41 | 72 | 98 | 135 | 157 | |
| | | | 0.5 | 57 | 101 | 113 | 192 | 200 | |
| Ex. 30 | Single | Hf(n-C₄H₉O)₄ | 0.001 | 14 | 22 | 40 | 62 | 74 | 99 to 100 |
| | solution | Si[(n-C₃H₇)₂N]₄ | 0.01 | 22 | 38 | 45 | 60 | 79 | |
| | | | 0.1 | 29 | 50 | 62 | 73 | 88 | |
| | | | 0.2 | 33 | 61 | 65 | 80 | 100 | |
| | | | 0.5 | 42 | 112 | 119 | 131 | 201 | |
| Ex. 31 | Single | Hf[(CH₃)₂N]₄ | 0.001 | 20 | 40 | 52 | 63 | 88 | 98 to 99 |
| | solution | Si[(n-C₄H₉)₂N]₄ | 0.01 | 20 | 38 | 49 | 67 | 92 | |
| | | | 0.1 | 32 | 48 | 67 | 92 | 123 | |
| | | | 0.2 | 41 | 72 | 89 | 120 | 146 | |
| | | | 0.5 | 60 | 100 | 105 | 150 | 201 | |
| Ex. 32 | Single | Hf[(C₂H₅)₂N]₄ | 0.001 | 13 | 21 | 57 | 69 | 72 | 99 to 100 |
| | solution | Si[(n-C₄H₉)₂N]₄ | 0.01 | 24 | 38 | 48 | 69 | 93 | |
| | | | 0.1 | 28 | 52 | 62 | 68 | 94 | |
| | | | 0.2 | 32 | 63 | 68 | 78 | 99 | |
| | | | 0.5 | 45 | 98 | 118 | 120 | 147 | |
| Ex. 33 | Single | Hf[(CH₃)(C₂H₅)N]₄ | 0.001 | 14 | 32 | 42 | 62 | 72 | 98 to 99 |
| | solution | Si[(n-C₄H₉)₂N]₄ | 0.01 | 20 | 33 | 50 | 73 | 90 | |
| | | | 0.1 | 21 | 42 | 62 | 82 | 99 | |
| | | | 0.2 | 23 | 41 | 61 | 76 | 101 | |
| | | | 0.5 | 40 | 70 | 112 | 140 | 168 | |

TABLE 38
Silicon substrate - HfSiO thin film

| | | | | | | | | Peel test | | | | |
|---|---|---|---|---|---|---|---|---|---|---|---|---|
| Raw | Organic Hf compound | Mixing | Film thickness per film | | | | | [a piece/100 pieces] | | | | |
| material | & organic Si | ratio | formation time [nm] | | | | | 1 | 2 | 3 | 4 | 5 |
| solution | compound | [wt %] | 1 min. | 2 min. | 3 min. | 4 min. | 5 min. | min. | min. | min. | min. | min. |

| | | | | | | | | | |
|---|---|---|---|---|---|---|---|---|---|
| Ex. 34 | Single | Hf(CH₃O)₄ | 0.001 | 14 | 30 | 40 | 60 | 70 | 90 to 92 |
| | solution | Si[(n-C₄H₉)₂N]₄ | 0.01 | 20 | 30 | 49 | 70 | 89 | |
| | | | 0.1 | 20 | 40 | 60 | 80 | 98 | |
| | | | 0.2 | 30 | 41 | 60 | 75 | 100 | |
| | | | 0.5 | 48 | 76 | 120 | 150 | 198 | |
| Ex. 35 | Single | Hf(C₂H₅O)₄ | 0.001 | 13 | 24 | 56 | 80 | 98 | 98 to 99 |
| | solution | Si[(n-C₄H₉)₂N]₄ | 0.01 | 20 | 40 | 50 | 58 | 68 | |
| | | | 0.1 | 30 | 45 | 89 | 120 | 141 | |
| | | | 0.2 | 34 | 60 | 110 | 140 | 158 | |
| | | | 0.5 | 30 | 100 | 121 | 151 | 200 | |
| Ex. 36 | Single | Hf(n-C₃H₇O)₄ | 0.001 | 20 | 40 | 51 | 62 | 88 | 98 to 99 |
| | solution | Si[(n-C₄H₉)₂N]₄ | 0.01 | 20 | 39 | 49 | 67 | 90 | |
| | | | 0.1 | 31 | 49 | 67 | 100 | 121 | |
| | | | 0.2 | 40 | 70 | 88 | 130 | 159 | |
| | | | 0.5 | 59 | 109 | 117 | 179 | 207 | |
| Ex. 37 | Single | Hf(n-C₄H₉O)₄ | 0.001 | 13 | 20 | 56 | 69 | 70 | 99 to 100 |
| | solution | Si[(n-C₄H₉)₂N]₄ | 0.01 | 23 | 38 | 47 | 68 | 90 | |
| | | | 0.1 | 29 | 50 | 60 | 68 | 91 | |
| | | | 0.2 | 31 | 60 | 67 | 79 | 100 | |
| | | | 0.5 | 40 | 99 | 117 | 127 | 156 | |
| Ex. 38 | Single | Hf[(CH₃)₂N]₄ | 0.001 | 14 | 21 | 58 | 70 | 96 | 99 to 100 |
| | solution | Si[(CH₃)(C₂H₅)N]₄ | 0.01 | 20 | 44 | 57 | 60 | 68 | |
| | | | 0.1 | 31 | 42 | 80 | 102 | 125 | |
| | | | 0.2 | 32 | 46 | 80 | 110 | 123 | |
| | | | 0.5 | 42 | 69 | 92 | 121 | 139 | |

TABLE 39
Silicon substrate - HfSiO thin film

| | | | | | | | | Peel test | | | | |
|---|---|---|---|---|---|---|---|---|---|---|---|---|
| Raw | Organic Hf | Mixing | Film thickness per film | | | | | [a piece/100 pieces] | | | | |
| material | compound & organic | ratio | formation time [nm] | | | | | 1 | 2 | 3 | 4 | 5 |
| solution | Si compound | [wt %] | 1 min. | 2 min. | 3 min. | 4 min. | 5 min. | min. | min. | min. | min. | min. |

| | | | | | | | | | |
|---|---|---|---|---|---|---|---|---|---|
| Ex. 39 | Single | Hf[(C₂H₅)₂N]₄ | 0.001 | 20 | 44 | 51 | 61 | 92 | 99 to 100 |
| | solution | Si[(CH₃)(C₂H₅)N]₄ | 0.01 | 14 | 32 | 44 | 58 | 70 | |
| | | | 0.1 | 31 | 43 | 56 | 62 | 72 | |
| | | | 0.2 | 38 | 64 | 80 | 94 | 110 | |
| | | | 0.5 | 62 | 110 | 122 | 179 | 182 | |
| Ex. 40 | Single | Hf[(CH₃)(C₂H₅)N]₄ | 0.001 | 18 | 42 | 49 | 61 | 92 | 92 to 94 |
| | solution | Si[(CH₃)(C₂H₅)N]₄ | 0.01 | 21 | 40 | 52 | 62 | 89 | |
| | | | 0.1 | 30 | 51 | 61 | 90 | 100 | |
| | | | 0.2 | 31 | 47 | 60 | 89 | 110 | |
| | | | 0.5 | 39 | 90 | 105 | 102 | 148 | |
| Ex. 41 | Single | Hf(CH₃O)₄ | 0.001 | 15 | 33 | 43 | 69 | 73 | 90 to 92 |
| | solution | Si[(CH₃)(C₂H₅)N]₄ | 0.01 | 18 | 33 | 50 | 72 | 81 | |
| | | | 0.1 | 20 | 40 | 64 | 78 | 92 | |
| | | | 0.2 | 30 | 42 | 58 | 79 | 99 | |
| | | | 0.5 | 46 | 74 | 127 | 149 | 202 | |
| Ex. 42 | Single | Hf(C₂H₅O)₄ | 0.001 | 13 | 23 | 61 | 80 | 93 | 95 to 96 |
| | solution | Si[(CH₃)(C₂H₅)N]₄ | 0.01 | 24 | 45 | 50 | 62 | 74 | |
| | | | 0.1 | 30 | 55 | 92 | 112 | 140 | |
| | | | 0.2 | 30 | 62 | 113 | 142 | 162 | |
| | | | 0.5 | 30 | 99 | 132 | 150 | 202 | |
| Ex. 43 | Single | Hf(n-C₃H₇O)₄ | 0.001 | 20 | 36 | 39 | 50 | 60 | 95 to 96 |
| | solution | Si[(CH₃)(C₂H₅)N]₄ | 0.01 | 18 | 42 | 50 | 72 | 90 | |
| | | | 0.1 | 30 | 63 | 69 | 119 | 141 | |
| | | | 0.2 | 42 | 69 | 92 | 130 | 162 | |
| | | | 0.5 | 59 | 110 | 128 | 192 | 200 | |

TABLE 40
Silicon substrate - HfSiO thin film

| | | | | | | | | Peel test | | | | |
|---|---|---|---|---|---|---|---|---|---|---|---|---|
| Raw | Organic Hf | Mixing | Film thickness per film | | | | | [a piece/100 pieces] | | | | |
| material | compound & organic | ratio | formation time [nm] | | | | | 1 | 2 | 3 | 4 | 5 |
| solution | Si compound | [wt %] | 1 min. | 2 min. | 3 min. | 4 min. | 5 min. | min. | min. | min. | min. | min. |

| | | | | | | | | | |
|---|---|---|---|---|---|---|---|---|---|
| Ex. 44 | Single | Hf(n-C₄H₉O)₄ | 0.001 | 15 | 23 | 44 | 69 | 76 | 98 to 99 |
| | solution | Si[(CH₃)(C₂H₅)N]₄ | 0.01 | 24 | 38 | 45 | 63 | 81 | |
| | | | 0.1 | 29 | 45 | 63 | 73 | 92 | |
| | | | 0.2 | 33 | 57 | 69 | 82 | 99 | |
| | | | 0.5 | 44 | 112 | 128 | 141 | 203 | |
| Ex. 45 | Single | Hf[(CH₃)₂N]₄ | 0.001 | 16 | 33 | 43 | 63 | 70 | 92 to 94 |
| | solution | Si[(CH₃)(n-C₃H₇)N]₄ | 0.01 | 23 | 32 | 51 | 72 | 81 | |
| | | | 0.1 | 24 | 40 | 61 | 80 | 90 | |
| | | | 0.2 | 32 | 43 | 61 | 76 | 110 | |
| | | | 0.5 | 51 | 72 | 132 | 150 | 192 | |
| Ex. 46 | Single | Hf[(C₂H₅)₂N]₄ | 0.001 | 18 | 29 | 59 | 89 | 100 | 97 to 98 |
| | solution | Si[(CH₃)(n-C₃H₇)N]₄ | 0.01 | 27 | 44 | 59 | 67 | 72 | |
| | | | 0.1 | 32 | 50 | 92 | 122 | 159 | |
| | | | 0.2 | 36 | 63 | 118 | 148 | 162 | |
| | | | 0.5 | 35 | 108 | 130 | 153 | 200 | |
| Ex. 47 | Single | Hf[(CH₃)(C₂H₅)N]₄ | 0.001 | 21 | 43 | 54 | 64 | 90 | 98 to 99 |
| | solution | Si[(CH₃)(n-C₃H₇)N]₄ | 0.01 | 24 | 42 | 52 | 70 | 93 | |
| | | | 0.1 | 33 | 53 | 70 | 112 | 123 | |
| | | | 0.2 | 44 | 73 | 92 | 134 | 162 | |
| | | | 0.5 | 62 | 109 | 120 | 182 | 206 | |
| Ex. 48 | Single | Hf(CH₃O)₄ | 0.001 | 17 | 32 | 43 | 58 | 69 | 93 to 94 |
| | solution | Si[(CH₃)(n-C₃H₇)N]₄ | 0.01 | 20 | 30 | 50 | 68 | 90 | |
| | | | 0.1 | 27 | 40 | 57 | 79 | 97 | |
| | | | 0.2 | 30 | 40 | 59 | 70 | 90 | |
| | | | 0.5 | 45 | 78 | 117 | 146 | 201 | |

TABLE 41
Silicon substrate - HfSiO thin film

| | | | | | | | | Peel test | | | | |
|---|---|---|---|---|---|---|---|---|---|---|---|---|
| Raw | Organic Hf compound | Mixing | Film thickness per film | | | | | [a piece/100 pieces] | | | | |
| material | & organic Si | ratio | formation time [nm] | | | | | | 2 | 3 | 4 | 5 |
| solution | compound | [wt %] | 1 min. | 2 min. | 3 min. | 4 min. | 5 min. | 1 min. | min. | min. | min. | min. |

| | | | | | | | | | |
|---|---|---|---|---|---|---|---|---|---|
| Ex. 49 | Single | Hf(C₂H₅O)₄ | 0.001 | 14 | 20 | 57 | 69 | 95 | 95 to 96 |
| | solution | Si[(CH₃)(n-C₃H₇)N]₄ | 0.01 | 20 | 43 | 56 | 59 | 67 | |
| | | | 0.1 | 30 | 40 | 79 | 101 | 127 | |
| | | | 0.2 | 29 | 45 | 79 | 110 | 122 | |
| | | | 0.5 | 40 | 68 | 90 | 120 | 140 | |
| Ex. 50 | Single | Hf(n-C₃H₇O)₄ | 0.001 | 20 | 42 | 50 | 60 | 90 | 95 to 96 |
| | solution | Si[(CH₃)(n-C₃H₇)N]₄ | 0.01 | 14 | 31 | 43 | 58 | 69 | |
| | | | 0.1 | 30 | 42 | 56 | 62 | 69 | |
| | | | 0.2 | 37 | 63 | 80 | 93 | 120 | |
| | | | 0.5 | 60 | 110 | 120 | 180 | 193 | |
| Ex. 51 | Single | Hf(n-C₄H₉O)₄ | 0.001 | 18 | 40 | 49 | 60 | 90 | 95 to 96 |
| | solution | Si[(CH₃)(n-C₃H₇)N]₄ | 0.01 | 20 | 42 | 50 | 60 | 88 | |
| | | | 0.1 | 29 | 50 | 62 | 92 | 101 | |
| | | | 0.2 | 30 | 48 | 62 | 92 | 120 | |
| | | | 0.5 | 38 | 90 | 110 | 120 | 149 | |
| Ex. 52 | Single | Hf[(CH₃)₂N]₄ | 0.001 | 18 | 30 | 44 | 61 | 72 | 98 to 99 |
| | solution | Si[(CH₃)(n-C₄H₉)N]₄ | 0.01 | 22 | 39 | 49 | 72 | 89 | |
| | | | 0.1 | 31 | 44 | 62 | 82 | 101 | |
| | | | 0.2 | 32 | 40 | 61 | 72 | 92 | |
| | | | 0.5 | 44 | 81 | 120 | 140 | 200 | |
| Ex. 53 | Single | Hf[(C₂H₅)₂N]₄ | 0.001 | 21 | 43 | 59 | 69 | 71 | 99 to 100 |
| | solution | Si[(CH₃)(n-C₄H₉)N]₄ | 0.01 | 21 | 42 | 49 | 57 | 92 | |
| | | | 0.1 | 31 | 50 | 64 | 93 | 101 | |
| | | | 0.2 | 35 | 51 | 62 | 82 | 113 | |
| | | | 0.5 | 37 | 90 | 101 | 120 | 140 | |

TABLE 42
Silicon substrate - HfSiO thin film

| | | | | | | | | Peel test | | | | |
|---|---|---|---|---|---|---|---|---|---|---|---|---|
| Raw | Organic Hf | Mixing | Film thickness per film | | | | | [a piece/100 pieces] | | | | |
| material | compound & organic | ratio | formation time [nm] | | | | | 1 | 2 | 3 | 4 | 5 |
| solution | Si compound | [wt %] | 1 min. | 2 min. | 3 min. | 4 min. | 5 min. | min. | min. | min. | min. | min. |

| | | | | | | | | | |
|---|---|---|---|---|---|---|---|---|---|
| Ex. 54 | Single | Hf[(CH₃)(C₂H₅)N]₄ | 0.001 | 17 | 30 | 42 | 61 | 72 | 90 to 92 |
| | solution | Si[(CH₃)(n-C₄H₉)N]₄ | 0.01 | 20 | 39 | 49 | 70 | 89 | |
| | | | 0.1 | 32 | 44 | 60 | 80 | 100 | |
| | | | 0.2 | 31 | 39 | 60 | 70 | 92 | |
| | | | 0.5 | 44 | 81 | 120 | 130 | 200 | |
| Ex. 55 | Single | Hf(CH₃O)₄ | 0.001 | 15 | 31 | 42 | 62 | 72 | 92 to 94 |
| | solution | Si[(CH₃)(n-C₄H₉)N]₄ | 0.01 | 22 | 32 | 50 | 70 | 90 | |
| | | | 0.1 | 23 | 41 | 62 | 81 | 98 | |
| | | | 0.2 | 31 | 42 | 62 | 76 | 110 | |
| | | | 0.5 | 50 | 77 | 130 | 151 | 192 | |
| Ex. 56 | Single | Hf(C₂H₅O)₄ | 0.001 | 14 | 25 | 57 | 82 | 99 | 90 to 92 |
| | solution | Si[(CH₃)(n-C₄H₉)N]₄ | 0.01 | 22 | 41 | 57 | 59 | 69 | |
| | | | 0.1 | 31 | 46 | 90 | 120 | 151 | |
| | | | 0.2 | 35 | 61 | 120 | 141 | 159 | |
| | | | 0.5 | 31 | 102 | 122 | 151 | 201 | |
| Ex. 57 | Single | Hf(n-C₃H₇O)₄ | 0.001 | 21 | 42 | 52 | 62 | 89 | 92 to 94 |
| | solution | Si[(CH₃)(n-C₄H₉)N]₄ | 0.01 | 23 | 40 | 50 | 67 | 91 | |
| | | | 0.1 | 32 | 50 | 67 | 110 | 122 | |
| | | | 0.2 | 42 | 72 | 90 | 132 | 159 | |
| | | | 0.5 | 60 | 110 | 120 | 180 | 207 | |
| Ex. 58 | Single | Hf(n-C₄H₉O)₄ | 0.001 | 14 | 21 | 56 | 70 | 72 | 95 to 96 |
| | solution | Si[(CH₃)(n-C₄H₉)N]₄ | 0.01 | 24 | 40 | 47 | 70 | 92 | |
| | | | 0.1 | 29 | 51 | 62 | 69 | 93 | |
| | | | 0.2 | 32 | 62 | 66 | 80 | 101 | |
| | | | 0.5 | 42 | 98 | 110 | 127 | 160 | |

TABLE 43
Silicon substrate - HfSiO thin film

| Raw | Organic Hf compound | Mixing | Film thickness per film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 59 | Single | Hf[(CH₃)₂N]₄ | 0.001 | 20 | 35 | 42 | 64 | 74 | 98 to 99 |
| | solution | Si[(C₂H₅)(n-C₃H₇)N]₄ | 0.01 | 24 | 34 | 53 | 74 | 94 | |
| | | | 0.1 | 25 | 43 | 63 | 84 | 99 | |
| | | | 0.2 | 33 | 49 | 64 | 76 | 102 | |
| | | | 0.5 | 53 | 70 | 129 | 150 | 163 | |
| Ex. 60 | Single | Hf[(C₂H₅)₂N]₄ | 0.001 | 20 | 27 | 59 | 90 | 98 | 97 to 98 |
| | solution | Si[(C₂H₅)(n-C₃H₇)N]₄ | 0.01 | 24 | 44 | 58 | 63 | 68 | |
| | | | 0.1 | 33 | 48 | 94 | 120 | 132 | |
| | | | 0.2 | 37 | 63 | 121 | 143 | 150 | |
| | | | 0.5 | 33 | 104 | 123 | 150 | 172 | |
| Ex. 61 | Single | Hf[(CH₃)(C₂H₅)N]₄ | 0.001 | 22 | 44 | 55 | 65 | 88 | 99 to 100 |
| | solution | Si[(C₂H₅)(n-C₃H₇)N]₄ | 0.01 | 26 | 43 | 55 | 72 | 92 | |
| | | | 0.1 | 37 | 54 | 69 | 113 | 120 | |
| | | | 0.2 | 43 | 74 | 92 | 138 | 160 | |
| | | | 0.5 | 63 | 117 | 124 | 182 | 190 | |
| Ex. 62 | Single | Hf(CH₃O)₄ | 0.001 | 17 | 29 | 43 | 60 | 70 | 95 to 96 |
| | solution | Si[(C₂H₅)(n-C₃H₇)N]₄ | 0.01 | 21 | 38 | 48 | 70 | 88 | |
| | | | 0.1 | 30 | 43 | 61 | 81 | 100 | |
| | | | 0.2 | 31 | 39 | 60 | 70 | 90 | |
| | | | 0.5 | 43 | 80 | 119 | 138 | 200 | |
| Ex. 63 | Single | Hf(C₂H₅O)₄ | 0.001 | 14 | 18 | 60 | 70 | 89 | 96 to 97 |
| | solution | Si[(C₂H₅)(n-C₃H₇)N]₄ | 0.01 | 20 | 40 | 55 | 60 | 69 | |
| | | | 0.1 | 30 | 42 | 80 | 98 | 130 | |
| | | | 0.2 | 30 | 44 | 88 | 120 | 132 | |
| | | | 0.5 | 39 | 65 | 88 | 110 | 132 | |

TABLE 44
Silicon substrate - HfSiO thin film

| Raw | Organic Hf compound | Mixing | Film thickness per film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 64 | Single | Hf(n-C₃H₇O)₄ | 0.001 | 23 | 40 | 51 | 61 | 88 | 92 to 94 |
| | solution | Si[(C₂H₅)(n-C₃H₇)N]₄ | 0.01 | 14 | 29 | 40 | 56 | 69 | |
| | | | 0.1 | 31 | 43 | 60 | 69 | 82 | |
| | | | 0.2 | 36 | 63 | 81 | 95 | 118 | |
| | | | 0.5 | 62 | 121 | 132 | 189 | 201 | |
| Ex. 65 | Single | Hf(n-C₄H₉O)₄ | 0.001 | 20 | 41 | 53 | 58 | 70 | 92 to 94 |
| | solution | Si[(C₂H₅)(n-C₃H₇)N]₄ | 0.01 | 20 | 40 | 49 | 56 | 90 | |
| | | | 0.1 | 30 | 49 | 63 | 91 | 100 | |
| | | | 0.2 | 32 | 56 | 60 | 90 | 112 | |
| | | | 0.5 | 37 | 89 | 100 | 118 | 139 | |
| Ex. 66 | Single | Hf[(CH₃)₂N]₄ | 0.001 | 21 | 31 | 41 | 60 | 70 | 99 to 100 |
| | solution | Si[(C₂H₅)(n-C₄H₉)N]₄ | 0.01 | 24 | 40 | 47 | 70 | 92 | |
| | | | 0.1 | 31 | 41 | 62 | 83 | 99 | |
| | | | 0.2 | 32 | 40 | 60 | 69 | 90 | |
| | | | 0.5 | 42 | 74 | 118 | 142 | 192 | |
| Ex. 67 | Single | Hf[(C₂H₅)₂N]₄ | 0.001 | 16 | 24 | 63 | 69 | 91 | 98 to 99 |
| | solution | Si[(C₂H₅)(n-C₄H₉)N]₄ | 0.01 | 22 | 44 | 57 | 65 | 74 | |
| | | | 0.1 | 30 | 42 | 78 | 101 | 126 | |
| | | | 0.2 | 31 | 42 | 80 | 101 | 122 | |
| | | | 0.5 | 39 | 60 | 91 | 100 | 123 | |
| Ex. 68 | Single | Hf[(CH₃)(C₂H₅)N]₄ | 0.001 | 25 | 39 | 51 | 63 | 91 | 92 to 94 |
| | solution | Si[(C₂H₅)(n-C₄H₉)N]₄ | 0.01 | 17 | 31 | 40 | 62 | 74 | |
| | | | 0.1 | 31 | 41 | 57 | 71 | 81 | |
| | | | 0.2 | 36 | 62 | 76 | 91 | 110 | |
| | | | 0.5 | 61 | 121 | 128 | 169 | 198 | |

TABLE 45
Silicon substrate - HfSiO thin film

| Raw | Organic Hf compound | Mixing | Film thickness er film | | | | | Peel test | | | | |
|---|---|---|---|---|---|---|---|---|---|---|---|---|
| material | & organic Si | ratio | formation time [nm] p | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 69 | Single | Hf(CH₃O)₄ | 0.001 | 18 | 32 | 43 | 62 | 73 | 94 to 100 |
| | solution | Si[(C₂H₅)(n-C₄H₉)N]₄ | 0.01 | 23 | 33 | 52 | 72 | 92 | |
| | | | 0.1 | 24 | 42 | 63 | 81 | 99 | |
| | | | 0.2 | 32 | 43 | 64 | 76 | 110 | |
| | | | 0.5 | 51 | 78 | 130 | 155 | 190 | |
| Ex. 70 | Single | Hf(C₂H₅O)₄ | 0.001 | 15 | 26 | 57 | 98 | 95 | 99 to 100 |
| | solution | Si[(C₂H₅)(n-C₄H₉)N]₄ | 0.01 | 23 | 42 | 57 | 63 | 65 | |
| | | | 0.1 | 32 | 47 | 93 | 121 | 142 | |
| | | | 0.2 | 36 | 62 | 120 | 145 | 150 | |
| | | | 0.5 | 33 | 102 | 124 | 152 | 200 | |
| Ex. 71 | Single | Hf(n-C₃H₇O)₄ | 0.001 | 22 | 43 | 53 | 62 | 85 | 98 to 99 |
| | solution | Si[(C₂H₅)(n-C₄H₉)N]₄ | 0.01 | 24 | 42 | 52 | 68 | 90 | |
| | | | 0.1 | 33 | 51 | 67 | 112 | 119 | |
| | | | 0.2 | 43 | 73 | 90 | 136 | 159 | |
| | | | 0.5 | 62 | 113 | 121 | 182 | 200 | |
| Ex. 72 | Single | Hf(n-C₄H₉O)₄ | 0.001 | 15 | 23 | 57 | 72 | 65 | 95 to 96 |
| | solution | Si[(C₂H₅)(n-C₄H₉)N]₄ | 0.01 | 25 | 42 | 47 | 75 | 93 | |
| | | | 0.1 | 30 | 53 | 63 | 66 | 95 | |
| | | | 0.2 | 33 | 63 | 66 | 80 | 100 | |
| | | | 0.5 | 43 | 99 | 110 | 121 | 154 | |
| Ex. 73 | Single | Hf[(CH₃)₂N]₄ | 0.001 | 25 | 39 | 53 | 63 | 93 | 99 to 100 |
| | solution | Si(CH₃O)₄ | 0.01 | 17 | 31 | 42 | 69 | 74 | |
| | | | 0.1 | 31 | 41 | 60 | 79 | 82 | |
| | | | 0.2 | 36 | 62 | 73 | 98 | 110 | |
| | | | 0.5 | 62 | 131 | 149 | 160 | 201 | |

TABLE 46
Silicon substrate - HfSiO thin film

| Raw | Organic Hf | Mixing | Film thickness [nm] per | | | | | Peel test [a piece/100 | | | | |
|---|---|---|---|---|---|---|---|---|---|---|---|---|
| marerial | compound & organic | ratio | film formation time | | | | | pieces] | | | | |
| solution | Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 74 | Single | Hf[(C₂H₅)₂N]₄ | 0.001 | 21 | 31 | 42 | 60 | 69 | 90 to 92 |
| | solution | Si(CH₃O)₄ | 0.01 | 24 | 40 | 48 | 70 | 92 | |
| | | | 0.1 | 31 | 41 | 62 | 82 | 98 | |
| | | | 0.2 | 32 | 40 | 60 | 69 | 90 | |
| | | | 0.5 | 41 | 74 | 120 | 141 | 190 | |
| Ex. 75 | Single | Hf[(CH₃)(C₂H₅)N]₄ | 0.001 | 16 | 24 | 65 | 70 | 91 | 93 to 94 |
| | solution | Si(CH₃O)₄ | 0.01 | 22 | 44 | 60 | 65 | 74 | |
| | | | 0.1 | 30 | 41 | 77 | 101 | 126 | |
| | | | 0.2 | 31 | 41 | 80 | 101 | 126 | |
| | | | 0.5 | 39 | 60 | 91 | 102 | 120 | |
| Ex. 76 | Single | Hf(CH₃O)₄ | 0.001 | 25 | 38 | 51 | 63 | 91 | 92 to 94 |
| | solution | Si(CH₃O)₄ | 0.01 | 17 | 31 | 40 | 62 | 74 | |
| | | | 0.1 | 31 | 42 | 57 | 71 | 81 | |
| | | | 0.2 | 36 | 62 | 76 | 91 | 109 | |
| | | | 0.5 | 61 | 120 | 129 | 179 | 201 | |
| Ex. 77 | Single | Hf(C₂H₅O)₄ | 0.001 | 21 | 44 | 51 | 61 | 74 | 93 to 94 |
| | solution | Si(CH₃O)₄ | 0.01 | 24 | 39 | 44 | 58 | 90 | |
| | | | 0.1 | 31 | 46 | 61 | 87 | 94 | |
| | | | 0.2 | 32 | 50 | 63 | 88 | 101 | |
| | | | 0.5 | 37 | 72 | 93 | 101 | 121 | |
| Ex. 78 | Single | Hf(n-C₃H₇O)₄ | 0.001 | 18 | 40 | 55 | 60 | 80 | 95 to 96 |
| | solution | Si(CH₃O)₄ | 0.01 | 25 | 39 | 49 | 59 | 91 | |
| | | | 0.1 | 32 | 47 | 61 | 88 | 94 | |
| | | | 0.2 | 37 | 52 | 64 | 89 | 100 | |
| | | | 0.5 | 30 | 70 | 98 | 100 | 120 | |

TABLE 47
Silicon substrate - HfSiO thin film

| Raw | Organic Hf compound | Mixing | Film thickness per film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 79 | Single | Hf(n-C₄H₉O)₄ | 0.001 | 22 | 30 | 42 | 63 | 72 | 96 to 97 |
| | solution | Si(CH₃O)₄ | 0.01 | 23 | 40 | 50 | 73 | 90 | |
| | | | 0.1 | 31 | 41 | 63 | 82 | 99 | |
| | | | 0.2 | 32 | 39 | 63 | 73 | 95 | |
| | | | 0.5 | 44 | 71 | 112 | 135 | 190 | |
| Ex. 80 | Single | Hf(CH₃O)₄ | 0.001 | 17 | 23 | 62 | 69 | 100 | 97 to 99 |
| | solution | Si(C₂H₅O)₄ | 0.01 | 23 | 44 | 63 | 63 | 73 | |
| | | | 0.1 | 29 | 50 | 82 | 94 | 124 | |
| | | | 0.2 | 31 | 46 | 90 | 100 | 110 | |
| | | | 0.5 | 36 | 60 | 90 | 101 | 113 | |
| Ex. 81 | Single | Hf(C₂H₅O)₄ | 0.001 | 22 | 37 | 60 | 62 | 89 | 99 to 100 |
| | solution | Si(C₂H₅O)₄ | 0.01 | 18 | 30 | 39 | 68 | 69 | |
| | | | 0.1 | 31 | 45 | 60 | 70 | 82 | |
| | | | 0.2 | 33 | 66 | 70 | 80 | 110 | |
| | | | 0.5 | 58 | 113 | 130 | 163 | 180 | |
| Ex. 82 | Single | Hf(n-C₃H₇O)₄ | 0.001 | 22 | 42 | 58 | 70 | 69 | 99 to 100 |
| | solution | Si(C₂H₅O)₄ | 0.01 | 22 | 42 | 48 | 62 | 89 | |
| | | | 0.1 | 43 | 45 | 64 | 90 | 98 | |
| | | | 0.2 | 37 | 52 | 70 | 92 | 100 | |
| | | | 0.5 | 41 | 70 | 93 | 100 | 105 | |
| Ex. 83 | Single | Hf(n-C₄H₉O)₄ | 0.001 | 23 | 32 | 45 | 64 | 69 | 97 to 98 |
| | solution | Si(C₂H₅O)₄ | 0.01 | 24 | 42 | 55 | 74 | 79 | |
| | | | 0.1 | 32 | 41 | 64 | 82 | 90 | |
| | | | 0.2 | 32 | 38 | 64 | 74 | 93 | |
| | | | 0.5 | 48 | 69 | 110 | 130 | 142 | |

TABLE 48
Silicon substrate - HfSiO thin film

| Raw | Organic Hf compound | Mixing | Film thickness per film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 84 | Single | Hf[(CH₃)₂N]₄ | 0.001 | 19 | 29 | 42 | 61 | 73 | 90 to 92 |
| | solution | Si(n-C₃H₇O)₄ | 0.01 | 20 | 39 | 48 | 71 | 89 | |
| | | | 0.1 | 29 | 41 | 61 | 81 | 97 | |
| | | | 0.2 | 31 | 39 | 61 | 71 | 93 | |
| | | | 0.5 | 41 | 71 | 110 | 131 | 169 | |
| Ex. 85 | Single | Hf[(C₂H₅)₂N]₄ | 0.001 | 16 | 22 | 61 | 69 | 99 | 92 to 93 |
| | solution | Si(n-C₃H₇O)₄ | 0.01 | 21 | 42 | 63 | 62 | 73 | |
| | | | 0.1 | 29 | 49 | 81 | 94 | 132 | |
| | | | 0.2 | 32 | 44 | 83 | 98 | 120 | |
| | | | 0.5 | 38 | 44 | 90 | 100 | 125 | |
| Ex. 86 | Single | Hf[(CH₃)(C₂H₅)N]₄ | 0.001 | 21 | 59 | 57 | 63 | 93 | 92 to 94 |
| | solution | Si(n-C₃H₇O)₄ | 0.01 | 17 | 30 | 38 | 68 | 90 | |
| | | | 0.1 | 30 | 44 | 61 | 68 | 82 | |
| | | | 0.2 | 31 | 62 | 73 | 82 | 110 | |
| | | | 0.5 | 57 | 111 | 131 | 162 | 200 | |
| Ex. 87 | Single | Hf(CH₃O)₄ | 0.001 | 21 | 41 | 60 | 69 | 79 | 93 to 94 |
| | solution | Si(n-C₃H₇O)₄ | 0.01 | 21 | 42 | 44 | 62 | 93 | |
| | | | 0.1 | 41 | 44 | 63 | 91 | 94 | |
| | | | 0.2 | 31 | 51 | 69 | 92 | 102 | |
| | | | 0.5 | 38 | 69 | 94 | 99 | 119 | |
| Ex. 88 | Single | Hf(n-C₂H₅O)₄ | 0.001 | 22 | 42 | 61 | 69 | 90 | 94 to 95 |
| | solution | Si(n-C₃H₇O)₄ | 0.01 | 23 | 43 | 45 | 64 | 95 | |
| | | | 0.1 | 43 | 45 | 64 | 93 | 99 | |
| | | | 0.2 | 32 | 50 | 70 | 94 | 120 | |
| | | | 0.5 | 39 | 69 | 94 | 100 | 125 | |

TABLE 49
Silicon substrate - HfSiO thin film

| Raw | Organic Hf | Mixing | Film thickness per film | | | | | Peel test | | | | |
|---|---|---|---|---|---|---|---|---|---|---|---|---|
| material | compound & organic | ratio | formation time [nm] | | | | | [a piece/100 pieces] | | | | |
| solution | Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 89 | Single | Hf(n-C₃H₇O)₄ | 0.001 | 20 | 29 | 41 | 61 | 72 | 90 to 92 |
| | solution | Si(n-C₃H₇O)₄ | 0.01 | 22 | 39 | 50 | 72 | 90 | |
| | | | 0.1 | 30 | 42 | 61 | 81 | 97 | |
| | | | 0.2 | 31 | 39 | 61 | 71 | 93 | |
| | | | 0.5 | 42 | 72 | 109 | 130 | 195 | |
| Ex. 90 | Single | Hf(n-C₄H₉O)₄ | 0.001 | 17 | 22 | 62 | 69 | 99 | 93 to 94 |
| | solution | Si(n-C₃H₇O)₄ | 0.01 | 22 | 42 | 63 | 62 | 72 | |
| | | | 0.1 | 29 | 50 | 82 | 93 | 131 | |
| | | | 0.2 | 32 | 44 | 83 | 99 | 125 | |
| | | | 0.5 | 39 | 60 | 89 | 102 | 123 | |
| Ex. 91 | Single | Hf[(CH₃)₂N]₄ | 0.001 | 21 | 38 | 57 | 63 | 92 | 94 to 95 |
| | solution | Si(n-C₄H₉O)₄ | 0.01 | 17 | 30 | 39 | 68 | 83 | |
| | | | 0.1 | 30 | 44 | 62 | 68 | 83 | |
| | | | 0.2 | 32 | 63 | 73 | 83 | 112 | |
| | | | 0.5 | 57 | 115 | 132 | 160 | 205 | |
| Ex. 92 | Single | Hf[(C₂H₅)₂N]₄ | 0.001 | 21 | 44 | 58 | 64 | 72 | 95 to 96 |
| | solution | Si(n-C₄H₉O)₄ | 0.01 | 21 | 45 | 44 | 63 | 91 | |
| | | | 0.1 | 41 | 47 | 63 | 92 | 92 | |
| | | | 0.2 | 37 | 51 | 69 | 91 | 92 | |
| | | | 0.5 | 38 | 69 | 92 | 99 | 101 | |
| Ex. 93 | Single | Hf[(CH₃)(C₂H₅)N]₄ | 0.001 | 22 | 45 | 59 | 65 | 75 | 96 to 98 |
| | solution | Si(n-C₄H₉O)₄ | 0.01 | 22 | 45 | 45 | 64 | 93 | |
| | | | 0.1 | 43 | 47 | 65 | 93 | 95 | |
| | | | 0.2 | 38 | 52 | 70 | 95 | 99 | |
| | | | 0.5 | 39 | 70 | 93 | 100 | 109 | |

TABLE 50
Silicon substrate - HfSiO thin film

| | Organic Hf | | | | | | | | | | | |
|---|---|---|---|---|---|---|---|---|---|---|---|---|
| Raw | compound & | Mixing | Film thickness per film | | | | | Peel test | | | | |
| material | organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. | Single | Hf(CH₃O)₄ | 0.001 | 24 | 31 | 41 | 63 | 72 | 97 to 98 |
| 94 | solution | Si(n-C₄H₉O)₄ | 0.01 | 25 | 42 | 51 | 74 | 91 | |
| | | | 0.1 | 33 | 43 | 61 | 89 | 101 | |
| | | | 0.2 | 34 | 39 | 64 | 77 | 95 | |
| | | | 0.5 | 47 | 77 | 113 | 132 | 190 | |
| Ex. | Single | Hf(C₂H₅O)₄ | 0.001 | 19 | 24 | 66 | 71 | 100 | 98 to 99 |
| 95 | solution | Si(n-C₄H₉O)₄ | 0.01 | 24 | 45 | 64 | 63 | 72 | |
| | | | 0.1 | 31 | 46 | 82 | 95 | 120 | |
| | | | 0.2 | 33 | 46 | 90 | 101 | 110 | |
| | | | 0.5 | 37 | 62 | 90 | 111 | 114 | |
| Ex. | Single | Hf(n-C₃H₇O)₄ | 0.001 | 23 | 37 | 61 | 63 | 90 | 99 to 100 |
| 96 | solution | Si(n-C₄H₉O)₄ | 0.01 | 20 | 31 | 41 | 69 | 67 | |
| | | | 0.1 | 31 | 45 | 61 | 72 | 89 | |
| | | | 0.2 | 34 | 62 | 72 | 82 | 110 | |
| | | | 0.5 | 57 | 112 | 130 | 164 | 200 | |
| Ex. | Single | Hf(n-C₄H₉O)₄ | 0.001 | 23 | 43 | 61 | 71 | 71 | 96 to 97 |
| 97 | solution | Si(n-C₄H₉O)₄ | 0.01 | 24 | 41 | 46 | 63 | 92 | |
| | | | 0.1 | 44 | 45 | 66 | 92 | 90 | |
| | | | 0.2 | 39 | 55 | 71 | 94 | 99 | |
| | | | 0.5 | 44 | 71 | 96 | 99 | 111 | |

As clearly shown in the tables 34 to 50, the films formed by using the single raw material solution according to Examples A14 to A97 had a significantly high film forming rate in comparison with Comparative Example 1, and stable film formation was obtained.

Also, in the peel test, most of grids were remained on substrates in films formed by using the raw material solution according to Examples A14 to A97 and thus high adhesivity results were obtained.

### Examples A98 to A104

Five raw material solutions for MOCVD method which differ in mixing ratio were respectively prepared in the same manner as in Example A1 so as to grow Si films on substrates and form Hf-Si—O thin films on surfaces of those Si films in the same manner as in Example A9, except that Si[(CH₃)₂N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O) 4 and Hf(n-C₄H₉O)₄ were used as the organic Hf compound.

### Examples A105 to A110

Five raw material solutions for MOCVD method which differ in mixing ratio were respectively prepared in the same manner as in Example A1 so as to grow Si films on substrates and form Hf-Si—O thin films on surfaces of those Si films in the same manner as in Example A9, except that Hf[(CH₃)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A111 to A117

Five raw material solutions for MOCVD method which differ in mixing ratio were respectively prepared in the same manner as in Example A1 so as to grow Si films on substrates and form Hf-Si—O thin films on surfaces of those Si films in the same manner as in Example A9, except that Si[(n-C₃H₇)₂N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A118 to A124

Five raw material solutions for MOCVD method which differ in mixing ratio were respectively prepared in the same manner as in Example A1 so as to grow Si films on substrates and form Hf-Si—O thin films on surfaces of those Si films in the same manner as in Example A9, except that Si[(n-C₄H₉)₂N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O) 4 and Hf(n-C₄H₉O)₄ were used as the organic Hf compound.

### Examples A125 to A131

Five raw material solutions for MOCVD method which differ in mixing ratio were respectively prepared in the same manner as in Example A1 so as to grow Si films on substrates and form Hf-Si—O thin films on surfaces of those Si films in the same manner as in Example A9, except that Si[(CH₃)(C₂H₅)N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A132 to A138

Five raw material solutions for MOCVD method which differ in mixing ratio were respectively prepared in the same manner as in Example A1 so as to grow Si films on substrates and form Hf-Si—O thin films on surfaces of those Si films in the same manner as in Example A9, except that Si[(CH₃)(n-C₃H₇)N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A139 to A145

Five raw material solutions for MOCVD method which differ in mixing ratio were respectively prepared in the same manner as in Example A1 so as to grow Si films on substrates and form Hf-Si—O thin films on surfaces of those Si films in the same manner as in Example A9, except that Si[(CH₃)(n-C₄H₉)N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A146 to A152

Five raw material solutions for MOCVD method which differ in mixing ratio were respectively prepared in the same manner as in Example A1 so as to grow Si films on substrates and form Hf-Si—O thin films on surfaces of those Si films in the same manner as in Example A9, except that Si[(C₂H₅)(n-C₃H₇)N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A153 to A159

Five raw material solutions for MOCVD method which differ in mixing ratio were respectively prepared in the same manner as in Example A1 so as to grow Si films on substrates and form Hf-Si—O thin films on surfaces of those Si films in the same manner as in Example A9, except that Si[(C₂H₅)(n-C₄H₉)N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A160 to A166

Five raw material solutions for MOCVD method which differ in mixing ratio were respectively prepared in the same manner as in Example 1 so as to grow Si films on substrates and form Hf-Si—O thin films on surfaces of those Si films in the same manner as in Example 9, except that Si(CH₃O)₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O) 4 and Hf(n-C₄H₉O)₄ were used as the organic Hf compound.

### Examples A167 to A173

Five raw material solutions for MOCVD method which differ in mixing ratio were respectively prepared in the same manner as in Example A1 so as to grow Si films on substrates and form Hf-Si—O thin films on surfaces of those Si films in the same manner as in Example A9, except that Si(C₂H₅O)₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O) 4 and Hf(n-C₄H₉O)₄ were used as the organic Hf compound.

### Examples A174 to A180

Five raw material solutions for MOCVD method which differ in mixing ratio were respectively prepared in the same manner as in Example A1 so as to grow Si films on substrates and form Hf-Si—O thin films on surfaces of those Si films in the same manner as in Example A9, except that Si (n-C₃H₇O)₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O) 4 and Hf(n-C₄H₉O)₄ were used as the organic Hf compound.

### Examples A181 to A187

Five raw material solutions for MOCVD method which differ in mixing ratio were respectively prepared in the same manner as in Example A1 so as to grow Si films on substrates and form Hf-Si—O thin films on surfaces of those Si films in the same manner as in Example A9, except that Si (n-C₄H₉O) 4 was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

<Comparative Test A5>

For each obtained Hf-Si—O thin film according to Examples A98 to A187, a film thickness test, and a peel test to examine adhesivity, per film formation time of the obtained Hf-Si—O thin film were carried out in the same manner as in the above-mentioned Comparative Test A1.

<Evaluation>

Obtained results of the film thickness and the peel test per film formation time are respectively shown in tables 51 to 68. The peel test shows the number of remaining substrates per 100 pieces of cut grid. In the tables 51 to 68, letter ‘A’s numbering Examples are omitted.

TABLE 51
Silicon substrate-Si film-HfSiO thin film

| Raw | Organic Hf compound | Mixing | Film thickness per film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 98 | Single | Hf[(CH₃)₂N]₄ | 0.001 | 21 | 31 | 41 | 61 | 73 | 99 to 100 |
| | solution | Si[(CH₃)₂N]₄ | 0.01 | 23 | 38 | 47 | 73 | 88 | |
| | | | 0.1 | 31 | 42 | 57 | 79 | 97 | |
| | | | 0.2 | 30 | 41 | 59 | 71 | 92 | |
| | | | 0.5 | 39 | 68 | 111 | 123 | 181 | |
| Ex. 99 | Single | Hf[(C₂H₅)₂N]₄ | 0.001 | 17 | 21 | 63 | 70 | 99 | 99 to 100 |
| | solution | Si[(CH₃)₂N]₄ | 0.01 | 23 | 38 | 62 | 63 | 68 | |
| | | | 0.1 | 31 | 49 | 80 | 92 | 130 | |
| | | | 0.2 | 33 | 41 | 81 | 93 | 111 | |
| | | | 0.5 | 42 | 57 | 87 | 99 | 121 | |
| Ex. 100 | Single | Hf[(CH₃)(C₂H₅)N]₄ | 0.001 | 25 | 37 | 57 | 61 | 93 | 99 to 100 |
| | solution | Si[(CH₃)₂N]₄ | 0.01 | 19 | 31 | 42 | 67 | 68 | |
| | | | 0.1 | 31 | 41 | 58 | 61 | 81 | |
| | | | 0.2 | 38 | 62 | 72 | 81 | 110 | |
| | | | 0.5 | 61 | 110 | 121 | 162 | 201 | |
| Ex. 101 | Single | Hf(CH₃O)₄ | 0.001 | 20 | 30 | 40 | 59 | 69 | 99 to 100 |
| | solution | Si[(CH₃)₂N]₄ | 0.01 | 23 | 39 | 47 | 69 | 90 | |
| | | | 0.1 | 30 | 40 | 61 | 82 | 98 | |
| | | | 0.2 | 31 | 39 | 57 | 68 | 88 | |
| | | | 0.5 | 40 | 73 | 120 | 140 | 190 | |
| Ex. 102 | Single | Hf(C₂H₅O)₄ | 0.001 | 15 | 23 | 62 | 68 | 90 | 99 to 100 |
| | solution | Si[(CH₃)₂N]₄ | 0.01 | 21 | 43 | 56 | 64 | 73 | |
| | | | 0.1 | 29 | 40 | 76 | 100 | 125 | |
| | | | 0.2 | 30 | 40 | 79 | 100 | 122 | |
| | | | 0.5 | 38 | 59 | 90 | 101 | 121 | |

TABLE 52
Silicon substrate-Si film-HfSiO thin film

| Raw | Organic Hf | Mixing | Film thickness per film | | | | | Peel test | | | | |
|---|---|---|---|---|---|---|---|---|---|---|---|---|
| material | compound & organic | ratio | formation time [nm] | | | | | [a piece/100 pieces] | | | | |
| solution | Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 103 | Single | Hf(n-C₃H₇O)₄ | 0.001 | 24 | 38 | 50 | 62 | 90 | 99 to 100 |
| | solution | Si[(CH₃)₂N]₄ | 0.01 | 16 | 30 | 39 | 61 | 73 | |
| | | | 0.1 | 30 | 40 | 56 | 70 | 80 | |
| | | | 0.2 | 35 | 61 | 75 | 90 | 110 | |
| | | | 0.5 | 60 | 120 | 127 | 170 | 200 | |
| Ex. 104 | Single | Hf(n-C₄H₉O)₄ | 0.001 | 20 | 43 | 50 | 60 | 72 | 98 to 99 |
| | solution | Si[(CH₃)₂N]₄ | 0.01 | 23 | 38 | 42 | 58 | 89 | |
| | | | 0.1 | 30 | 45 | 60 | 88 | 93 | |
| | | | 0.2 | 31 | 49 | 62 | 88 | 100 | |
| | | | 0.5 | 36 | 70 | 92 | 100 | 120 | |
| Ex. 105 | Single | Hf[(CH₃)₂N]₄ | 0.001 | 26 | 39 | 62 | 69 | 79 | 98 to 99 |
| | solution | Si[(C₂H₅)₂N]₄ | 0.01 | 20 | 33 | 44 | 69 | 78 | |
| | | | 0.1 | 32 | 42 | 60 | 82 | 99 | |
| | | | 0.2 | 38 | 63 | 73 | 88 | 99 | |
| | | | 0.5 | 62 | 119 | 129 | 143 | 169 | |
| Ex. 106 | Single | Hf[(CH₃)(C₂H₅)N]₄ | 0.001 | 21 | 33 | 42 | 63 | 73 | 98 to 99 |
| | solution | Si[(C₂H₅)₂N]₄ | 0.1 | 23 | 40 | 50 | 74 | 80 | |
| | | | 0.1 | 33 | 49 | 56 | 78 | 98 | |
| | | | 0.2 | 39 | 43 | 59 | 79 | 94 | |
| | | | 0.5 | 40 | 70 | 100 | 122 | 162 | |
| Ex. 107 | Single | Hf(CH₃O)₄ | 0.001 | 22 | 29 | 41 | 62 | 70 | 97 to 99 |
| | solution | Si[(C₂H₅)₂N]₄ | 0.01 | 23 | 39 | 49 | 72 | 89 | |
| | | | 0.1 | 31 | 42 | 62 | 81 | 99 | |
| | | | 0.2 | 32 | 38 | 62 | 72 | 93 | |
| | | | 0.5 | 45 | 70 | 110 | 134 | 190 | |

TABLE 53
Silicon substrate-Si film-HfSiO thin film

| Raw | Organic Hf compound | Mixing | Film thickness per film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 108 | Single | Hf(C₂H₅O)₄ | 0.001 | 16 | 22 | 61 | 69 | 99 | 97 to 99 |
| | solution | Si[(C₂H₅)₂N]₄ | 0.01 | 22 | 43 | 62 | 61 | 70 | |
| | | | 0.1 | 29 | 49 | 81 | 93 | 123 | |
| | | | 0.2 | 30 | 45 | 88 | 99 | 110 | |
| | | | 0.5 | 35 | 59 | 89 | 100 | 112 | |
| Ex. 109 | Single | Hf(n-C₃H₇O)₄ | 0.001 | 21 | 36 | 56 | 60 | 88 | 89 to 100 |
| | solution | Si[(C₂H₅)₂N]₄ | 0.01 | 17 | 29 | 39 | 67 | 65 | |
| | | | 0.1 | 30 | 44 | 56 | 69 | 80 | |
| | | | 0.2 | 32 | 65 | 72 | 80 | 110 | |
| | | | 0.5 | 57 | 112 | 132 | 162 | 205 | |
| Ex. 110 | Single | Hf(n-C₄H₉O)₄ | 0.001 | 21 | 41 | 57 | 69 | 69 | 99 to 100 |
| | solution | Si[(C₂H₅)₂N]₄ | 0.01 | 21 | 41 | 44 | 60 | 88 | |
| | | | 0.1 | 42 | 44 | 63 | 89 | 87 | |
| | | | 0.2 | 37 | 51 | 69 | 92 | 92 | |
| | | | 0.5 | 40 | 69 | 94 | 99 | 100 | |
| Ex. 111 | Single | Hf[(CH₃)₂N]₄ | 0.001 | 23 | 40 | 59 | 65 | 95 | 98 to 99 |
| | solution | Si[(n-C₃H₇)₂N]₄ | 0.01 | 20 | 33 | 44 | 70 | 73 | |
| | | | 0.1 | 33 | 47 | 65 | 72 | 85 | |
| | | | 0.2 | 33 | 65 | 73 | 85 | 112 | |
| | | | 0.5 | 60 | 111 | 132 | 165 | 210 | |
| Ex. 112 | Single | Hf[(C₂H₅)₂N]₄ | 0.001 | 25 | 43 | 60 | 67 | 79 | 99 to 100 |
| | solution | Si[(n-C₃H₇)₂N]₄ | 0.01 | 25 | 45 | 49 | 68 | 92 | |
| | | | 0.1 | 45 | 47 | 69 | 98 | 110 | |
| | | | 0.2 | 33 | 57 | 73 | 97 | 120 | |
| | | | 0.5 | 40 | 72 | 92 | 100 | 123 | |

TABLE 54
Silicon substrate-Si film-HfSiO thin film

| Raw | Organic Hf compound | Mixing | Film thickness per film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 113 | Single | Hf[(CH₃)(C₂H₅)N]₄ | 0.001 | 20 | 30 | 43 | 63 | 73 | 96 to 97 |
| | solution | Si[(n-C₃H₇)₂N]₄ | 0.01 | 23 | 39 | 50 | 75 | 90 | |
| | | | 0.1 | 32 | 43 | 65 | 82 | 100 | |
| | | | 0.2 | 33 | 40 | 64 | 76 | 95 | |
| | | | 0.5 | 42 | 79 | 110 | 140 | 182 | |
| Ex. 114 | Single | Hf(CH₃O)₄ | 0.001 | 18 | 27 | 40 | 60 | 70 | 90 to 92 |
| | solution | Si[(n-C₃H₇)₂N]₄ | 0.01 | 20 | 38 | 47 | 70 | 88 | |
| | | | 0.1 | 29 | 40 | 60 | 80 | 97 | |
| | | | 0.2 | 30 | 38 | 60 | 70 | 90 | |
| | | | 0.5 | 40 | 70 | 110 | 132 | 192 | |
| Ex. 115 | Single | Hf(C₂H₅O)₄ | 0.001 | 15 | 21 | 60 | 68 | 98 | 92 to 94 |
| | solution | Si[(n-C₃H₇)₂N]₄ | 0.01 | 20 | 40 | 62 | 60 | 70 | |
| | | | 0.1 | 28 | 49 | 80 | 92 | 130 | |
| | | | 0.2 | 31 | 43 | 82 | 98 | 120 | |
| | | | 0.5 | 37 | 58 | 88 | 101 | 121 | |
| Ex. 116 | Single | Hf(n-C₃H₇O)₄ | 0.001 | 20 | 37 | 57 | 62 | 90 | 94 to 95 |
| | solution | Si[(n-C₃H₇)₂N]₄ | 0.01 | 16 | 29 | 38 | 67 | 70 | |
| | | | 0.1 | 29 | 43 | 60 | 67 | 82 | |
| | | | 0.2 | 30 | 61 | 72 | 82 | 110 | |
| | | | 0.5 | 56 | 110 | 130 | 162 | 201 | |
| Ex. 117 | Single | Hf(n-C₄H₉O)₄ | 0.001 | 20 | 40 | 57 | 63 | 70 | 95 to 96 |
| | solution | Si[(n-C₃H₇)₂N]₄ | 0.01 | 20 | 40 | 43 | 60 | 90 | |
| | | | 0.1 | 40 | 43 | 62 | 90 | 90 | |
| | | | 0.2 | 36 | 50 | 68 | 90 | 101 | |
| | | | 0.5 | 37 | 68 | 93 | 98 | 110 | |

TABLE 55
Silicon substrate-Si film-HfSiO thin film

| Raw | Organic Hf compound | Mixing | Film thickness er film | | | | | Peel test | | | | |
|---|---|---|---|---|---|---|---|---|---|---|---|---|
| material | & organic Si | ratio | formation time [nm] p | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 118 | Single | Hf[(CH₃)₂N]₄ | 0.001 | 22 | 29 | 44 | 62 | 75 | 95 to 98 |
| | solution | Si[(n-C₄H₉)₂N]₄ | 0.01 | 25 | 39 | 51 | 74 | 92 | |
| | | | 0.1 | 33 | 43 | 63 | 84 | 100 | |
| | | | 0.2 | 32 | 40 | 64 | 74 | 98 | |
| | | | 0.5 | 42 | 70 | 115 | 142 | 192 | |
| Ex. 119 | Single | Hf[(C₂H₅)₂N]₄ | 0.001 | 18 | 23 | 66 | 73 | 98 | 96 to 97 |
| | solution | Si[(n-C₄H₉)₂N]₄ | 0.01 | 23 | 43 | 64 | 65 | 72 | |
| | | | 0.1 | 30 | 53 | 90 | 96 | 132 | |
| | | | 0.2 | 32 | 47 | 89 | 100 | 125 | |
| | | | 0.5 | 39 | 62 | 89 | 105 | 123 | |
| Ex. 120 | Single | Hf[(CH₃)(C₂H₅)N]₄ | 0.001 | 22 | 40 | 60 | 65 | 93 | 96 to 97 |
| | solution | Si[(n-C₄H₉)₂N]₄ | 0.01 | 18 | 33 | 42 | 70 | 74 | |
| | | | 0.1 | 32 | 42 | 63 | 70 | 85 | |
| | | | 0.2 | 32 | 65 | 73 | 85 | 112 | |
| | | | 0.5 | 60 | 110 | 132 | 165 | 205 | |
| Ex. 121 | Single | Hf(CH₃O)₄ | 0.001 | 23 | 30 | 40 | 63 | 71 | 97 to 99 |
| | solution | Si[(n-C₄H₉)₂N]₄ | 0.01 | 24 | 40 | 50 | 73 | 90 | |
| | | | 0.1 | 32 | 42 | 60 | 88 | 100 | |
| | | | 0.2 | 33 | 38 | 63 | 76 | 94 | |
| | | | 0.5 | 46 | 76 | 112 | 132 | 192 | |
| Ex. 122 | Single | Hf(C₂H₅O)₄ | 0.001 | 18 | 23 | 65 | 70 | 99 | 99 to 100 |
| | solution | Si[(n-C₄H₉)₂N]₄ | 0.01 | 23 | 44 | 63 | 62 | 72 | |
| | | | 0.1 | 30 | 45 | 81 | 94 | 122 | |
| | | | 0.2 | 32 | 45 | 89 | 100 | 111 | |
| | | | 0.5 | 36 | 66 | 89 | 110 | 113 | |

TABLE 56
Silicon substrate-Si film-HfSiO thin film

| Raw | Organic Hf | Mixing | Film thickness [nm] per | | | | | Peel test [a piece/100 | | | | |
|---|---|---|---|---|---|---|---|---|---|---|---|---|
| material | compound & organic | ratio | film formation time | | | | | pieces] | | | | |
| solution | Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 123 | Single | Hf(n-C₃H₇O)₄ | 0.001 | 22 | 35 | 60 | 62 | 89 | 98 to 99 |
| | solution | Si[(n-C₄H₉)₂N]₄ | 0.01 | 19 | 30 | 40 | 67 | 65 | |
| | | | 0.1 | 31 | 44 | 60 | 70 | 81 | |
| | | | 0.2 | 33 | 60 | 72 | 81 | 111 | |
| | | | 0.5 | 56 | 110 | 130 | 163 | 206 | |
| Ex. 124 | Single | Hf(n-C₄H₉O)₄ | 0.001 | 22 | 42 | 60 | 70 | 70 | 90 to 90 |
| | solution | Si[(n-C₄H₉)₂N]₄ | 0.01 | 23 | 40 | 45 | 61 | 90 | |
| | | | 0.1 | 43 | 43 | 65 | 90 | 89 | |
| | | | 0.2 | 38 | 53 | 70 | 93 | 93 | |
| | | | 0.5 | 42 | 70 | 95 | 99 | 101 | |
| Ex. 125 | Single | Hf[(CH₃)₂N]₄ | 0.001 | 21 | 32 | 36 | 62 | 71 | 96 to 97 |
| | solution | Si[(CH₃)(C₂H₅)N]₄ | 0.01 | 22 | 38 | 49 | 71 | 81 | |
| | | | 0.1 | 34 | 41 | 51 | 71 | 91 | |
| | | | 0.2 | 33 | 41 | 61 | 73 | 93 | |
| | | | 0.5 | 42 | 66 | 110 | 115 | 182 | |
| Ex. 126 | Single | Hf[(C₂H₅)₂N]₄ | 0.001 | 19 | 21 | 61 | 61 | 93 | 97 to 99 |
| | solution | Si[(CH₃)(C₂H₅)N]₄ | 0.01 | 21 | 37 | 69 | 57 | 67 | |
| | | | 0.1 | 42 | 45 | 81 | 87 | 120 | |
| | | | 0.2 | 31 | 41 | 71 | 91 | 109 | |
| | | | 0.5 | 34 | 50 | 83 | 91 | 108 | |
| Ex. 127 | Single | Hf[(CH₃)(C₂H₅)N]₄ | 0.001 | 26 | 36 | 51 | 57 | 92 | 96 to 98 |
| | solution | Si[(CH₃)(C₂H₅)N]₄ | 0.01 | 21 | 42 | 36 | 61 | 66 | |
| | | | 0.1 | 26 | 37 | 51 | 68 | 87 | |
| | | | 0.2 | 41 | 61 | 71 | 81 | 100 | |
| | | | 0.5 | 54 | 81 | 121 | 169 | 180 | |

TABLE 57
Silicon substrate-Si film-HfSiO thin film

| Raw | Organic Hf compound | Mixing | Film thickness per film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 128 | Single | Hf(CH₃O)₄ | 0.001 | 20 | 30 | 40 | 60 | 72 | 99 to 100 |
| | solution | Si[(CH₃)(C₂H₅)N]₄ | 0.01 | 22 | 37 | 46 | 72 | 82 | |
| | | | 0.1 | 30 | 41 | 56 | 78 | 96 | |
| | | | 0.2 | 29 | 40 | 57 | 70 | 90 | |
| | | | 0.5 | 38 | 67 | 110 | 122 | 180 | |
| Ex. 129 | Single | Hf(C₂H₅O)₄ | 0.001 | 16 | 20 | 62 | 69 | 97 | 99 to 100 |
| | solution | Si[(CH₃)(C₂H₅)N]₄ | 0.01 | 22 | 37 | 60 | 62 | 67 | |
| | | | 0.1 | 30 | 48 | 79 | 90 | 129 | |
| | | | 0.2 | 32 | 40 | 80 | 92 | 110 | |
| | | | 0.5 | 40 | 56 | 86 | 98 | 120 | |
| Ex. 130 | Single | Hf(n-C₃H₇O)₄ | 0.001 | 24 | 36 | 56 | 60 | 92 | 96 to 98 |
| | solution | Si[(CH₃)(C₂H₅)N]₄ | 0.01 | 18 | 30 | 40 | 67 | 67 | |
| | | | 0.1 | 30 | 40 | 57 | 60 | 80 | |
| | | | 0.2 | 37 | 61 | 70 | 80 | 110 | |
| | | | 0.5 | 60 | 109 | 120 | 160 | 200 | |
| Ex. 131 | Single | Hf(n-C₄H₉O)₄ | 0.001 | 22 | 38 | 57 | 60 | 68 | 97 to 99 |
| | solution | Si[(CH₃)(C₂H₅)N]₄ | 0.01 | 21 | 37 | 42 | 59 | 92 | |
| | | | 0.1 | 38 | 40 | 60 | 88 | 88 | |
| | | | 0.2 | 32 | 48 | 67 | 88 | 92 | |
| | | | 0.5 | 36 | 70 | 90 | 90 | 98 | |
| Ex. 132 | Single | Hf[(CH₃)₂N]₄ | 0.001 | 22 | 41 | 57 | 61 | 69 | 99 to 100 |
| | solution | Si[(CH₃)(n-C₃H₇)N]₄ | 0.01 | 23 | 31 | 42 | 60 | 90 | |
| | | | 0.1 | 41 | 36 | 60 | 81 | 89 | |
| | | | 0.2 | 31 | 51 | 61 | 88 | 99 | |
| | | | 0.5 | 41 | 66 | 90 | 91 | 98 | |

TABLE 58
Silicon substrate-Si film-HfSiO thin film

| Raw | Organic Hf compound | Mixing | Film thickness per film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 133 | Single | Hf[(C₂H₅)₂N]₄ | 0.001 | 19 | 30 | 44 | 61 | 71 | 98 to 99 |
| | solution | Si[(CH₃)(n-C₃H₇)N]₄ | 0.01 | 23 | 40 | 51 | 71 | 91 | |
| | | | 0.1 | 32 | 42 | 64 | 81 | 97 | |
| | | | 0.2 | 33 | 41 | 65 | 72 | 94 | |
| | | | 0.5 | 42 | 73 | 112 | 141 | 193 | |
| Ex. 134 | Single | Hf[(CH₃)(C₂H₅)N]₄ | 0.001 | 18 | 24 | 61 | 74 | 99 | 99 to 100 |
| | solution | Si[(CH₃)(n-C₃H₇)N]₄ | 0.01 | 24 | 43 | 63 | 64 | 73 | |
| | | | 0.1 | 31 | 52 | 81 | 95 | 132 | |
| | | | 0.2 | 32 | 46 | 83 | 100 | 123 | |
| | | | 0.5 | 40 | 61 | 92 | 101 | 126 | |
| Ex. 135 | Single | Hf(CH₃O)₄ | 0.001 | 19 | 28 | 42 | 62 | 72 | 99 to 100 |
| | solution | Si[(CH₃)(n-C₃H₇)N]₄ | 0.01 | 22 | 38 | 49 | 72 | 89 | |
| | | | 0.1 | 30 | 41 | 62 | 82 | 97 | |
| | | | 0.2 | 31 | 39 | 62 | 72 | 92 | |
| | | | 0.5 | 40 | 72 | 112 | 141 | 193 | |
| Ex. 136 | Single | Hf(C₂H₅O)₄ | 0.001 | 16 | 22 | 62 | 70 | 98 | 99 to 100 |
| | solution | Si[(CH₃)(n-C₃H₇)N]₄ | 0.01 | 22 | 41 | 63 | 62 | 70 | |
| | | | 0.1 | 29 | 50 | 87 | 93 | 130 | |
| | | | 0.2 | 30 | 44 | 83 | 99 | 121 | |
| | | | 0.5 | 38 | 59 | 88 | 102 | 121 | |
| Ex. 137 | Single | Hf(n-C₃H₇O)₄ | 0.001 | 21 | 38 | 57 | 63 | 92 | 97 to 98 |
| | solution | Si[(CH₃)(n-C₃H₇)N]₄ | 0.01 | 17 | 30 | 40 | 67 | 71 | |
| | | | 0.1 | 30 | 44 | 62 | 68 | 82 | |
| | | | 0.2 | 30 | 62 | 72 | 83 | 110 | |
| | | | 0.5 | 57 | 109 | 131 | 163 | 200 | |

TABLE 59
Silicon substrate-Si film-HfSiO thin film

| Raw | Organic Hf | Mixing | Film thickness per film | | | | | Peel test | | | | |
|---|---|---|---|---|---|---|---|---|---|---|---|---|
| material | compound & organic | ratio | formation time [nm] | | | | | [a piece/100 pieces] | | | | |
| solution | Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 138 | Single | Hf(n-C₄H₉O)₄ | 0.001 | 22 | 41 | 57 | 64 | 72 | 96 to 98 |
| | solution | Si[(CH₃)(n-C₃H₇)N]₄ | 0.01 | 22 | 42 | 44 | 62 | 92 | |
| | | | 0.1 | 42 | 44 | 62 | 92 | 92 | |
| | | | 0.2 | 31 | 51 | 69 | 92 | 101 | |
| | | | 0.5 | 37 | 69 | 94 | 99 | 101 | |
| Ex. 139 | Single | Hf[(CH₃)₂N]₄ | 0.001 | 23 | 40 | 62 | 80 | 99 | 98 to 99 |
| | solution | Si[(CH₃)(n-C₄H₉)N]₄ | 0.01 | 19 | 32 | 65 | 82 | 98 | |
| | | | 0.1 | 32 | 46 | 80 | 90 | 101 | |
| | | | 0.2 | 33 | 64 | 83 | 93 | 120 | |
| | | | 0.5 | 60 | 115 | 163 | 173 | 182 | |
| Ex. 140 | Single | Hf[(C₂H₅)₂N]₄ | 0.001 | 24 | 43 | 58 | 82 | 99 | 97 to 98 |
| | solution | Si[(CH₃)(n-C₄H₉)N]₄ | 0.01 | 23 | 47 | 63 | 80 | 98 | |
| | | | 0.1 | 42 | 48 | 82 | 93 | 105 | |
| | | | 0.2 | 33 | 49 | 69 | 88 | 99 | |
| | | | 0.5 | 38 | 69 | 79 | 89 | 98 | |
| Ex. 141 | Single | Hf[(CH₃)(C₂H₅)N]₄ | 0.001 | 19 | 44 | 59 | 73 | 89 | 98 to 99 |
| | solution | Si[(CH₃)(n-C₄H₉)N]₄ | 0.01 | 23 | 49 | 63 | 79 | 90 | |
| | | | 0.1 | 33 | 39 | 70 | 82 | 93 | |
| | | | 0.2 | 32 | 44 | 72 | 85 | 95 | |
| | | | 0.5 | 43 | 63 | 78 | 90 | 93 | |
| Ex. 142 | Single | Hf(CH₃O)₄ | 0.001 | 20 | 31 | 35 | 60 | 70 | 99 to 100 |
| | solution | Si[(CH₃)(n-C₄H₉)N]₄ | 0.01 | 21 | 37 | 48 | 70 | 80 | |
| | | | 0.1 | 33 | 40 | 50 | 70 | 90 | |
| | | | 0.2 | 32 | 40 | 60 | 72 | 92 | |
| | | | 0.5 | 40 | 65 | 109 | 110 | 190 | |

TABLE 60
Silicon substrate-Si film-HfSiO thin film

| Raw | Organic Hf compound | Mixing | Film thickness per film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 143 | Single | Hf(C₂H₅O)₄ | 0.001 | 18 | 20 | 60 | 60 | 90 | 99 to 100 |
| | solution | Si[(CH₃)(n-C₄H₉)N]₄ | 0.01 | 20 | 36 | 68 | 56 | 65 | |
| | | | 0.1 | 41 | 40 | 80 | 86 | 120 | |
| | | | 0.2 | 30 | 40 | 70 | 90 | 109 | |
| | | | 0.5 | 33 | 49 | 81 | 90 | 109 | |
| Ex. 144 | Single | Hf(n-C₃H₇O)₄ | 0.001 | 25 | 37 | 50 | 56 | 90 | 99 to 100 |
| | solution | Si[(CH₃)(n-C₄H₉)N]₄ | 0.01 | 20 | 41 | 35 | 60 | 65 | |
| | | | 0.1 | 25 | 35 | 50 | 67 | 81 | |
| | | | 0.2 | 40 | 60 | 70 | 80 | 109 | |
| | | | 0.5 | 53 | 80 | 120 | 180 | 190 | |
| Ex. 145 | Single | Hf(n-C₄H₉O)₄ | 0.001 | 21 | 40 | 57 | 60 | 62 | 98 to 99 |
| | solution | Si[(CH₃)(n-C₄H₉)N]₄ | 0.01 | 22 | 30 | 40 | 59 | 92 | |
| | | | 0.1 | 40 | 35 | 58 | 80 | 88 | |
| | | | 0.2 | 30 | 50 | 60 | 87 | 90 | |
| | | | 0.5 | 40 | 65 | 89 | 90 | 98 | |
| Ex. 146 | Single | Hf[(CH₃)₂N]₄ | 0.001 | 20 | 31 | 33 | 62 | 66 | 99 to 100 |
| | solution | Si[(C₂H₅)(n-C₃H₇)N]₄ | 0.01 | 21 | 38 | 47 | 71 | 79 | |
| | | | 0.1 | 31 | 41 | 53 | 63 | 80 | |
| | | | 0.2 | 33 | 41 | 63 | 72 | 90 | |
| | | | 0.5 | 40 | 64 | 93 | 99 | 130 | |
| Ex. 147 | Single | Hf[(C₂H₅)₂N]₄ | 0.001 | 21 | 21 | 63 | 73 | 92 | 99 to 100 |
| | solution | Si[(C₂H₅)(n-C₃H₇)N]₄ | 0.01 | 19 | 37 | 69 | 62 | 89 | |
| | | | 0.1 | 42 | 46 | 73 | 83 | 101 | |
| | | | 0.2 | 33 | 43 | 73 | 87 | 120 | |
| | | | 0.5 | 34 | 49 | 83 | 98 | 131 | |

TABLE 61
Silicon substrate-Si film-HfSiO thin film

| Raw | Organic Hf compound | Mixing | Film thickness per film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 148 | Single | Hf[(CH₃)(C₂H₅)N]₄ | 0.001 | 20 | 43 | 58 | 61 | 72 | 96 to 98 |
| | solution | Si[(C₂H₅)(n-C₃H₇)N]₄ | 0.01 | 23 | 31 | 44 | 62 | 92 | |
| | | | 0.1 | 36 | 39 | 62 | 83 | 93 | |
| | | | 0.2 | 36 | 50 | 63 | 88 | 99 | |
| | | | 0.5 | 41 | 61 | 92 | 93 | 98 | |
| Ex. 149 | Single | Hf(CH₃O)₄ | 0.001 | 18 | 29 | 43 | 60 | 70 | 99 to 100 |
| | solution | Si[(C₂H₅)(n-C₃H₇)N]₄ | 0.01 | 22 | 39 | 50 | 70 | 90 | |
| | | | 0.1 | 31 | 42 | 63 | 80 | 96 | |
| | | | 0.2 | 32 | 40 | 63 | 70 | 93 | |
| | | | 0.5 | 41 | 72 | 112 | 140 | 194 | |
| Ex. 150 | Single | Hf(C₂H₅O)₄ | 0.001 | 17 | 23 | 60 | 72 | 99 | 96 to 98 |
| | solution | Si[(C₂H₅)(n-C₃H₇)N]₄ | 0.01 | 23 | 42 | 62 | 63 | 72 | |
| | | | 0.1 | 30 | 51 | 80 | 94 | 132 | |
| | | | 0.2 | 31 | 45 | 82 | 99 | 122 | |
| | | | 0.5 | 39 | 60 | 90 | 110 | 125 | |
| Ex. 151 | Single | Hf(n-C₃H₇O)₄ | 0.001 | 22 | 39 | 60 | 64 | 90 | 96 to 98 |
| | solution | Si[(C₂H₅)(n-C₃H₇)N]₄ | 0.01 | 18 | 31 | 42 | 68 | 73 | |
| | | | 0.1 | 31 | 45 | 60 | 68 | 83 | |
| | | | 0.2 | 31 | 63 | 70 | 82 | 115 | |
| | | | 0.5 | 57 | 110 | 130 | 162 | 201 | |
| Ex. 152 | Single | Hf(n-C₄H₉O)₄ | 0.001 | 23 | 42 | 55 | 65 | 75 | 98 to 99 |
| | solution | Si[(C₂H₅)(n-C₃H₇)N]₄ | 0.01 | 22 | 40 | 43 | 63 | 95 | |
| | | | 0.1 | 43 | 45 | 60 | 92 | 95 | |
| | | | 0.2 | 32 | 52 | 70 | 92 | 100 | |
| | | | 0.5 | 38 | 70 | 90 | 100 | 102 | |

TABLE 62
Silicon substrate-Si film-HfSiO thin film

| Raw | Organic Hf | Mixing | Film thickness per film | | | | | Peel test | | | | |
|---|---|---|---|---|---|---|---|---|---|---|---|---|
| material | compound & organic | ratio | formation time [nm] | | | | | [a piece/100 pieces] | | | | |
| solution | Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 153 | Single | Hf[(CH₃)₂N]₄ | 0.001 | 19 | 31 | 35 | 63 | 65 | 96 to 98 |
| | solution | Si[(C₂H₅)(n-C₄H₉)N]₄ | 0.01 | 20 | 37 | 45 | 72 | 78 | |
| | | | 0.1 | 30 | 41 | 52 | 63 | 80 | |
| | | | 0.2 | 33 | 40 | 62 | 70 | 90 | |
| | | | 0.5 | 39 | 63 | 90 | 98 | 180 | |
| Ex. 154 | Single | Hf[(C₂H₅)₂N]₄ | 0.001 | 21 | 21 | 60 | 72 | 92 | 97 to 99 |
| | solution | Si[(C₂H₅)(n-C₄H₉)N]₄ | 0.01 | 20 | 37 | 70 | 60 | 82 | |
| | | | 0.1 | 40 | 45 | 70 | 86 | 110 | |
| | | | 0.2 | 33 | 43 | 70 | 93 | 112 | |
| | | | 0.5 | 32 | 49 | 80 | 98 | 135 | |
| Ex. 155 | Single | Hf[(CH₃)(C₂H₅)N]₄ | 0.001 | 25 | 37 | 50 | 62 | 93 | 96 to 98 |
| | solution | Si[(C₂H₅)(n-C₄H₉)N]₄ | 0.01 | 22 | 41 | 43 | 64 | 86 | |
| | | | 0.1 | 23 | 38 | 53 | 73 | 82 | |
| | | | 0.2 | 40 | 50 | 72 | 84 | 120 | |
| | | | 0.5 | 50 | 70 | 100 | 180 | 192 | |
| Ex. 156 | Single | Hf(CH₃O)₄ | 0.001 | 19 | 30 | 32 | 62 | 65 | 90 to 92 |
| | solution | Si[(C₂H₅)(n-C₄H₉)N]₄ | 0.01 | 20 | 37 | 45 | 70 | 70 | |
| | | | 0.1 | 30 | 40 | 52 | 62 | 80 | |
| | | | 0.2 | 32 | 40 | 62 | 70 | 92 | |
| | | | 0.5 | 38 | 63 | 92 | 98 | 190 | |
| Ex. 157 | Single | Hf(C₂H₅O)₄ | 0.001 | 20 | 20 | 62 | 72 | 90 | 92 to 94 |
| | solution | Si[(C₂H₅)(n-C₄H₉)N]₄ | 0.01 | 18 | 36 | 68 | 60 | 82 | |
| | | | 0.1 | 41 | 46 | 72 | 86 | 109 | |
| | | | 0.2 | 32 | 42 | 72 | 93 | 120 | |
| | | | 0.5 | 33 | 48 | 82 | 98 | 131 | |

TABLE 63
Silicon substrate-Si film-HfSiO thin film

| Raw | Organic Hf compound | Mixing | Film thickness per film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 158 | Single | Hf(n-C₃H₇O)₄ | 0.001 | 25 | 35 | 50 | 62 | 90 | 94 to 96 |
| | solution | Si[(C₂H₅)(n-C₄H₉)N]₄ | 0.01 | 21 | 41 | 43 | 62 | 85 | |
| | | | 0.1 | 25 | 38 | 52 | 70 | 81 | |
| | | | 0.2 | 40 | 57 | 70 | 82 | 110 | |
| | | | 0.5 | 53 | 79 | 112 | 190 | 198 | |
| Ex. 159 | Single | Hf(n-C₄H₉O)₄ | 0.001 | 20 | 42 | 57 | 60 | 70 | 96 to 98 |
| | solution | Si[(C₂H₅)(n-C₄H₉)N]₄ | 0.01 | 22 | 30 | 43 | 60 | 90 | |
| | | | 0.1 | 35 | 38 | 60 | 82 | 90 | |
| | | | 0.2 | 35 | 49 | 62 | 87 | 98 | |
| | | | 0.5 | 40 | 60 | 90 | 92 | 97 | |
| Ex. 160 | Single | Hf[(CH₃)₂N]₄ | 0.001 | 20 | 24 | 61 | 65 | 83 | 97 to 99 |
| | solution | Si(CH₃O)₄ | 0.01 | 24 | 40 | 43 | 70 | 82 | |
| | | | 0.1 | 33 | 50 | 59 | 70 | 85 | |
| | | | 0.2 | 32 | 46 | 70 | 82 | 93 | |
| | | | 0.5 | 40 | 61 | 120 | 142 | 153 | |
| Ex. 161 | Single | Hf[(C₂H₅)₂N]₄ | 0.001 | 20 | 40 | 55 | 70 | 85 | 97 to 98 |
| | solution | Si(CH₃O)₄ | 0.01 | 19 | 30 | 43 | 65 | 73 | |
| | | | 0.1 | 30 | 46 | 62 | 82 | 93 | |
| | | | 0.2 | 32 | 60 | 70 | 90 | 99 | |
| | | | 0.5 | 60 | 109 | 120 | 132 | 140 | |
| Ex. 162 | Single | Hf[(CH₃)(C₂H₅)N]₄ | 0.001 | 23 | 40 | 55 | 69 | 79 | 99 to 100 |
| | solution | Si(CH₃O)₄ | 0.01 | 24 | 46 | 49 | 72 | 82 | |
| | | | 0.1 | 40 | 48 | 62 | 80 | 89 | |
| | | | 0.2 | 33 | 50 | 69 | 85 | 93 | |
| | | | 0.5 | 39 | 70 | 80 | 93 | 99 | |

TABLE 64
Silicon substrate-Si film-HfSiO thin film

| Raw | Organic Hf compound | Mixing | Film thicknessper film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 163 | Single | Hf(CH₃O)₄ | 0.001 | 20 | 31 | 33 | 63 | 66 | 96 to 97 |
| | solution | Si(CH₃O)₄ | 0.01 | 21 | 36 | 46 | 73 | 79 | |
| | | | 0.1 | 31 | 41 | 53 | 62 | 88 | |
| | | | 0.2 | 33 | 41 | 62 | 70 | 93 | |
| | | | 0.5 | 39 | 64 | 90 | 98 | 120 | |
| Ex. 164 | Single | Hf(C₂H₅O)₄ | 0.001 | 21 | 22 | 63 | 72 | 92 | 95 to 96 |
| | solution | Si(CH₃O)₄ | 0.01 | 19 | 37 | 69 | 60 | 82 | |
| | | | 0.1 | 42 | 46 | 73 | 88 | 109 | |
| | | | 0.2 | 33 | 43 | 73 | 94 | 121 | |
| | | | 0.5 | 34 | 50 | 83 | 98 | 130 | |
| Ex. 165 | Single | Hf(n-C₃H₇O)₄ | 0.001 | 26 | 36 | 51 | 63 | 91 | 97 to 98 |
| | solution | Si(CH₃O)₄ | 0.01 | 22 | 42 | 43 | 63 | 86 | |
| | | | 0.1 | 26 | 39 | 52 | 72 | 82 | |
| | | | 0.2 | 42 | 56 | 71 | 83 | 101 | |
| | | | 0.5 | 55 | 80 | 101 | 182 | 197 | |
| Ex. 166 | Single | Hf(n-C₄H₉O)₄ | 0.001 | 21 | 43 | 59 | 65 | 79 | 98 to 99 |
| | solution | Si(CH₃O)₄ | 0.01 | 23 | 32 | 44 | 63 | 93 | |
| | | | 0.1 | 36 | 39 | 62 | 82 | 94 | |
| | | | 0.2 | 36 | 49 | 63 | 90 | 99 | |
| | | | 0.5 | 40 | 62 | 92 | 98 | 109 | |
| Ex. 167 | Single | Hf[(CH₃)₂N]₄ | 0.001 | 40 | 63 | 90 | 99 | 109 | 97 to 98 |
| | solution | Si(C₂H₅O)₄ | 0.01 | 41 | 62 | 92 | 98 | 109 | |
| | | | 0.1 | 36 | 60 | 90 | 97 | 105 | |
| | | | 0.2 | 33 | 57 | 93 | 98 | 107 | |
| | | | 0.5 | 40 | 60 | 90 | 99 | 110 | |

TABLE 65
Silicon substrate-Si film-HfSiO thin film

| Raw | Organic Hf compound | Mixing | Film thickness er film | | | | | Peel test | | | | |
|---|---|---|---|---|---|---|---|---|---|---|---|---|
| material | & organic Si | ratio | formation time [nm] p | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 168 | Single | Hf[(C₂H₅)₂N]₄ | 0.001 | 21 | 32 | 36 | 63 | 72 | 96 to 97 |
| | solution | Si(C₂H₅O)₄ | 0.01 | 23 | 40 | 50 | 72 | 80 | |
| | | | 0.1 | 35 | 44 | 53 | 72 | 92 | |
| | | | 0.2 | 34 | 44 | 60 | 73 | 89 | |
| | | | 0.5 | 39 | 80 | 90 | 109 | 179 | |
| Ex. 169 | Single | Hf[(CH₃)(C₂H₅)N]₄ | 0.001 | 21 | 41 | 69 | 61 | 90 | 97 to 98 |
| | solution | Si(C₂H₅O)₄ | 0.01 | 22 | 36 | 69 | 72 | 88 | |
| | | | 0.1 | 39 | 43 | 80 | 88 | 120 | |
| | | | 0.2 | 37 | 42 | 82 | 101 | 109 | |
| | | | 0.5 | 33 | 46 | 83 | 110 | 118 | |
| Ex. 170 | Single | Hf(CH₃O)₄ | 0.001 | 29 | 39 | 53 | 93 | 99 | 96 to 97 |
| | solution | Si(C₂H₅O)₄ | 0.01 | 22 | 44 | 42 | 64 | 75 | |
| | | | 0.1 | 24 | 39 | 45 | 83 | 89 | |
| | | | 0.2 | 39 | 66 | 65 | 90 | 180 | |
| | | | 0.5 | 51 | 80 | 120 | 162 | 190 | |
| Ex. 171 | Single | Hf(C₂H₅O)₄ | 0.001 | 23 | 36 | 60 | 68 | 73 | 97 to 99 |
| | solution | Si(C₂H₅O)₄ | 0.01 | 27 | 39 | 50 | 93 | 112 | |
| | | | 0.1 | 39 | 50 | 63 | 92 | 118 | |
| | | | 0.2 | 41 | 55 | 65 | 100 | 125 | |
| | | | 0.5 | 43 | 60 | 90 | 100 | 120 | |
| Ex. 172 | Single | Hf(n-C₃H₇O)₄ | 0.001 | 20 | 37 | 63 | 69 | 70 | 99 to 100 |
| | solution | Si(C₂H₅O)₄ | 0.01 | 26 | 40 | 49 | 63 | 79 | |
| | | | 0.1 | 27 | 39 | 60 | 80 | 89 | |
| | | | 0.2 | 30 | 60 | 63 | 90 | 99 | |
| | | | 0.5 | 40 | 65 | 90 | 102 | 105 | |

TABLE 66
Silicon substrate-Si film-HfSiO thin film

| Raw | Organic Hf | Mixing | Film thickness [nm] per | | | | | Peel test [a piece/100 | | | | |
|---|---|---|---|---|---|---|---|---|---|---|---|---|
| material | compound & organic | ratio | film formation time | | | | | pieces] | | | | |
| solution | Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 173 | Single | Hf(n-C₄H₉O)₄ | 0.001 | 21 | 32 | 34 | 65 | 69 | 97 to 99 |
| | solution | Si(C₂H₅O)₄ | 0.01 | 22 | 39 | 45 | 73 | 79 | |
| | | | 0.1 | 33 | 42 | 53 | 65 | 80 | |
| | | | 0.2 | 36 | 42 | 59 | 73 | 83 | |
| | | | 0.5 | 39 | 65 | 92 | 99 | 182 | |
| Ex. 174 | Single | Hf[(CH₃)₂N]₄ | 0.001 | 22 | 22 | 64 | 75 | 90 | 97 to 98 |
| | solution | Si(n-C₃H₇O)₄ | 0.01 | 20 | 38 | 70 | 65 | 88 | |
| | | | 0.1 | 46 | 48 | 74 | 90 | 101 | |
| | | | 0.2 | 33 | 44 | 75 | 94 | 112 | |
| | | | 0.5 | 34 | 49 | 89 | 100 | 131 | |
| Ex. 175 | Single | Hf[(C₂H₅)₂N]₄ | 0.001 | 27 | 38 | 54 | 64 | 93 | 99 to 100 |
| | solution | Si(n-C₃H₇O)₄ | 0.01 | 23 | 43 | 43 | 65 | 84 | |
| | | | 0.1 | 28 | 40 | 53 | 75 | 81 | |
| | | | 0.2 | 42 | 59 | 72 | 90 | 101 | |
| | | | 0.5 | 56 | 79 | 113 | 160 | 189 | |
| Ex. 176 | Single | Hf[(CH₃)(C₂H₅)N]₄ | 0.001 | 21 | 43 | 59 | 62 | 69 | 97 to 98 |
| | solution | Si(n-C₃H₇O)₄ | 0.01 | 24 | 32 | 47 | 65 | 92 | |
| | | | 0.1 | 37 | 40 | 65 | 88 | 101 | |
| | | | 0.2 | 37 | 51 | 63 | 82 | 102 | |
| | | | 0.5 | 43 | 63 | 95 | 99 | 109 | |
| Ex. 177 | Single | Hf(CH₃O)₄ | 0.001 | 22 | 49 | 60 | 69 | 79 | 99 to 100 |
| | solution | Si(n-C₃H₇O)₄ | 0.01 | 25 | 33 | 50 | 65 | 80 | |
| | | | 0.1 | 36 | 42 | 68 | 80 | 89 | |
| | | | 0.2 | 38 | 53 | 69 | 82 | 90 | |
| | | | 0.5 | 44 | 62 | 92 | 97 | 109 | |

TABLE 67
Silicon substrate-Si film-HfSiO thin film

| Raw | Organic Hf compound | Mixing | Film thicknessper film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 178 | Single | Hf(C₂H₅O)₄ | 0.001 | 20 | 29 | 35 | 60 | 70 | 92 to 94 |
| | solution | Si(n-C₃H₇O)₄ | 0.01 | 22 | 36 | 49 | 70 | 81 | |
| | | | 0.1 | 37 | 40 | 55 | 70 | 92 | |
| | | | 0.2 | 33 | 42 | 60 | 70 | 90 | |
| | | | 0.5 | 38 | 88 | 90 | 100 | 180 | |
| Ex. 179 | Single | Hf(n-C₃H₇O)₄ | 0.001 | 20 | 40 | 68 | 72 | 91 | 93 to 95 |
| | solution | Si(n-C₃H₇O)₄ | 0.01 | 20 | 35 | 68 | 71 | 85 | |
| | | | 0.1 | 38 | 40 | 79 | 80 | 120 | |
| | | | 0.2 | 35 | 40 | 79 | 100 | 110 | |
| | | | 0.5 | 32 | 45 | 78 | 110 | 118 | |
| Ex. 180 | Single | Hf(n-C₄H₉O)₄ | 0.001 | 28 | 38 | 52 | 92 | 95 | 99 to 100 |
| | solution | Si(n-C₃H₇O)₄ | 0.01 | 20 | 42 | 48 | 60 | 70 | |
| | | | 0.1 | 22 | 38 | 45 | 80 | 82 | |
| | | | 0.2 | 38 | 65 | 68 | 90 | 100 | |
| | | | 0.5 | 51 | 79 | 100 | 120 | 176 | |
| Ex. 181 | Single | Hf[(CH₃)₂N]₄ | 0.001 | 22 | 35 | 62 | 64 | 82 | 97 to 89 |
| | solution | Si(n-C₄H₉O)₄ | 0.01 | 25 | 38 | 48 | 90 | 95 | |
| | | | 0.1 | 38 | 45 | 60 | 90 | 98 | |
| | | | 0.2 | 40 | 50 | 62 | 92 | 99 | |
| | | | 0.5 | 42 | 62 | 68 | 90 | 96 | |
| Ex. 182 | Single | Hf[(C₂H₅)₂N]₄ | 0.001 | 20 | 35 | 60 | 65 | 72 | 97 to 98 |
| | solution | Si(n-C₄H₉O)₄ | 0.01 | 20 | 37 | 49 | 68 | 79 | |
| | | | 0.1 | 38 | 40 | 59 | 70 | 78 | |
| | | | 0.2 | 32 | 50 | 63 | 72 | 90 | |
| | | | 0.5 | 30 | 60 | 69 | 82 | 99 | |

TABLE 68
Silicon substrate-Si film-HfSiO thin film

| Raw | Organic Hf compound | Mixing | Film thickness per film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 183 | Single | Hf[(CH₃)(C₂H₅)N]₄ | 0.001 | 23 | 32 | 37 | 63 | 73 | 97 to 98 |
| | solution | Si(n-C₄H₉O)₄ | 0.01 | 24 | 40 | 52 | 72 | 81 | |
| | | | 0.1 | 37 | 44 | 54 | 75 | 92 | |
| | | | 0.2 | 35 | 43 | 60 | 75 | 98 | |
| | | | 0.5 | 40 | 80 | 90 | 100 | 180 | |
| Ex. 184 | Single | Hf(CH₃O)₄ | 0.001 | 23 | 41 | 70 | 79 | 95 | 97 to 98 |
| | solution | Si(n-C₄H₉O)₄ | 0.01 | 22 | 37 | 71 | 78 | 85 | |
| | | | 0.1 | 40 | 42 | 79 | 89 | 120 | |
| | | | 0.2 | 37 | 49 | 80 | 120 | 125 | |
| | | | 0.5 | 34 | 46 | 81 | 101 | 118 | |
| Ex. 185 | Single | Hf(C₂H₅O)₄ | 0.001 | 30 | 38 | 52 | 90 | 95 | 95 to 96 |
| | solution | Si(n-C₄H₉O)₄ | 0.01 | 23 | 44 | 49 | 63 | 75 | |
| | | | 0.1 | 24 | 38 | 45 | 82 | 89 | |
| | | | 0.2 | 40 | 67 | 79 | 90 | 100 | |
| | | | 0.5 | 50 | 80 | 100 | 181 | 190 | |
| Ex. 186 | Single | Hf(n-C₃H₇O)₄ | 0.001 | 23 | 37 | 63 | 69 | 75 | 96 to 98 |
| | solution | Si(n-C₄H₉O)₄ | 0.01 | 26 | 38 | 49 | 90 | 110 | |
| | | | 0.1 | 38 | 49 | 62 | 92 | 118 | |
| | | | 0.2 | 40 | 53 | 65 | 97 | 100 | |
| | | | 0.5 | 42 | 70 | 90 | 99 | 120 | |
| Ex. 187 | Single | Hf(n-C₄H₉O)₄ | 0.001 | 20 | 30 | 62 | 69 | 78 | 97 to 98 |
| | solution | Si(n-C₄H₉O)₄ | 0.01 | 26 | 38 | 48 | 92 | 100 | |
| | | | 0.1 | 39 | 40 | 60 | 78 | 89 | |
| | | | 0.2 | 40 | 53 | 63 | 82 | 100 | |
| | | | 0.5 | 41 | 69 | 78 | 95 | 130 | |

As clearly shown in the tables 51 to 68, the HfSiO films formed by using the single raw material solution according to Examples A98 to A187 had a significantly high film forming rate in comparison with Comparative Example 2, and stable film formation was obtained. Also, in the peel test, most of grids were remained on substrates in HfSiO films formed by using the raw material solution according to Examples A98 to A187 and thus high adhesivity results were obtained.

### Example A188

Five raw material solutions for MOCVD method which differ in mixing ratio were respectively prepared in the same manner as in Example 1 to form Hf-Si—O—N thin films on substrates, except that Si[(CH₃)₂N]₄ was used as the organic Si compound, and Hf[(CH₃)₂N]₄ was used as the organic Hf compound. In specific, first, five silicon substrates having a SiO₂ film (thickness of 5000 Å) on each surface were respectively prepared as substrates, and the substrates were installed in the film forming chamber of the MOCVD apparatus shown in FIG. 1. Then, the substrate temperature, the vaporization temperature and the pressure were set to 600° C., 70° C., and about 266 Pa (2 torr), respectively. H₂ gas was used as a reducing gas and its partial pressure was set at 1 ccm. Ar gas was used as a carrier gas. Si[(C₂H₅)₂N]₄ was respectively fed as the organic Si compound at a rate of 0.1 g/min, and Si[(C₂H₅)₂N]₄ was thermally decomposed to grow the Si film on a surface of the substrate. Supply of the organic Si compound and the reducing gas was stopped when the film formation time reached 2 minutes. Next, O₂ gas and N₂ were used as reactant gases and their partial pressures were each set at 1000 ccm. Ar gas was used as a carrier gas, and the raw material solutions for MOCVD method were respectively fed at a rate of 0.1 g/min to form the Hf-Si—O—N film on a surface of the grown Si film. The substrates were taken out by one from the film forming chamber when the film formation time reached 1 minute, 2 minutes, 3 minutes, 4 minutes, and 5 minutes, respectively.

### Examples A189 to A194

Five raw material solutions for MOCVD method which differ in mixing ratio were respectively prepared in the same manner as in Example A188 so as to grow Si films on substrates and form Hf-Si—O—N thin films on surfaces of those Si films in the same manner as in Example A188, except that Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A195 to A201

Five raw material solutions for MOCVD method which differ in mixing ratio were respectively prepared in the same manner as in Example A188 so as to grow Si films on substrates and form Hf-Si—O—N thin films on surfaces of those Si films in the same manner as in Example A188, except that Si[(C₂H₅)₂N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A202 to A208

Five raw material solutions for MOCVD method which differ in mixing ratio were respectively prepared in the same manner as in Example A188 so as to grow Si films on substrates and form Hf-Si—O—N thin films on surfaces of those Si films in the same manner as in Example A188, except that Si[(n-C₃H₇)₂N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A209 to A215

Five raw material solutions for MOCVD method which differ in mixing ratio were respectively prepared in the same manner as in Example A188 so as to grow Si films on substrates and form Hf-Si—O—N thin films on surfaces of those Si films in the same manner as in Example A188, except that Si[(n-C₄H₉)₂N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A216 to A222

Five raw material solutions for MOCVD method which differ in mixing ratio were respectively prepared in the same manner as in Example A188 so as to grow Si films on substrates and form Hf-Si—O—N thin films on surfaces of those Si films in the same manner as in Example A188, except that Si[(CH₃)(C₂H₅)N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A223 to A229

Five raw material solutions for MOCVD method which differ in mixing ratio were respectively prepared in the same manner as in Example A188 so as to grow Si films on substrates and form Hf-Si—O—N thin films on surfaces of those Si films in the same manner as in Example A188, except that Si[(CH₃)(n-C₃H₇)N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A230 to A236

Five raw material solutions for MOCVD method which differ in mixing ratio were respectively prepared in the same manner as in Example A188 so as to grow Si films on substrates and form Hf-Si—O—N thin films on surfaces of those Si films in the same manner as in Example A188, except that Si[(CH₃)(n-C₄H₉)N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A237 to A243

Five raw material solutions for MOCVD method which differ in mixing ratio were respectively prepared in the same manner as in Example A188 so as to grow Si films on substrates and form Hf-Si—O—N thin films on surfaces of those Si films in the same manner as in Example A188, except that Si[(C₂H₅)(n-C₃H₇)N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A244 to A250

Five raw material solutions for MOCVD method which differ in mixing ratio were respectively prepared in the same manner as in Example A188 so as to grow Si films on substrates and form Hf-Si—O—N thin films on surfaces of those Si films in the same manner as in Example A188, except that Si[(C₂H₅)(n-C₄H₉)N]₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A251 to A257

Five raw material solutions for MOCVD method which differ in mixing ratio were respectively prepared in the same manner as in Example A188 so as to grow Si films on substrates and form Hf-Si—O—N thin films on surfaces of those Si films in the same manner as in Example A188, except that Si(CH₃O)₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A258 to A264

Five raw material solutions for MOCVD method which differ in mixing ratio were respectively prepared in the same manner as in Example A188 so as to grow Si films on substrates and form Hf-Si—O—N thin films on surfaces of those Si films in the same manner as in Example A188, except that Si(C₂H₅O)₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A265 to A271

Five raw material solutions for MOCVD method which differ in mixing ratio were respectively prepared in the same manner as in Example A188 so as to grow Si films on substrates and form Hf-Si—O—N thin films on surfaces of those Si films in the same manner as in Example A188, except that Si(n-C₃H₇O)₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

### Examples A272 to A278

Five raw material solutions for MOCVD method which differ in mixing ratio were respectively prepared in the same manner as in Example A188 so as to grow Si films on substrates and form Hf-Si—O—N thin films on surfaces of those Si films in the same manner as in Example A188, except that Si(n-C₄H₉O)₄ was used as the organic Si compound, and Hf[(CH₃)₂N]₄, Hf[(C₂H₅)₂N]₄, Hf[(CH₃)(C₂H₅)N]₄, Hf(CH₃O)₄, Hf(C₂H₅O)₄, Hf(n-C₃H₇O)₄ and Hf(n-C₄H₉O)₄ were used as the organic Hf compound.

<Comparative Test A6>

For each obtained Hf-Si—O—N thin film according to Examples A188 to A278, a film thickness test, and a peel test to examine adhesivity, per film formation time of the obtained Hf-Si—O—N thin film were carried out in the same manner as in the above-mentioned Comparative Test A1.

<Evaluation>

Obtained results of the film thickness and the peel test per film formation time are respectively shown in tables 69 to 87. The peel test shows the number of remaining substrates per 100 pieces of cut grid. In the tables 69 to 87, letter ‘A’s numbering Examples are omitted.

TABLE 69
Silicon substrate-Si film-HfSiON thin film

| Raw | Organic Hf | Mixing | Film thickness per film | | | | | Peel test | | | | |
|---|---|---|---|---|---|---|---|---|---|---|---|---|
| material | compound & organic | ratio | formation time [nm] | | | | | [a piece/100 pieces] | | | | |
| solution | Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 188 | Single | Hf[(CH₃)₂N]₄ | 0.001 | 24 | 33 | 35 | 69 | 85 | 97 to 98 |
| | solution | Si[(CH₃)₂N]₄ | 0.01 | 23 | 40 | 45 | 76 | 87 | |
| | | | 0.1 | 34 | 43 | 85 | 64 | 82 | |
| | | | 0.2 | 37 | 43 | 63 | 79 | 93 | |
| | | | 0.5 | 41 | 65 | 93 | 101 | 180 | |
| Ex. 189 | Single | Hf[(C₂H₅)₂N]₄ | 0.001 | 23 | 23 | 65 | 75 | 93 | 97 to 99 |
| | solution | Si[(CH₃)₂N]₄ | 0.01 | 22 | 39 | 69 | 90 | 95 | |
| | | | 0.1 | 47 | 87 | 85 | 92 | 101 | |
| | | | 0.2 | 35 | 46 | 76 | 96 | 113 | |
| | | | 0.5 | 36 | 53 | 92 | 101 | 140 | |
| Ex. 190 | Single | Hf[(CH₃)(C₂H₅)N]₄ | 0.001 | 28 | 38 | 56 | 65 | 92 | 99 to 100 |
| | solution | Si[(CH₃)₂N]₄ | 0.01 | 24 | 46 | 87 | 99 | 103 | |
| | | | 0.1 | 28 | 41 | 60 | 76 | 85 | |
| | | | 0.2 | 42 | 61 | 73 | 93 | 99 | |
| | | | 0.5 | 57 | 81 | 110 | 182 | 190 | |
| Ex. 191 | Single | Hf(CH₃O)₄ | 0.001 | 20 | 31 | 35 | 62 | 70 | 99 to 100 |
| | solution | Si[(CH₃)₂N]₄ | 0.01 | 22 | 39 | 49 | 70 | 80 | |
| | | | 0.1 | 35 | 43 | 53 | 70 | 92 | |
| | | | 0.2 | 33 | 42 | 62 | 72 | 99 | |
| | | | 0.5 | 38 | 85 | 93 | 110 | 180 | |
| Ex. 192 | Single | Hf(C₂H₅O)₄ | 0.001 | 20 | 40 | 68 | 60 | 90 | 99 to 100 |
| | solution | Si[(CH₃)₂N]₄ | 0.01 | 21 | 35 | 68 | 70 | 85 | |
| | | | 0.1 | 38 | 42 | 79 | 88 | 121 | |
| | | | 0.2 | 35 | 41 | 79 | 100 | 110 | |
| | | | 0.5 | 32 | 45 | 80 | 109 | 119 | |

TABLE 70
Silicon substrate-Si film-HfSiON thin film

| Raw | Organic Hf compound | Mixing | Film thickness per film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 193 | Single | Hf(n-C₃H₇O)₄ | 0.001 | 28 | 38 | 52 | 92 | 95 | 98 to 99 |
| | solution | Si[(CH₃)₂N]₄ | 0.01 | 21 | 43 | 40 | 65 | 70 | |
| | | | 0.1 | 23 | 38 | 44 | 80 | 88 | |
| | | | 0.2 | 38 | 65 | 65 | 90 | 190 | |
| | | | 0.5 | 50 | 79 | 119 | 182 | 195 | |
| Ex. 194 | Single | Hf(n-C₄H₉O)4 | 0.001 | 22 | 35 | 60 | 65 | 72 | 99 to 100 |
| | solution | Si[(CH₃)₂N]₄ | 0.01 | 25 | 38 | 48 | 92 | 110 | |
| | | | 0.1 | 38 | 49 | 60 | 90 | 110 | |
| | | | 0.2 | 40 | 53 | 62 | 99 | 120 | |
| | | | 0.5 | 43 | 68 | 90 | 99 | 120 | |
| Ex. 195 | Single | Hf[(CH₃)₂N]₄ | 0.001 | 23 | 32 | 39 | 65 | 75 | 99 to 100 |
| | solution | Si[(C₂H₅)₂N]₄ | 0.01 | 24 | 40 | 52 | 72 | 83 | |
| | | | 0.1 | 37 | 44 | 55 | 77 | 92 | |
| | | | 0.2 | 36 | 45 | 64 | 74 | 99 | |
| | | | 0.5 | 42 | 88 | 95 | 113 | 172 | |
| Ex. 196 | Single | Hf[(C₂H₅)₂N]₄ | 0.001 | 23 | 43 | 72 | 85 | 95 | 97 to 98 |
| | solution | Si[(C₂H₅)₂N]₄ | 0.01 | 23 | 37 | 71 | 73 | 87 | |
| | | | 0.1 | 40 | 49 | 80 | 92 | 121 | |
| | | | 0.2 | 38 | 43 | 81 | 112 | 125 | |
| | | | 0.5 | 38 | 49 | 80 | 120 | 132 | |
| Ex. 197 | Single | Hf[(CH₃)(C₂H₅)N]₄ | 0.001 | 31 | 41 | 55 | 93 | 99 | 99 to 100 |
| | solution | Si[(C₂H₅)₂N]₄ | 0.01 | 24 | 46 | 59 | 65 | 72 | |
| | | | 0.1 | 25 | 42 | 49 | 84 | 90 | |
| | | | 0.2 | 40 | 65 | 70 | 93 | 180 | |
| | | | 0.5 | 50 | 81 | 121 | 162 | 190 | |

TABLE 71
Silicon substrate-Si film-HfSiON thin film

| Raw | Organic Hf compound | Mixing | Film thickness per film | | | | | Peel test | | | | |
|---|---|---|---|---|---|---|---|---|---|---|---|---|
| material | & organic Si | ratio | formation time [nm] | | | | | [a piece/100 pieces] | | | | |
| solution | compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 198 | Single | Hf(CH₃O)₄ | 0.001 | 20 | 31 | 33 | 62 | 63 | 96 to 97 |
| | solution | Si[(C₂H₅)₂N]₄ | 0.01 | 21 | 38 | 44 | 72 | 72 | |
| | | | 0.1 | 32 | 41 | 53 | 63 | 81 | |
| | | | 0.2 | 35 | 41 | 63 | 72 | 83 | |
| | | | 0.5 | 39 | 64 | 93 | 99 | 192 | |
| Ex. 199 | Single | Hf(C₂H₅O)₄ | 0.001 | 21 | 21 | 63 | 73 | 90 | 97 to 99 |
| | solution | Si[(C₂H₅)₂N]₄ | 0.01 | 19 | 37 | 69 | 62 | 85 | |
| | | | 0.1 | 45 | 46 | 73 | 88 | 100 | |
| | | | 0.2 | 33 | 43 | 74 | 93 | 113 | |
| | | | 0.5 | 34 | 49 | 88 | 99 | 132 | |
| Ex. 200 | Single | Hf(n-C₃H₇O)₄ | 0.001 | 26 | 37 | 53 | 63 | 93 | 99 to 100 |
| | solution | Si[(C₂H₅)₂N]₄ | 0.01 | 22 | 42 | 42 | 63 | 84 | |
| | | | 0.1 | 27 | 39 | 52 | 73 | 80 | |
| | | | 0.2 | 41 | 57 | 70 | 88 | 100 | |
| | | | 0.5 | 55 | 79 | 112 | 190 | 199 | |
| Ex. 201 | Single | Hf(n-C₄H₉O)₄ | 0.001 | 21 | 42 | 56 | 60 | 69 | 99 to 100 |
| | solution | Si[(C₂H₅)₂N]₄ | 0.01 | 23 | 31 | 43 | 60 | 93 | |
| | | | 0.1 | 36 | 39 | 62 | 80 | 100 | |
| | | | 0.2 | 36 | 50 | 61 | 84 | 100 | |
| | | | 0.5 | 41 | 62 | 93 | 95 | 100 | |
| Ex. 202 | Single | Hf[(CH₃)₂N]₄ | 0.001 | 35 | 49 | 60 | 83 | 120 | 99 to 100 |
| | solution | Si[(n-C₃H₇)₂N]₄ | 0.01 | 32 | 45 | 62 | 82 | 125 | |
| | | | 0.1 | 30 | 42 | 65 | 92 | 130 | |
| | | | 0.2 | 40 | 53 | 69 | 93 | 132 | |
| | | | 0.5 | 42 | 55 | 70 | 98 | 141 | |

TABLE 72
Silicon substrate-Si film-HfSiON thin film

| Raw | Organic Hf | Mixing | Film thickness per film | | | | | Peel test | | | | |
|---|---|---|---|---|---|---|---|---|---|---|---|---|
| material | compound & organic | ratio | formation time [nm] | | | | | [a piece/100 pieces] | | | | |
| solution | Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 203 | Single | Hf[(C₂H₅)₂N]₄ | 0.001 | 21 | 32 | 41 | 61 | 73 | 93 to 95 |
| | solution | Si[(n-C₃H₇)₂N]₄ | 0.01 | 23 | 38 | 47 | 73 | 83 | |
| | | | 0.1 | 32 | 43 | 57 | 79 | 96 | |
| | | | 0.2 | 30 | 42 | 59 | 72 | 97 | |
| | | | 0.5 | 42 | 69 | 112 | 123 | 170 | |
| Ex. 204 | Single | Hf[(CH₃)(C₂H₅)N]₄ | 0.001 | 19 | 23 | 63 | 69 | 98 | 94 to 96 |
| | solution | Si[(n-C₃H₇)₂N]₄ | 0.01 | 23 | 39 | 61 | 63 | 69 | |
| | | | 0.1 | 31 | 49 | 80 | 92 | 130 | |
| | | | 0.2 | 35 | 42 | 82 | 93 | 110 | |
| | | | 0.5 | 42 | 58 | 87 | 99 | 121 | |
| Ex. 205 | Single | Hf(CH₃O)₄ | 0.001 | 21 | 30 | 36 | 62 | 71 | 90 to 92 |
| | solution | Si[(n-C₃H₇)₂N]₄ | 0.01 | 23 | 38 | 50 | 71 | 81 | |
| | | | 0.1 | 36 | 42 | 54 | 71 | 92 | |
| | | | 0.2 | 34 | 43 | 63 | 73 | 99 | |
| | | | 0.5 | 39 | 86 | 93 | 111 | 181 | |
| Ex. 206 | Single | Hf(C₂H₅O)₄ | 0.001 | 21 | 41 | 69 | 61 | 91 | 92 to 94 |
| | solution | Si[(n-C₃H₇)₂N]₄ | 0.01 | 22 | 36 | 69 | 71 | 85 | |
| | | | 0.1 | 39 | 41 | 80 | 89 | 121 | |
| | | | 0.2 | 36 | 42 | 80 | 110 | 110 | |
| | | | 0.5 | 33 | 46 | 80 | 119 | 119 | |
| Ex. 207 | Single | Hf(n-C₃H₇O)₄ | 0.001 | 29 | 39 | 53 | 93 | 95 | 94 to 96 |
| | solution | Si[(n-C₃H₇)₂N]₄ | 0.01 | 22 | 44 | 41 | 65 | 71 | |
| | | | 0.1 | 23 | 39 | 45 | 82 | 88 | |
| | | | 0.2 | 39 | 66 | 68 | 91 | 101 | |
| | | | 0.5 | 51 | 80 | 119 | 183 | 194 | |

TABLE 73
Silicon substrate-Si film-HfSiON thin film

| Raw | | Mixing | Film thickness per film | | | | | Peel test | | | | |
|---|---|---|---|---|---|---|---|---|---|---|---|---|
| material | Organic Hf compound | ratio | formation time [nm] | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 208 | Single | Hf(n-C₄H₉O)₄ | 0.001 | 23 | 36 | 62 | 64 | 72 | 90 to 92 |
| | solution | Si[(n-C₃H₇)₂N]₄ | 0.01 | 26 | 39 | 49 | 92 | 110 | |
| | | | 0.1 | 39 | 48 | 61 | 92 | 111 | |
| | | | 0.2 | 41 | 54 | 63 | 99 | 120 | |
| | | | 0.5 | 44 | 69 | 91 | 99 | 121 | |
| Ex. 209 | Single | Hf[(CH₃)₂N]₄ | 0.001 | 20 | 29 | 43 | 63 | 75 | 97 to 99 |
| | solution | Si[(n-C₄H₉)₂N]₄ | 0.01 | 23 | 39 | 50 | 73 | 93 | |
| | | | 0.1 | 31 | 43 | 62 | 83 | 95 | |
| | | | 0.2 | 32 | 40 | 63 | 73 | 93 | |
| | | | 0.5 | 42 | 73 | 110 | 140 | 159 | |
| Ex. 210 | Single | Hf[(C₂H₅)₂N]₄ | 0.001 | 17 | 23 | 63 | 72 | 99 | 96 to 98 |
| | solution | Si[(n-C₄H₉)₂N]₄ | 0.01 | 23 | 42 | 64 | 63 | 132 | |
| | | | 0.1 | 30 | 53 | 86 | 93 | 125 | |
| | | | 0.2 | 39 | 47 | 83 | 99 | 123 | |
| | | | 0.5 | 39 | 60 | 90 | 100 | 120 | |
| Ex. 211 | Single | Hf[(CH₃)(C₂H₅)N]₄ | 0.001 | 23 | 38 | 59 | 64 | 92 | 99 to 100 |
| | solution | Si[(n-C₄H₉)₂N]₄ | 0.01 | 18 | 31 | 42 | 68 | 73 | |
| | | | 0.1 | 30 | 42 | 63 | 69 | 85 | |
| | | | 0.2 | 31 | 60 | 70 | 83 | 109 | |
| | | | 0.5 | 56 | 100 | 120 | 142 | 200 | |
| Ex. 212 | Single | Hf(CH₃O)₄ | 0.001 | 23 | 32 | 34 | 63 | 82 | 96 to 97 |
| | solution | Si[(n-C₄H₉)₂N]₄ | 0.01 | 22 | 39 | 45 | 74 | 85 | |
| | | | 0.1 | 33 | 42 | 55 | 64 | 81 | |
| | | | 0.2 | 36 | 42 | 64 | 78 | 93 | |
| | | | 0.5 | 40 | 64 | 94 | 100 | 190 | |

TABLE 74
Silicon substrate-Si film-HfSiON thin film

| Raw | | Mixing | Film thickness per film | | | | | Peel test | | | | |
|---|---|---|---|---|---|---|---|---|---|---|---|---|
| material | Organic Hf compound | ratio | formation time [nm] | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 213 | Single | Hf(C₂H₅O)₄ | 0.001 | 22 | 21 | 64 | 74 | 93 | 97 to 98 |
| | solution | Si[(n-C₄H₉)₂N]₄ | 0.01 | 20 | 38 | 68 | 89 | 97 | |
| | | | 0.1 | 46 | 85 | 74 | 90 | 100 | |
| | | | 0.2 | 34 | 45 | 75 | 95 | 113 | |
| | | | 0.5 | 35 | 50 | 90 | 100 | 135 | |
| Ex. 214 | Single | Hf(n-C₃H₇O)₄ | 0.001 | 27 | 37 | 55 | 63 | 90 | 99 to 100 |
| | solution | Si[(n-C₄H₉)₂N]₄ | 0.01 | 23 | 45 | 84 | 99 | 105 | |
| | | | 0.1 | 27 | 40 | 59 | 73 | 85 | |
| | | | 0.2 | 41 | 60 | 72 | 90 | 95 | |
| | | | 0.5 | 56 | 80 | 110 | 190 | 195 | |
| Ex. 215 | Single | Hf(n-C₄H₉O)₄ | 0.001 | 22 | 43 | 60 | 65 | 69 | 99 to 100 |
| | solution | Si[(n-C₄H₉)₂N]₄ | 0.01 | 24 | 33 | 49 | 62 | 92 | |
| | | | 0.1 | 37 | 40 | 63 | 80 | 100 | |
| | | | 0.2 | 37 | 51 | 62 | 85 | 95 | |
| | | | 0.5 | 42 | 65 | 100 | 110 | 120 | |
| Ex. 216 | Single | Hf[(CH₃)₂N]₄ | 0.001 | 24 | 45 | 53 | 60 | 90 | 96 to 97 |
| | solution | Si[(CH₃)(C₂H₅)N]₄ | 0.01 | 23 | 35 | 36 | 62 | 82 | |
| | | | 0.1 | 42 | 36 | 52 | 65 | 81 | |
| | | | 0.2 | 32 | 52 | 73 | 81 | 100 | |
| | | | 0.5 | 42 | 68 | 110 | 176 | 185 | |
| Ex. 217 | Single | Hf[(C₂H₅)₂N]₄ | 0.001 | 19 | 37 | 59 | 62 | 68 | 99 to 100 |
| | solution | Si[(CH₃)(C₂H₅)N]₄ | 0.01 | 23 | 42 | 49 | 59 | 92 | |
| | | | 0.1 | 42 | 35 | 60 | 82 | 89 | |
| | | | 0.2 | 32 | 62 | 63 | 88 | 95 | |
| | | | 0.5 | 35 | 82 | 90 | 93 | 99 | |

TABLE 75
Silicon substrate-Si film-HfSiON thin film

| Raw | | Mixing | Film thickness er film | | | | | Peel test | | | | |
|---|---|---|---|---|---|---|---|---|---|---|---|---|
| material | Organic Hf compound | ratio | formation time [nm] p | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 218 | Single | Hf[(CH₃)(C₂H₅)N]₄ | 0.001 | 21 | 32 | 38 | 63 | 69 | 95 to 97 |
| | solution | Si[(CH₃)(C₂H₅)N]₄ | 0.01 | 25 | 39 | 45 | 72 | 78 | |
| | | | 0.1 | 31 | 43 | 52 | 65 | 82 | |
| | | | 0.2 | 35 | 42 | 63 | 72 | 90 | |
| | | | 0.5 | 40 | 63 | 93 | 99 | 120 | |
| Ex. 219 | Single | Hf(CH₃O)₄ | 0.001 | 21 | 31 | 37 | 63 | 73 | 90 to 92 |
| | solution | Si[(CH₃)(C₂H₅)N]₄ | 0.01 | 23 | 39 | 51 | 72 | 82 | |
| | | | 0.1 | 36 | 43 | 54 | 72 | 93 | |
| | | | 0.2 | 35 | 44 | 63 | 73 | 99 | |
| | | | 0.5 | 40 | 87 | 94 | 112 | 182 | |
| Ex. 220 | Single | Hf(C₂H₅O)₄ | 0.001 | 22 | 42 | 70 | 82 | 93 | 92 to 95 |
| | solution | Si[(CH₃)(C₂H₅)N]₄ | 0.01 | 22 | 36 | 70 | 72 | 86 | |
| | | | 0.1 | 39 | 42 | 81 | 90 | 122 | |
| | | | 0.2 | 37 | 43 | 80 | 111 | 111 | |
| | | | 0.5 | 34 | 47 | 81 | 119 | 119 | |
| Ex. 221 | Single | Hf(n-C₃H₇O)₄ | 0.001 | 30 | 40 | 54 | 94 | 96 | 99 to 100 |
| | solution | Si[(CH₃)(C₂H₅)N]₄ | 0.01 | 23 | 45 | 52 | 66 | 72 | |
| | | | 0.1 | 24 | 40 | 47 | 83 | 88 | |
| | | | 0.2 | 40 | 67 | 69 | 92 | 192 | |
| | | | 0.5 | 52 | 81 | 120 | 182 | 193 | |
| Ex. 222 | Single | Hf(n-C₄H₉O)₄ | 0.001 | 24 | 36 | 61 | 63 | 74 | 96 to 97 |
| | solution | Si[(CH₃)(C₂H₅)N]₄ | 0.01 | 27 | 39 | 49 | 92 | 111 | |
| | | | 0.1 | 40 | 49 | 62 | 93 | 111 | |
| | | | 0.2 | 42 | 55 | 64 | 99 | 121 | |
| | | | 0.5 | 45 | 70 | 92 | 99 | 120 | |

TABLE 76
Silicon substrate-Si film-HfSiON thin film

| Raw | | Mixing | Film thickness [nm] per | | | | | Peel test | | | | |
|---|---|---|---|---|---|---|---|---|---|---|---|---|
| material | Organic Hf compound | ratio | film formation time | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 223 | Single | Hf[(CH₃)₂N]₄ | 0.001 | 25 | 28 | 49 | 62 | 78 | 98 to 99 |
| | solution | Si[(CH₃)(n-C₃H₇)N]₄ | 0.01 | 19 | 32 | 53 | 70 | 90 | |
| | | | 0.1 | 42 | 43 | 70 | 82 | 93 | |
| | | | 0.2 | 33 | 40 | 72 | 82 | 95 | |
| | | | 0.5 | 39 | 48 | 82 | 98 | 110 | |
| Ex. 224 | Single | Hf[(C₂H₅)₂N]₄ | 0.001 | 28 | 36 | 50 | 72 | 92 | 97 to 99 |
| | solution | Si[(CH₃)(n-C₃H₇)N]₄ | 0.01 | 25 | 42 | 44 | 63 | 80 | |
| | | | 0.1 | 30 | 39 | 52 | 88 | 99 | |
| | | | 0.2 | 40 | 56 | 65 | 92 | 110 | |
| | | | 0.5 | 52 | 70 | 112 | 125 | 141 | |
| Ex. 225 | Single | Hf[(CH₃)(C₂H₅)N]₄ | 0.001 | 23 | 43 | 70 | 82 | 99 | 98 to 100 |
| | solution | Si[(CH₃)(n-C₃H₇)N]₄ | 0.01 | 25 | 30 | 43 | 69 | 82 | |
| | | | 0.1 | 36 | 39 | 62 | 72 | 81 | |
| | | | 0.2 | 37 | 49 | 65 | 78 | 88 | |
| | | | 0.5 | 40 | 53 | 68 | 80 | 99 | |
| Ex. 226 | Single | Hf(CH₃O)₄ | 0.001 | 22 | 31 | 37 | 63 | 75 | 98 to 99 |
| | solution | Si[(CH₃)(n-C₃H₇)N]₄ | 0.01 | 24 | 39 | 51 | 72 | 82 | |
| | | | 0.1 | 40 | 44 | 55 | 73 | 92 | |
| | | | 0.2 | 35 | 45 | 63 | 75 | 99 | |
| | | | 0.5 | 40 | 85 | 93 | 110 | 182 | |
| Ex. 227 | Single | Hf(C₂H₅O)₄ | 0.001 | 22 | 43 | 69 | 62 | 90 | 97 to 99 |
| | solution | Si[(CH₃)(n-C₃H₇)N]₄ | 0.01 | 26 | 37 | 69 | 75 | 82 | |
| | | | 0.1 | 40 | 41 | 82 | 90 | 120 | |
| | | | 0.2 | 37 | 43 | 82 | 110 | 110 | |
| | | | 0.5 | 35 | 49 | 80 | 117 | 118 | |

TABLE 77
Silicon substrate-Si film-HfSiON thin film

| Raw | | Mixing | Film thickness per film | | | | | Peel test | | | | |
|---|---|---|---|---|---|---|---|---|---|---|---|---|
| material | Organic Hf compound | ratio | formation time [nm] | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 228 | Single | Hf(n-C₃H₇O)₄ | 0.001 | 30 | 42 | 54 | 94 | 99 | 96 to 98 |
| | solution | Si[(CH₃)(n-C₃H₇)N]₄ | 0.01 | 23 | 45 | 42 | 65 | 75 | |
| | | | 0.1 | 24 | 40 | 47 | 84 | 89 | |
| | | | 0.2 | 40 | 62 | 69 | 92 | 110 | |
| | | | 0.5 | 53 | 80 | 110 | 180 | 190 | |
| Ex. 229 | Single | Hf(n-C₄H₉O)₄ | 0.001 | 24 | 37 | 62 | 65 | 72 | 99 to 100 |
| | solution | Si[(CH₃)(n-C₃H₇)N]₄ | 0.01 | 27 | 40 | 50 | 95 | 118 | |
| | | | 0.1 | 40 | 48 | 62 | 92 | 118 | |
| | | | 0.2 | 42 | 55 | 64 | 98 | 120 | |
| | | | 0.5 | 45 | 70 | 95 | 99 | 125 | |
| Ex. 230 | Single | Hf[(CH₃)₂N]₄ | 0.001 | 21 | 41 | 68 | 82 | 90 | 92 to 95 |
| | solution | Si[(CH₃)(n-C₄H₉)N]₄ | 0.01 | 22 | 35 | 69 | 78 | 85 | |
| | | | 0.1 | 40 | 42 | 80 | 99 | 121 | |
| | | | 0.2 | 36 | 43 | 82 | 110 | 129 | |
| | | | 0.5 | 35 | 46 | 69 | 108 | 128 | |
| Ex. 231 | Single | Hf[(C₂H₅)₂N]₄ | 0.001 | 30 | 37 | 50 | 93 | 100 | 93 to 94 |
| | solution | Si[(CH₃)(n-C₄H₉)N]₄ | 0.01 | 23 | 40 | 49 | 65 | 70 | |
| | | | 0.1 | 32 | 37 | 44 | 82 | 89 | |
| | | | 0.2 | 38 | 66 | 73 | 83 | 99 | |
| | | | 0.5 | 50 | 80 | 93 | 162 | 179 | |
| Ex. 232 | Single | Hf[(CH₃)(C₂H₅)N]₄ | 0.001 | 23 | 35 | 62 | 89 | 102 | 99 to 100 |
| | solution | Si[(CH₃)(n-C₄H₉)N]₄ | 0.01 | 25 | 40 | 48 | 92 | 110 | |
| | | | 0.1 | 40 | 50 | 62 | 90 | 110 | |
| | | | 0.2 | 42 | 53 | 65 | 82 | 109 | |
| | | | 0.5 | 45 | 69 | 92 | 100 | 112 | |

TABLE 78
Silicon substrate-Si film-HfSiON thin film

| Raw | | Mixing | Film thickness per film | | | | | Peel test | | | | |
|---|---|---|---|---|---|---|---|---|---|---|---|---|
| material | Organic Hf compound | ratio | formation time [nm] | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 233 | Single | Hf(CH₃O)₄ | 0.001 | 22 | 32 | 37 | 63 | 74 | 99 to 100 |
| | solution | Si[(CH₃)(n-C₄H₉)N]₄ | 0.01 | 24 | 40 | 52 | 73 | 83 | |
| | | | 0.1 | 36 | 44 | 55 | 73 | 93 | |
| | | | 0.2 | 35 | 45 | 64 | 74 | 99 | |
| | | | 0.5 | 41 | 88 | 94 | 113 | 181 | |
| Ex. 234 | Single | Hf(C₂H₅O)₄ | 0.001 | 23 | 42 | 71 | 63 | 94 | 99 to 100 |
| | solution | Si[(CH₃)(n-C₄H₉)N]₄ | 0.01 | 23 | 36 | 71 | 73 | 87 | |
| | | | 0.1 | 40 | 44 | 81 | 91 | 123 | |
| | | | 0.2 | 37 | 44 | 81 | 112 | 112 | |
| | | | 0.5 | 34 | 48 | 80 | 120 | 118 | |
| Ex. 235 | Single | Hf(n-C₃H₇O)₄ | 0.001 | 31 | 41 | 55 | 95 | 97 | 99 to 100 |
| | solution | Si[(CH₃)(n-C₄H₉)N]₄ | 0.01 | 24 | 46 | 43 | 66 | 73 | |
| | | | 0.1 | 24 | 41 | 47 | 84 | 89 | |
| | | | 0.2 | 41 | 68 | 69 | 93 | 192 | |
| | | | 0.5 | 53 | 82 | 122 | 183 | 190 | |
| Ex. 236 | Single | Hf(n-C₄H₉O)₄ | 0.001 | 25 | 36 | 62 | 64 | 75 | 96 to 97 |
| | solution | Si[(CH₃)(n-C₄H₉)N]₄ | 0.01 | 28 | 39 | 50 | 93 | 112 | |
| | | | 0.1 | 41 | 50 | 63 | 93 | 113 | |
| | | | 0.2 | 43 | 54 | 64 | 99 | 120 | |
| | | | 0.5 | 46 | 71 | 93 | 98 | 121 | |
| Ex. 237 | Single | Hf[(CH₃)₂N]₄ | 0.001 | 24 | 35 | 49 | 63 | 93 | 93 to 95 |
| | solution | Si[(C₂H₅)(n-C₃H₇)N]₄ | 0.01 | 23 | 32 | 42 | 69 | 82 | |
| | | | 0.1 | 32 | 40 | 53 | 62 | 81 | |
| | | | 0.2 | 41 | 52 | 68 | 79 | 92 | |
| | | | 0.5 | 52 | 62 | 72 | 82 | 99 | |

TABLE 79
Silicon substrate-Si film-HfSiON thin film

| Raw | | Mixing | Film thickness per film | | | | | Peel test | | | | |
|---|---|---|---|---|---|---|---|---|---|---|---|---|
| material | Organic Hf compound | ratio | formation time [nm] | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 238 | Single | Hf[(C₂H₅)₂N]₄ | 0.001 | 21 | 32 | 35 | 63 | 71 | 93 to 95 |
| | solution | Si[(C₂H₅)(n-C₃H₇)N]₄ | 0.01 | 22 | 40 | 50 | 72 | 82 | |
| | | | 0.1 | 36 | 43 | 59 | 71 | 80 | |
| | | | 0.2 | 34 | 45 | 62 | 70 | 82 | |
| | | | 0.5 | 39 | 72 | 83 | 93 | 112 | |
| Ex. 239 | Single | Hf[(CH₃)(C₂H₅)N]₄ | 0.001 | 21 | 35 | 60 | 69 | 92 | 94 to 96 |
| | solution | Si[(C₂H₅)(n-C₃H₇)N]₄ | 0.01 | 25 | 41 | 60 | 72 | 88 | |
| | | | 0.1 | 27 | 33 | 55 | 89 | 120 | |
| | | | 0.2 | 30 | 41 | 70 | 90 | 101 | |
| | | | 0.5 | 41 | 49 | 72 | 93 | 109 | |
| Ex. 240 | Single | Hf(CH₃O)₄ | 0.001 | 22 | 31 | 36 | 64 | 75 | 93 to 100 |
| | solution | Si[(C₂H₅)(n-C₃H₇)N]₄ | 0.01 | 28 | 38 | 51 | 78 | 85 | |
| | | | 0.1 | 30 | 40 | 55 | 76 | 99 | |
| | | | 0.2 | 35 | 42 | 62 | 75 | 100 | |
| | | | 0.5 | 44 | 80 | 93 | 110 | 190 | |
| Ex. 241 | Single | Hf(C₂H₅O)₄ | 0.001 | 23 | 42 | 72 | 80 | 95 | 92 to 94 |
| | solution | Si[(C₂H₅)(n-C₃H₇)N]₄ | 0.01 | 24 | 37 | 72 | 85 | 95 | |
| | | | 0.1 | 40 | 46 | 85 | 93 | 99 | |
| | | | 0.2 | 39 | 45 | 80 | 100 | 110 | |
| | | | 0.5 | 39 | 50 | 79 | 120 | 129 | |
| Ex. 242 | Single | Hf(n-C₃H₇O)₄ | 0.001 | 38 | 42 | 55 | 93 | 99 | 94 to 98 |
| | solution | Si[(C₂H₅)(n-C₃H₇)N]₄ | 0.01 | 24 | 48 | 54 | 69 | 78 | |
| | | | 0.1 | 25 | 40 | 49 | 80 | 90 | |
| | | | 0.2 | 42 | 65 | 69 | 90 | 180 | |
| | | | 0.5 | 53 | 80 | 120 | 180 | 190 | |

TABLE 80
Silicon substrate-Si film-HfSiON thin film

| Raw | | Mixing | Film thickness per film | | | | | Peel test | | | | |
|---|---|---|---|---|---|---|---|---|---|---|---|---|
| material | Organic Hf compound | ratio | formation time [nm] | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 243 | Single | Hf(n-C₄H₉O)₄ | 0.001 | 24 | 36 | 60 | 61 | 70 | 98 to 100 |
| | solution | Si[(C₂H₅)(n-C₃H₇)N]₄ | 0.01 | 29 | 40 | 50 | 90 | 110 | |
| | | | 0.1 | 40 | 50 | 68 | 93 | 112 | |
| | | | 0.2 | 43 | 53 | 69 | 97 | 130 | |
| | | | 0.5 | 45 | 68 | 90 | 100 | 119 | |
| Ex. 244 | Single | Hf[(CH₃)₂N]₄ | 0.001 | 21 | 32 | 34 | 63 | 69 | 99 to 100 |
| | solution | Si[(C₂H₅)(n-C₄H₉)N]₄ | 0.01 | 22 | 39 | 45 | 72 | 88 | |
| | | | 0.1 | 33 | 42 | 54 | 64 | 89 | |
| | | | 0.2 | 36 | 42 | 64 | 74 | 84 | |
| | | | 0.5 | 40 | 65 | 82 | 98 | 172 | |
| Ex. 245 | Single | Hf[(C₂H₅)₂N]₄ | 0.001 | 22 | 24 | 53 | 69 | 94 | 98 to 100 |
| | solution | Si[(C₂H₅)(n-C₄H₉)N]₄ | 0.01 | 20 | 37 | 43 | 64 | 84 | |
| | | | 0.1 | 46 | 48 | 53 | 74 | 83 | |
| | | | 0.2 | 34 | 59 | 70 | 88 | 102 | |
| | | | 0.5 | 35 | 80 | 109 | 120 | 129 | |
| Ex. 246 | Single | Hf[(CH₃)(C₂H₅)N]₄ | 0.001 | 27 | 43 | 59 | 62 | 69 | 99 to 100 |
| | solution | Si[(C₂H₅)(n-C₄H₉)N]₄ | 0.01 | 23 | 33 | 43 | 63 | 93 | |
| | | | 0.1 | 28 | 40 | 62 | 82 | 100 | |
| | | | 0.2 | 42 | 51 | 63 | 84 | 93 | |
| | | | 0.5 | 56 | 63 | 94 | 99 | 125 | |
| Ex. 247 | Single | Hf(CH₃O)₄ | 0.001 | 23 | 33 | 37 | 64 | 76 | 90 to 95 |
| | solution | Si[(C₂H₅)(n-C₄H₉)N]₄ | 0.01 | 25 | 41 | 53 | 74 | 84 | |
| | | | 0.1 | 37 | 45 | 55 | 74 | 94 | |
| | | | 0.2 | 34 | 46 | 65 | 75 | 95 | |
| | | | 0.5 | 40 | 89 | 96 | 115 | 180 | |

TABLE 81
Silicon substrate-Si film-HfSiON thin film

| Raw | | Mixing | Film thickness per film | | | | | Peel test | | | | |
|---|---|---|---|---|---|---|---|---|---|---|---|---|
| material | Organic Hf compound | ratio | formation time [nm] | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 248 | Single | Hf(C₂H₅O)₄ | 0.001 | 22 | 43 | 70 | 84 | 93 | 92 to 100 |
| | solution | Si[(C₂H₅)(n-C₄H₉)N]₄ | 0.01 | 24 | 40 | 71 | 74 | 87 | |
| | | | 0.1 | 41 | 45 | 73 | 93 | 130 | |
| | | | 0.2 | 38 | 47 | 82 | 113 | 112 | |
| | | | 0.5 | 35 | 49 | 80 | 121 | 116 | |
| Ex. 249 | Single | Hf(n-C₃H₇O)₄ | 0.001 | 32 | 40 | 57 | 98 | 98 | 95 to 98 |
| | solution | Si[(C₂H₅)(n-C₄H₉)N]₄ | 0.01 | 25 | 47 | 44 | 67 | 74 | |
| | | | 0.1 | 25 | 40 | 46 | 84 | 89 | |
| | | | 0.2 | 43 | 69 | 65 | 95 | 190 | |
| | | | 0.5 | 53 | 80 | 120 | 180 | 188 | |
| Ex. 250 | Single | Hf(n-C₄H₉O)₄ | 0.001 | 26 | 37 | 63 | 65 | 70 | 99 to 100 |
| | solution | Si[(C₂H₅)(n-C₄H₉)N]4 | 0.01 | 28 | 40 | 51 | 94 | 115 | |
| | | | 0.1 | 42 | 51 | 62 | 94 | 115 | |
| | | | 0.2 | 43 | 53 | 65 | 99 | 123 | |
| | | | 0.5 | 47 | 70 | 93 | 96 | 120 | |
| Ex. 251 | Single | Hf[(CH₃)₂N]₄ | 0.001 | 30 | 38 | 70 | 93 | 99 | 95 to 96 |
| | solution | Si(CH₃O)₄ | 0.01 | 31 | 43 | 49 | 62 | 71 | |
| | | | 0.1 | 29 | 38 | 49 | 82 | 90 | |
| | | | 0.2 | 40 | 69 | 72 | 92 | 101 | |
| | | | 0.5 | 52 | 81 | 160 | 162 | 182 | |
| Ex. 252 | Single | Hf[(C₂H₅)₂N]₄ | 0.001 | 24 | 37 | 62 | 69 | 74 | 92 to 93 |
| | solution | Si(CH₃O)₄ | 0.01 | 25 | 40 | 49 | 92 | 112 | |
| | | | 0.1 | 39 | 49 | 61 | 93 | 114 | |
| | | | 0.2 | 41 | 55 | 64 | 98 | 120 | |
| | | | 0.5 | 43 | 70 | 92 | 99 | 112 | |

TABLE 82
Silicon substrate-Si film-HfSiON thin film

| Raw | | Mixing | Film thickness per film | | | | | Peel test | | | | |
|---|---|---|---|---|---|---|---|---|---|---|---|---|
| material | Organic Hf compound | ratio | formation time [nm] | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 253 | Single | Hf[(CH₃)(C₂H₅)N]₄ | 0.001 | 24 | 33 | 35 | 64 | 83 | 97 to 98 |
| | solution | Si(CH₃O)₄ | 0.01 | 23 | 40 | 46 | 75 | 85 | |
| | | | 0.1 | 34 | 43 | 86 | 65 | 82 | |
| | | | 0.2 | 37 | 43 | 65 | 79 | 93 | |
| | | | 0.5 | 41 | 65 | 93 | 99 | 180 | |
| Ex. 254 | Single | Hf(CH₃O)₄ | 0.001 | 23 | 22 | 65 | 73 | 94 | 98 to 99 |
| | solution | Si(CH₃O)₄ | 0.01 | 21 | 39 | 69 | 88 | 98 | |
| | | | 0.1 | 47 | 72 | 75 | 88 | 99 | |
| | | | 0.2 | 35 | 46 | 75 | 94 | 114 | |
| | | | 0.5 | 36 | 52 | 90 | 99 | 136 | |
| Ex. 255 | Single | Hf(C₂H₅O)₄ | 0.001 | 28 | 37 | 56 | 64 | 93 | 97 to 99 |
| | solution | Si(CH₃O)₄ | 0.01 | 24 | 46 | 85 | 98 | 102 | |
| | | | 0.1 | 28 | 40 | 60 | 73 | 83 | |
| | | | 0.2 | 42 | 61 | 72 | 88 | 97 | |
| | | | 0.5 | 57 | 81 | 101 | 173 | 185 | |
| Ex. 256 | Single | Hf(n-C₃H₇O)₄ | 0.001 | 23 | 44 | 60 | 68 | 72 | 96 to 97 |
| | solution | Si(CH₃O)₄ | 0.01 | 25 | 34 | 49 | 62 | 92 | |
| | | | 0.1 | 38 | 42 | 64 | 81 | 99 | |
| | | | 0.2 | 38 | 52 | 63 | 86 | 96 | |
| | | | 0.5 | 43 | 65 | 99 | 112 | 123 | |
| Ex. 257 | Single | Hf(n-C₄H₉O)₄ | 0.001 | 22 | 32 | 38 | 63 | 74 | 95 to 97 |
| | solution | Si(CH₃O)₄ | 0.01 | 24 | 40 | 52 | 74 | 82 | |
| | | | 0.1 | 37 | 44 | 55 | 73 | 93 | |
| | | | 0.2 | 37 | 45 | 64 | 70 | 99 | |
| | | | 0.5 | 40 | 88 | 96 | 110 | 119 | |

TABLE 83
Silicon substrate-Si film-HfSiON thin film

| Raw | | Mixing | Film thickness per film | | | | | Peel test | | | | |
|---|---|---|---|---|---|---|---|---|---|---|---|---|
| material | Organic Hf compound | ratio | formation time [nm] | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 258 | Single | Hf[(CH₃)₂N]₄ | 0.001 | 23 | 33 | 38 | 64 | 74 | 97 to 98 |
| | solution | Si(C₂H₅O)₄ | 0.01 | 24 | 40 | 52 | 73 | 83 | |
| | | | 0.1 | 40 | 44 | 53 | 72 | 94 | |
| | | | 0.2 | 37 | 45 | 64 | 75 | 99 | |
| | | | 0.5 | 42 | 87 | 95 | 102 | 180 | |
| Ex. 259 | Single | Hf[(C₂H₅)₂N]₄ | 0.001 | 23 | 42 | 71 | 80 | 94 | 97 to 98 |
| | solution | Si(C₂H₅O)₄ | 0.01 | 24 | 37 | 72 | 75 | 87 | |
| | | | 0.1 | 40 | 44 | 82 | 92 | 121 | |
| | | | 0.2 | 40 | 44 | 81 | 101 | 115 | |
| | | | 0.5 | 29 | 48 | 82 | 109 | 121 | |
| Ex. 260 | Single | Hf[(CH₃)(C₂H₅)N]₄ | 0.001 | 31 | 41 | 55 | 95 | 99 | 97 to 99 |
| | solution | Si(C₂H₅O)₄ | 0.01 | 24 | 46 | 53 | 67 | 79 | |
| | | | 0.1 | 25 | 42 | 49 | 84 | 98 | |
| | | | 0.2 | 41 | 68 | 70 | 99 | 129 | |
| | | | 0.5 | 52 | 82 | 100 | 152 | 182 | |
| Ex. 261 | Single | Hf(CH₃O)₄ | 0.001 | 25 | 37 | 62 | 69 | 79 | 96 to 97 |
| | solution | Si(C₂H₅O)₄ | 0.01 | 27 | 40 | 50 | 92 | 102 | |
| | | | 0.1 | 41 | 50 | 64 | 95 | 105 | |
| | | | 0.2 | 42 | 55 | 63 | 90 | 102 | |
| | | | 0.5 | 45 | 71 | 90 | 97 | 120 | |
| Ex. 262 | Single | Hf(C₂H₅O)₄ | 0.001 | 23 | 37 | 42 | 64 | 79 | 95 to 97 |
| | solution | Si(C₂H₅O)₄ | 0.01 | 25 | 40 | 53 | 73 | 88 | |
| | | | 0.1 | 40 | 45 | 54 | 75 | 92 | |
| | | | 0.2 | 38 | 47 | 64 | 69 | 99 | |
| | | | 0.5 | 34 | 80 | 90 | 101 | 170 | |

TABLE 84
Silicon substrate-Si film-HfSiON thin film

| Raw | | Mixing | Film thickness per film | | | | | Peel test | | | | |
|---|---|---|---|---|---|---|---|---|---|---|---|---|
| material | Organic Hf compound | ratio | formation time [nm] | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 263 | Single | Hf(n-C₃H₇O)₄ | 0.001 | 24 | 33 | 37 | 64 | 73 | 97 to 98 |
| | solution | Si(C₂H₅O)₄ | 0.01 | 25 | 41 | 53 | 74 | 85 | |
| | | | 0.1 | 41 | 45 | 56 | 73 | 94 | |
| | | | 0.2 | 37 | 46 | 64 | 70 | 100 | |
| | | | 0.5 | 41 | 89 | 95 | 110 | 172 | |
| Ex. 264 | Single | Hf(n-C₄H₉O)₄ | 0.001 | 24 | 43 | 73 | 64 | 93 | 97 to 99 |
| | solution | Si(C₂H₅O)₄ | 0.01 | 24 | 37 | 72 | 72 | 88 | |
| | | | 0.1 | 42 | 45 | 80 | 90 | 121 | |
| | | | 0.2 | 38 | 45 | 80 | 101 | 113 | |
| | | | 0.5 | 35 | 49 | 82 | 115 | 119 | |
| Ex. 265 | Single | Hf[(CH₃)₂N]₄ | 0.001 | 32 | 42 | 56 | 97 | 99 | 97 to 99 |
| | solution | Si(n-C₃H₇O)₄ | 0.01 | 25 | 47 | 44 | 64 | 79 | |
| | | | 0.1 | 25 | 42 | 48 | 82 | 89 | |
| | | | 0.2 | 42 | 69 | 72 | 92 | 183 | |
| | | | 0.5 | 51 | 80 | 125 | 180 | 192 | |
| Ex. 266 | Single | Hf[(C₂H₅)₂N]₄ | 0.001 | 25 | 37 | 68 | 65 | 74 | 96 to 97 |
| | solution | Si(n-C₃H₇O)₄ | 0.01 | 29 | 38 | 53 | 94 | 112 | |
| | | | 0.1 | 42 | 51 | 64 | 93 | 115 | |
| | | | 0.2 | 44 | 53 | 65 | 93 | 121 | |
| | | | 0.5 | 47 | 72 | 92 | 99 | 131 | |

TABLE 85
Silicon substrate-Si film-HfSiON thin film

| Raw | | Mixing | Film thickness per film | | | | | Peel test | | | | |
|---|---|---|---|---|---|---|---|---|---|---|---|---|
| material | Organic Hf compound | ratio | formation time [nm] | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 267 | Single | Hf[(CH₃)(C₂H₅)N]₄ | 0.001 | 23 | 33 | 39 | 65 | 74 | 97 to 99 |
| | solution | Si(n-C₃H₇O)₄ | 0.01 | 29 | 39 | 51 | 80 | 84 | |
| | | | 0.1 | 31 | 41 | 56 | 77 | 95 | |
| | | | 0.2 | 33 | 43 | 63 | 75 | 99 | |
| | | | 0.5 | 42 | 81 | 92 | 110 | 170 | |
| Ex. 268 | Single | Hf(CH₃O)₄ | 0.001 | 24 | 43 | 73 | 81 | 95 | 96 to 99 |
| | solution | Si(n-C₃H₇O)₄ | 0.01 | 25 | 38 | 72 | 84 | 98 | |
| | | | 0.1 | 41 | 47 | 85 | 92 | 99 | |
| | | | 0.2 | 40 | 46 | 81 | 99 | 105 | |
| | | | 0.5 | 42 | 51 | 79 | 115 | 120 | |
| Ex. 269 | Single | Hf(C₂H₅O)₄ | 0.001 | 39 | 43 | 56 | 92 | 99 | 97 to 99 |
| | solution | Si(n-C₃H₇O)₄ | 0.01 | 25 | 49 | 55 | 70 | 82 | |
| | | | 0.1 | 26 | 41 | 50 | 81 | 99 | |
| | | | 0.2 | 43 | 66 | 70 | 90 | 170 | |
| | | | 0.5 | 54 | 81 | 118 | 179 | 192 | |
| Ex. 270 | Single | Hf(n-C₃H₇O)₄ | 0.001 | 25 | 37 | 61 | 68 | 79 | 96 to 97 |
| | solution | Si(n-C₃H₇O)₄ | 0.01 | 30 | 41 | 52 | 91 | 115 | |
| | | | 0.1 | 41 | 51 | 70 | 93 | 118 | |
| | | | 0.2 | 42 | 54 | 72 | 95 | 132 | |
| | | | 0.5 | 46 | 69 | 91 | 100 | 120 | |

TABLE 86
Silicon substrate-Si film-HfSiON thin film

| Raw | | Mixing | Film thickness [nm] per | | | | | Peel test | | | | |
|---|---|---|---|---|---|---|---|---|---|---|---|---|
| material | Organic Hf compound | ratio | film formation time | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 271 | Single | Hf(n-C₄H₉O)₄ | 0.001 | 24 | 34 | 38 | 65 | 79 | 96 to 97 |
| | solution | Si(n-C₃H₇O)₄ | 0.01 | 26 | 42 | 54 | 75 | 81 | |
| | | | 0.1 | 38 | 46 | 55 | 74 | 94 | |
| | | | 0.2 | 35 | 47 | 66 | 75 | 98 | |
| | | | 0.5 | 42 | 90 | 97 | 102 | 123 | |
| Ex. 272 | Single | Hf[(CH₃)₂N]₄ | 0.001 | 25 | 43 | 72 | 83 | 99 | 97 to 99 |
| | solution | Si(n-C₄H₉O)₄ | 0.01 | 26 | 40 | 73 | 82 | 95 | |
| | | | 0.1 | 40 | 44 | 72 | 92 | 103 | |
| | | | 0.2 | 39 | 46 | 80 | 103 | 115 | |
| | | | 0.5 | 37 | 56 | 81 | 132 | 147 | |
| Ex. 273 | Single | Hf[(C₂H₅)₂N]₄ | 0.001 | 33 | 41 | 57 | 95 | 99 | 96 to 98 |
| | solution | Si(n-C₄H₉O)₄ | 0.01 | 29 | 47 | 52 | 69 | 89 | |
| | | | 0.1 | 27 | 42 | 49 | 80 | 92 | |
| | | | 0.2 | 44 | 69 | 72 | 95 | 130 | |
| | | | 0.5 | 54 | 79 | 85 | 170 | 187 | |
| Ex. 274 | Single | Hf[(CH₃)(C₂H₅)N]₄ | 0.001 | 27 | 38 | 69 | 82 | 92 | 97 to 99 |
| | solution | Si(n-C₄H₉O)₄ | 0.01 | 29 | 41 | 53 | 95 | 105 | |
| | | | 0.1 | 43 | 52 | 63 | 95 | 120 | |
| | | | 0.2 | 44 | 55 | 69 | 99 | 118 | |
| | | | 0.5 | 49 | 71 | 92 | 98 | 123 | |

TABLE 87
Silicon substrate-Si film-HfSiON thin film

| Raw | | Mixing | Film thickness per film | | | | | Peel test | | | | |
|---|---|---|---|---|---|---|---|---|---|---|---|---|
| material | Organic Hf compound | ratio | formation time [nm] | | | | | [a piece/100 pieces] | | | | |
| solution | & organic Si compound | [wt %] | 1 min. | 2 min. | 3 min. | 4 min. | 5 min. | 1 min. | 2 min. | 3 min. | 4 min. | 5 min. |

| | | | | | | | | | |
|---|---|---|---|---|---|---|---|---|---|
| Ex. 275 | Single | Hf(CH₃O)₄ | 0.001 | 19 | 35 | 42 | 63 | 79 | 97 to 99 |
| | solution | Si(n-C₄H₉O)₄ | 0.01 | 18 | 25 | 50 | 60 | 79 | |
| | | | 0.1 | 25 | 31 | 63 | 75 | 89 | |
| | | | 0.2 | 30 | 39 | 62 | 70 | 100 | |
| | | | 0.5 | 44 | 69 | 121 | 139 | 153 | |
| Ex. 276 | Single | Hf(C₂H₅O)₄ | 0.001 | 20 | 29 | 59 | 81 | 99 | 97 to 99 |
| | solution | Si(n-C₄H₉O)₄ | 0.01 | 23 | 38 | 43 | 69 | 79 | |
| | | | 0.1 | 29 | 47 | 89 | 120 | 139 | |
| | | | 0.2 | 31 | 59 | 101 | 130 | 152 | |
| | | | 0.5 | 34 | 97 | 129 | 135 | 189 | |
| Ex. 277 | Single | Hf(n-C₃H₇O)₄ | 0.001 | 21 | 31 | 35 | 49 | 55 | 97 to 98 |
| | solution | Si(n-C₄H₉O)₄ | 0.01 | 19 | 39 | 52 | 71 | 93 | |
| | | | 0.1 | 31 | 57 | 71 | 103 | 121 | |
| | | | 0.2 | 43 | 69 | 81 | 121 | 139 | |
| | | | 0.5 | 55 | 100 | 115 | 163 | 200 | |
| Ex. 278 | Single | Hf(n-C₄H₉O)₄ | 0.001 | 14 | 20 | 41 | 69 | 79 | 96 to 98 |
| | solution | Si(n-C₄H₉O)₄ | 0.01 | 22 | 35 | 47 | 70 | 81 | |
| | | | 0.1 | 29 | 45 | 59 | 73 | 89 | |
| | | | 0.2 | 34 | 59 | 65 | 80 | 99 | |
| | | | 0.5 | 43 | 100 | 129 | 153 | 173 | |

As clearly shown in the tables 69 to 87, the HfSiON films formed by using the single raw material solution according to Examples A188 to A278 had a significantly high film forming rate, and stable film formation was obtained. Also, in the peel test, most of grids were remained on substrates in HfSiON films formed by using the raw material solution according to Examples A188 to A278 and thus high adhesivity results were obtained.

### INDUSTRIAL APPLICABILITY

The raw material solution for MOCVD method of the invention is a single solution of the metalorganic compound raw material for a film containing a plurality of metals such as the composite oxide film containing Hf-Si. This raw material solution is prepared as a single solution by mixing the organic Si compound with the organic Hf compound in a predetermined mixing ratio and then by dissolving the organic Hf compound in the organic Si compound, and the solution is obtained by heating in a predetermined temperature range to be prepared. Since the single solution of the raw material solution for MOCVD method prepared in such manner is thought to include an intermediate of Hf-Si mixed metal polynuclear molecule formed with the organic Hf compound and the organic Si compound, this intermediate nucleates the initial film-forming core on a surface of the substrate. Therefore, high film forming rate is obtained by using the raw material solution of the invention.

In addition, the method for manufacturing composite oxide film containing Hf-Si is a method for manufacturing composite oxide film containing Hf-Si by using the above-mentioned raw material solution for MOCVD method. By using the above-mentioned single raw material solution for MOCVD method of the invention, films can be formed at a higher film forming rate in comparison with the conventional case where two solutions of raw material solution for MOCVD method are respectively supplied to form a film. Further, obtained composite oxide film containing Hf-Si has a high adhesivity with a substrate.

1. A raw material solution for metal organic chemical vapor deposition, comprising:
an organic Si compound represented by the following formula (1) and an organic Hf compound represented by the following formula (2), which are mixed in a predetermined ratio to dissolve the organic Hf compound in the organic Si compound,
(R¹R²N)ₙSiH₍₄₋ₙ₎ (1)
(wherein, R¹ and R² are straight or branched alkyl groups having 1 to 4 carbon atoms provided that R¹ and R² are the same, and R¹ is an alkyl group having 1 or 2 carbon atoms and R² is a straight or branched alkyl group having 2 to 4 carbon atoms provided that R¹ and R² are different, and n is an integer of 1 to 4),
Hf(OR³)₄ (2)
(wherein, R³ is a straight or branched alkyl group having 1 to 4 carbon atoms).

2. The raw material solution for metal organic chemical vapor deposition method according to claim 1, wherein a ratio of the organic Hf compound and to the organic Si compound is within a range of 0.001 to 0.5 wt %.

3. A method for manufacturing a composite oxide film containing Hf-Si, comprising:
depositing a composite oxide film containing Hf-Si by using the raw material solution according to claim 1 in a chemical vapor deposition process.

4. A method for manufacturing a composite oxide film containing Hf-Si, comprising the steps of:
growing a Si film on a surface of a substrate by thermally decomposing an organic Si compound with a reducing gas; and
supplying the raw material solution according to claim 1 together with an oxidizing agent and performing thermal decomposition to form a HfSiO film on a surface of the Si film,
wherein the composition of the organic Si compound used for growing the Si film and the composition of the organic Si compound used in the raw material solution may be the same or different.

5. A method for manufacturing a composite oxide film containing Hf-Si, comprising the steps of:
growing a Si film on a surface of a substrate by thermally decomposing an organic Si compound with a reducing gas; and
supplying the raw material solution according to claim 1 together with an oxidizing agent and a nitrogen source and then performing thermal decomposition to form a HfSiON film on a surface of the Si film,
wherein the composition of the organic Si compound used for growing the Si film and the composition of the organic Si compound used in the raw material solution may be the same or different.

6. A method for preparing a raw material solution for metal organic chemical vapor deposition, comprising:
mixing an organic Si compound with an organic Hf compound such that the ratio of the organic Hf compound to the organic Si compound ranges from 0.001 to 0.5 wt %;
dissolving the organic Hf compound in the organic Si compound; and
heating the solution at a temperature of 20 to 100° C.

7. The raw material solution for metal organic chemical vapor deposition method according to claim 6, wherein the organic Si compound is represented by the following formula (1) or (3),
(R¹R²N)ₙSiH₍₄₋ₙ₎ (1)
(wherein, R¹ and R² are straight or branched alkyl groups having 1 to 4 carbon atoms provided that R¹ and R² are the same, and R¹ is an alkyl group having 1 or 2 carbon atoms and R² is a straight or branched alkyl group having 2 to 4 carbon atoms provided that R¹ and R² are different, and n is an integer of 1 to 4),
(R³O)ₘSiH₍₄₋ₘ₎ (3)
(wherein, R³ is a straight or branched alkyl group having 1 to 4 carbon atoms, and m is an integer of 1 to 4).

8. The raw material solution for metal organic chemical vapor deposition method according to claim 6, wherein the organic Hf compound is represented by the following formula (4),
Hf(R⁴R⁵N)₄ (4)
(wherein, R⁴ and R⁵ are alkyl groups having 1 or 2 carbon atoms, and R⁴ and R⁵ may be the same or different from each other).

9. The raw material solution for metal organic chemical vapor deposition method according to claim 6, wherein the organic Hf compound is represented by the following formula (5),
Hf(OR⁶)₄ (5)
(wherein, R⁶ is a straight or branched alkyl group having 1 to 4 carbon atoms).

10. A method for manufacturing a composite oxide film containing Hf-Si, comprising:
depositing a composite oxide film containing Hf-Si by using the raw material solution according to claim 6.

11. A method for manufacturing a composite oxide film containing Hf-Si, comprising the steps of:
growing a Si film on a surface of a substrate by thermally decomposing an organic Si compound with a reducing gas; and
supplying the raw material solution according to claim 6 together with an oxidizing agent and performing thermal decomposition to form a HfSiO film on a surface of the Si film,
wherein the composition of the organic Si compound used for growing the Si film and the composition of the organic Si compound used in the raw material solution may be the same or different.

12. A method for manufacturing a composite oxide film containing Hf-Si, comprising the steps of:
growing a Si film on a surface of a substrate by thermally decomposing an organic Si compound with a reducing gas; and
supplying the raw material solution according to claim 6 together with an oxidizing agent and a nitrogen source and performing thermal decomposition to form a HfSiON film on a surface of the Si film,
wherein the composition of the organic Si compound used for growing the Si film and the composition of the organic Si compound used in the raw material solution may be the same or different.

13. A method for manufacturing a composite oxide film containing Hf-Si, comprising:
depositing a composite oxide film containing Hf-Si by using the raw material solution according to claim 2 in a chemical vapor deposition process.

14. A method for manufacturing a composite oxide film containing Hf-Si, comprising:
depositing a composite oxide film containing Hf-Si by using the raw material solution according to claim 7.

15. A method for manufacturing a composite oxide film containing Hf-Si, comprising the steps of:
growing a Si film on a surface of a substrate by thermally decomposing an organic Si compound with a reducing gas; and
supplying the raw material solution according to claim 7 together with an oxidizing agent and performing thermal decomposition to form a HfSiO film on a surface of the Si film,
wherein the composition of the organic Si compound used for growing the Si film and the composition of the organic Si compound used in the raw material solution may be the same or different.

16. A method for manufacturing composite oxide film containing Hf-Si, comprising the steps of:
growing a Si film on a surface of a substrate by thermally decomposing an organic Si compound with a reducing gas; and
supplying the raw material solution according to claim 7 together with an oxidizing agent and a nitrogen source and performing thermal decomposition to form a HfSiON film on a surface of the Si film,
wherein the composition of the organic Si compound used for growing the Si film and the composition of the organic Si compound used in the raw material solution may be the same or different.

17. A method for manufacturing a composite oxide film containing Hf-Si, comprising:
depositing a composite oxide film containing Hf-Si by using the raw material solution according to claim 8.

18. A method for manufacturing a composite oxide film containing Hf-Si, comprising the steps of:
growing a Si film on a surface of a substrate by thermally decomposing an organic Si compound with a reducing gas; and
supplying the raw material solution according to claim 8 together with an oxidizing agent and performing thermal decomposition to form a HfSiO film on a surface of the Si film,
wherein the composition of the organic Si compound used for growing the Si film and the composition of the organic Si compound used in the raw material solution may be the same or different.

19. A method for manufacturing composite oxide film containing Hf-Si, comprising the steps of:
growing a Si film on a surface of a substrate by thermally decomposing an organic Si compound with a reducing gas; and
supplying the raw material solution according to claim 8 together with an oxidizing agent and a nitrogen source and performing thermal decomposition to form a HfSiON film on a surface of the Si film,
wherein the composition of the organic Si compound used for growing the Si film and the composition of the organic Si compound used in the raw material solution may be the same or different.

20. A method for manufacturing a composite oxide film containing Hf-Si, comprising:
depositing a composite oxide film containing Hf-Si by using the raw material solution according to claim 9.

21. A method for manufacturing a composite oxide film containing Hf-Si, comprising the steps of:
growing a Si film on a surface of a substrate by thermally decomposing an organic Si compound with a reducing gas; and
supplying the raw material solution according to claim 9 together with an oxidizing agent and performing thermal decomposition to form a HfSiO film on a surface of the Si film,
wherein the composition of the organic Si compound used for growing the Si film and the composition of the organic Si compound used in the raw material solution may be the same or different.

22. A method for manufacturing composite oxide film containing Hf-Si, comprising the steps of:
growing a Si film on a surface of a substrate by thermally decomposing an organic Si compound with a reducing gas; and
supplying the raw material solution according to claim 9 together with an oxidizing agent and a nitrogen source and performing thermal decomposition to form a HfSiON film on a surface of the Si film,
wherein the composition of the organic Si compound used for growing the Si film and the composition of the organic Si compound used in the raw material solution may be the same or different.
